(19) United States
(12) Patent Application Publication
(10) Pub. No.: US 2010/0068470 A1
(43) Pub. Date: Mar. 18, 2010

(54) RESIN COMPOSITION FOR LASER ENGRAVING, RELIEF PRINTING PLATE PRECURSOR FOR LASER ENGRAVING, RELIEF PRINTING PLATE AND METHOD OF PRODUCING THE SAME

(75) Inventor: Atsushi SUGASAKI, Shizuoka-ken (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/554,002

(22) Filed: Sep. 4, 2009

(30) Foreign Application Priority Data
Sep. 17, 2008 (JP) 2008-238359
Jan. 21, 2009 (JP) 2009-011000

(51) Int. Cl. B32B 3/02; G03F 7/004; G03F 7/20

(52) U.S. Cl. 428/172; 430/270.1; 430/286.1; 430/306

(57) ABSTRACT

The present invention provides a resin composition for laser engraving, containing at least an inorganic porous material, a binder polymer, a thermopolymerization initiator and a polymerizable compound; a relief printing plate precursor for laser engraving using the same; a relief printing plate; and a method of producing the relief printing plate.

### CROSS-REFERENCE TO RELATED APPLICATIONS

This application claims priorities under 35 USC 119 from Japanese Patent Application No. 2008-238359 filed on Sep. 17, 2008, and Japanese Patent Application No. 2009-011000 filed on Jan. 21, 2009, the disclosures of which are incorporated by reference herein.

### BACKGROUND OF THE INVENTION

1. Field of the Invention

The present invention relates to a resin composition for laser engraving, a relief printing plate precursor for laser engraving, a relief printing plate and a method of producing the relief printing plate.

2. Description of the Related Art

As a method for forming a printing plate by forming a concave-convex structure on a photosensitive resin layer laminated on the surface of a support, a method of exposing a relief forming layer which has been formed using a photosensitive composition, to ultraviolet radiation through an original image film so as to selectively cure image areas, and removing uncured parts by means of a developer solution, that is, so-called “analogue plate making”, is well known.

A relief printing plate is a letterpress printing plate having a relief layer with a concave-convex structure, and such a relief layer having a concave-convex structure may be obtained by patterning a relief forming layer formed from a photosensitive composition containing, as a main component, for example, an elastomeric polymer such as synthetic rubber, a resin such as a thermoplastic resin, or a mixture of a resin and a plasticizer, to thus form a concave-convex structure. Among such relief printing plates, a printing plate having a flexible relief layer is often referred to as a flexo plate.

In the case of producing a relief printing plate by analogue plate making, since an original image film using a silver salt material is needed in general, the plate making process requires time and costs for the production of original image films. Furthermore, since chemical treatments are required in the development of original image films, and also treatments of development waste water are necessary, investigations on simpler methods of plate making, for example, methods which do not use original image films or methods which do not necessitate development treatments, are being undertaken.

In recent years, a method of making a plate having a relief forming layer by means of scanning exposure, without requiring an original image film, is being investigated. As a technique which does not require an original image film, there has been proposed a relief printing plate precursor in which a laser-sensitive type mask layer element capable of forming an image mask is provided on a relief forming layer (see, for example, Japanese Patent No. 2773847 and Japanese Patent Application Laid-Open (JP-A) No. 9-171247). The method of making such a plate precursor is referred to as a “mask CTP method”, because an image mask having the same function as the original image film is formed from the mask layer element by means of laser irradiation that is based on image data. This method does not require an original image film, but the subsequent plate making treatment involves a process of exposing the plate precursor to ultraviolet radiation through an image mask, and then removing uncured parts by development, and from the viewpoint of requiring a development treatment, the method has a room for further improvement.

As a method of plate making which does not require a development process, a so-called “direct engraving CTP method”, in which plate making is carried out by directly engraving a relief forming layer using laser, has been proposed a number of times. The direct engraving CTP method is literally a method of forming a concave-convex structure which will serve as relief, by engraving the structure with laser. This method is advantageous in that the relief shape can be freely controlled, unlike the relief formation processes using original image films. For this reason, in the case of forming images like cutout characters, it is possible to engrave the image regions deeper than other regions, or for microdot images, to carry out shouldered engraving in consideration of resistance to the printing pressure, or the like. Hitherto, as the plate material which has been used in the direct engraving CTP, a number of various plate materials have been proposed, for example, U.S. Pat. No. 5,798,202, JP-A No. 2002-3665, Japanese Patent No. 3438404, JP-A No. 2004-262135, JP-A No. 2001-121833, JP-A No. 2006-2061, JP-A No. 2007-148322, and the like.

The resin composition for laser engraving used in the direct engraving CTP method generates an engraving residue, which is formed from a low molecular weight polymerizable compound or the like, when a relief forming layer is directly subjected to platemaking with laser light. Since the presence of engraving residue on the surface of a plate after platemaking seriously affects print quality, it is necessary to facilitate removal of any engraving residue that is generated. In order to facilitate the removal of engraving residue, WO 2004/00571 A1, for example, discloses that an inorganic porous material is contained in a photosensitive resin composition for laser-engravable printing plate precursors. However, this kind of photosensitive resin composition is problematic with respect to photostability; for example, when the photosensitive resin composition is left to stand under a white lamp for a long time, the viscosity increases or gelation occurs.

### SUMMARY OF THE INVENTION

The invention has been made in view of the circumstances described above.

A first aspect of the invention is to provide a resin composition for laser engraving, containing at least an inorganic porous material, a binder polymer, a thermopolymerization initiator, and a polymerizable compound.

A second aspect of the invention is to provide a relief printing plate precursor for laser engraving, having a relief forming layer formed by thermally crosslinking the resin composition for laser engraving of the invention.

A third aspect of the invention is to provide a method of producing a relief printing plate, the method including laser engraving a relief forming layer in the relief printing plate precursor for laser engraving of the invention to form a relief layer.

A fourth aspect of the invention is to provide a relief printing plate having a relief layer, produced by the method of producing a relief printing plate of the invention.

### BRIEF DESCRIPTION OF THE DRAWINGS

FIG. 1 is a schematic constitution view (perspective view) showing a platemaking device provided with a semiconductor laser recording device equipped with a fiber, which may be applied to the invention.

### DETAILED DESCRIPTION

Hereinafter, the resin composition for laser engraving, the relief printing plate precursor for laser engraving, the relief printing plate and the method of producing a relief printing plate of the invention will be described in detail.

In the present specification, a phrase “ . . . to . . . ” represents a range including the numeral values represented before and after “to” as a minimum value and a maximum value, respectively.

1. Resin Composition for Laser Engraving

The resin composition for laser engraving of the invention (hereinafter, may also be simply referred to as “resin composition of the invention”) contains at least (A) an inorganic porous material, (B) a binder polymer, (C) a thermopolymerization initiator, and (D) a polymerizable compound. The resin composition of the invention may be polymerized and cured using thermal energy.

The resin composition of the invention exhibits excellent storage stability (photostability). In this regard, it is supposed that the resin composition of the invention is not photosensitive because the composition contains a thermopolymerization initiator and, as a result, even if left to stand for a long time under a white lamp or the like, viscosity increase or gelation due to the polymerization of the polymerizable compound induced by decomposition of the polymerization initiator is less likely to occur as compared to resin compositions containing a photopolymerization initiator, whereby the resin composition of the invention exhibits excellent storage stability (photostability).

Incorporation of a thermopolymerization initiator in the resin composition of the invention enables achievement of photostability under white lamps, as well as sufficient enhancement of thermal crosslinking efficiency, which is important in the production of a resin molded product. This enhancement of thermal crosslinking efficiency is particularly remarkable when the resin composition of the invention contains carbon black as a photothermal conversion agent, which is an optional component described below. Although the reason is unclear, it is supposed, as described in detail below, that the carbon black may act as an exothermic body at the time of thermal crosslinking, and enhance the decomposition efficiency of the thermopolymerization initiator.

Even with a resin composition containing a photopolymerization initiator, it is still possible to suppress the decomposition of the photopolymerization initiator caused by photosensitization, by using, for example, a photothermal conversion agent. However, if a photopolymerization initiator and a photothermal conversion agent are used in combination, the photothermal conversion agent absorbs light having a wavelength that is required in the photodecomposition of the photopolymerization initiator, and thus photodecomposition is suppressed, resulting in insufficient crosslinking. For this reason, in most cases, the photostability under a white lamp and the photo-crosslinking property of the resin composition cancel each other out.

As such, the resin composition of the invention is a resin composition which exhibits not only excellent storage stability (photostability) but also excellent crosslinking efficiency, in contrast to resin compositions containing a photopolymerization initiator.

Furthermore, the resin composition of the invention allows easy removal of engraving residue which is generated when the resin composition is subjected to laser engraving to form a resin molded product. In this regard, it is supposed that the inorganic porous material according to the invention is porous with numerous fine pores on the surface, and the engraving residue (typically, liquid residue) generated upon laser engraving is absorbed (adsorbed) into these fine pore parts. As a result, an “engraving residue-inorganic microparticle complex” is formed which has different properties from the properties before adsorption of the engraving residue and, therefore, the adhesiveness between the engraving residue and the surface of the resin molded product is decreased, whereby removal of the engraving residue is easier.

In the resin composition of the invention, combined use of the inorganic porous material and carbon black, which is a suitable photothermal conversion agent, exhibits an effect whereby when the resin composition of the invention is used in the formation of a relief forming layer of the relief printing plate precursor for laser engraving, which is a suitable embodiment of an application of the resin composition, the surface state of the relief forming layer being formed is improved. In this regard, it is supposed that when the inorganic porous material and carbon black are used in combination, the π electrons at the surface of the carbon black and the OH group at the surface of the inorganic porous material interact with each other, and aggregation of the carbon black is suppressed, as a result of which a favorable film surface state is formed. On the other hand, if only carbon black is used without the inorganic porous material, the surface of the relief forming layer does not become a uniform surface, and a large number of fine crater-shaped portions are generated.

Furthermore, since the resin composition of the invention has high engraving sensitivity when subjected to laser engraving, laser engraving may be performed at high speed, and thus the engraving time required during laser engraving may also be shortened.

The resin composition of the invention having such properties can, without particular limitation, be applied widely for forming a resin molded product to be subjected to laser engraving. For example, the resin composition of the invention, although its application is not particularly limited, can be applied specifically to a relief forming layer in a relief printing plate precursor for forming a convex relief by laser engraving, as well as to an intaglio printing plate, a stencil printing plate and a stamp. The resin composition of the invention can be used particularly preferably in forming a relief forming layer in a relief printing plate precursor for laser engraving.

Hereinafter, the constituent elements of the resin composition for laser engraving of the invention will be described.

(A) Inorganic Porous Material

The resin composition of the invention contains an inorganic porous material. In the invention, the term “inorganic porous material” means inorganic particles having minute pores or minute voids.

As the inorganic porous material according to the invention, inorganic particles having an average pore size of 1 nm to 1,000 nm, a pore volume of 0.1 ml/g to 10 ml/g, and a number average particle size of 10 μm or less, are preferred.

The average pore size of the inorganic porous material is preferably 1 nm to 1,000 nm, more preferably 2 nm to 200 nm, even more preferably 2 nm to 40 nm, and particularly preferably 2 nm to 30 nm, from the viewpoint of the amount of absorption of the engraving residue (liquid residue) generated during laser engraving. The inorganic porous material shows particularly excellent effects in the removal of engraving residue when the average pore size is 40 nm or less, while the inorganic porous material having an average pore size of 2 nm to 30 nm have an extremely high ability of absorbing the liquid residue. Therefore, as the inorganic porous material according to the invention, such an inorganic porous material having an average pore size of 2 nm to 30 nm is particularly preferred. Here, the average pore size of the inorganic porous material is a value measured using a nitrogen adsorption method.

The pore volume of the inorganic porous material is preferably 0.1 ml/g to 10 ml/g, and more preferably 0.2 ml/g to 5 ml/g, from the viewpoint of the amount of absorption of the liquid residue that is viscous. The pore volume according to the invention is a value obtained by a nitrogen adsorption method. Specifically, the pore volume is a value determined from an adsorption isotherm of nitrogen at −196° C. The average pore size and the pore volume for the inorganic porous material are calculated under an assumption of a cylindrical model from an adsorption isotherm at the time of nitrogen adsorption, based on a pore distribution analysis method called the BHJ (Brrett-Joyner-Halenda) method. The average pore size and the pore volume for the inorganic porous material are defined such that the finally reached pore volume on a curve obtained by plotting the cumulative pore volume against the pore size is designated as the pore volume, and the pore size obtained when the value of the pore volume reaches half the final value is designated as the average pore size.

The number average particle size of the inorganic porous material according to the invention is preferably 10 μm or less, more preferably 0.1 μm to 10 μm, even more preferably 0.5 μm to 10 μm, and most preferably 2 μm to 10 μm. The number average particle size according to the invention is a value measured using a laser scattering type particle size distribution measurement apparatus. When the number average particle size of the inorganic porous material is within the range described above, when the resin composition of the invention is subjected to laser engraving, there will be neither dust fluttering, nor contamination of the engraving apparatus by dust.

Particularly, in the case where the resin composition of the invention is applied to the relief forming layer of a relief printing plate precursor for laser engraving, when an inorganic porous material having a number average particle size of 10 μm or less is used, elaborateness of printed materials may be securely obtained without particles remaining behind on the fine relief image obtained by laser engraving. That is, in the field of high definition printing, printing plates having an elaborate pattern with a size of about 10 μm are used, but if an inorganic porous material having a number average particle size of 10 μm or less is used, image defects that are attributable to the inorganic porous material remaining at intaglio pattern parts formed with laser light, does not occur.

Furthermore, when inorganic porous particles having a number average particle size of 10 μm or less are used, the surface friction resistance value of the surface of resin molded products formed from the resin composition of the invention is decreased. Therefore, if the resin composition of the invention is applied to the relief forming layer of a relief printing plate precursor for laser engraving, attachment of paper dust upon printing may be more effectively suppressed. Also, the tensile properties or breaking strength of the resin molded products formed from the resin composition of the invention may also be ensured.

In order to obtain better adsorbability of the engraving residue, the inorganic porous material preferably has a specific surface area of 10 m²/g to 1,500 m²/g, and an amount of oil absorption of 10 ml/100 g to 2,000 ml/100 g. The specific surface area of the inorganic porous material is preferably 10 m²/g to 1,500 m²/g, and more preferably 100 m²/g to 800 m²/g. The specific surface area according to the invention is a value determined from an adsorption isotherm of nitrogen at −196° C. based on the BET formula.

The amount of oil absorption of the inorganic porous material is an index for evaluating the amount of oil absorption of a liquid gas by an inorganic porous material, and is defined as the amount of oil absorbed by 100 g of an inorganic porous material. The amount of oil absorption of the inorganic porous material according to the invention is preferably 10 ml/100 g to 2,000 ml/100 g, and more preferably 50 ml/100 g to 1,000 ml/100 g, from the viewpoints of the removability of liquid engraving residue and the mechanical strength of the inorganic porous material. Measurement of the amount of oil absorption was carried out according to JIS-K5101.

The inorganic porous material according to the invention needs to maintain porous property without deforming or melting by irradiation of laser light particularly in the infrared wavelength region. The ignition loss after treatment at 950° C. for 2 hours is preferably 15% by mass or less, and more preferably 10% by mass or less.

The characteristics of the porous material may be evaluated based on porosity. Here, the porosity is the ratio of the specific surface area P with respect to the surface area per unit mass S calculated from the number average particle size D (unit: μm) and the density d (unit: g/cm³) constituting the particles, that is, P/S. In the case where the particles are spherical, the surface area per particle is πD²×10⁻¹² (unit: m²), and the mass of one particle is (πD³d/6)×10⁻¹² (unit: g). Therefore, the surface area per unit mass is S=6/(Dd) (unit: m²/g). The aforementioned number average particle size D adopts a value measured using a laser diffraction/scattering type particle size distribution measurement apparatus or the like, and even if the porous particles are not true spheres, the particles are to be considered as spheres having a number average particle size D.

The specific surface area P adopts a value obtained by measuring the nitrogen molecules adsorbed onto the particle surfaces. When the particle size is decreased, the specific surface area P is increased. Thus, the specific surface area alone is inappropriate as an index representing the characteristics of the porous material. Therefore, in consideration of the particle size, porosity is employed as a non-dimensionalized index. The porosity of the inorganic porous material according to the invention is preferably 20 or greater, more preferably 50 or greater, and even more preferably 100 or greater. When the porosity is 20 or greater, excellent effects are manifested as a result of adsorption and removal of the liquid residue.

Preferable inorganic elements in the inorganic porous material include silicon (Si), titanium (Ti), zirconium (Zr) and aluminum (Al), and Si and Ti are more preferable.

The particle shape of the inorganic porous material is not particularly limited, and spherical, polyhedral, flat-shaped, needle-shaped or amorphous particles, or particles having protrusions on the surface may be mentioned. Furthermore, in regard to the inorganic porous material, particles which are hollow inside, spherical granules having a uniform pore size such as silica sponge, and the like may also be used, and for example, porous silica, mesoporous silica, silica-zirconia porous gel, porous alumina, porous glass, zirconium phosphate, zirconium silicophosphate, and the like may be mentioned. Among them, porous silica and mesoporous silica are preferred. Furthermore, in a compound having voids of a few nanometers to 100 nm between the layers, such as a layered clay compound, the pore size may not be defined, and thus, in regard to the invention, the distance between the voids present between the layers is defined as the pore size.

The particle shape of the inorganic porous material is preferably a spherical particle or a regular polyhedral particle from the viewpoint of the abrasion resistance of the surface of a resin molded product obtained by thermally curing the resin composition of the invention, and particularly a spherical particle is preferred. It is preferable to use a scanning electron microscope for the confirmation of the shape of particle. Even for a particle having a number average particle size of about 0.1 μm, the shape may be verified with a field emission type high resolution scanning electron microscope.

When the resin composition of the invention is to be applied to a relief printing plate precursor for laser engraving, it is preferable to use spherical particles or regular polyhedral rod-shaped particles because when the particles are exposed to the surface of a printing plate obtained from the precursor, the area of contact point between the particles and the surface of the printing medium is reduced. Furthermore, in the case of using spherical particles, an effect of reducing the thixotropic properties of the resin composition may also be obtained. It is presumed that this thixotropic properties suppressive effect could be a result of large reduction in the area of contact between particles themselves within the resin composition.

The spherical particles that are used in the invention are particles each surrounded by a curved surface, and not only true spheres but also quasi-spherical particles, which are not true spheres, are also included in the category of spherical particles. The spherical particles of the invention are such that when light is shed from one direction and is projected to a two-dimensional plane, the shape of the projected area is circular, elliptical or egg-shaped. A shape approximating to a true sphere is desirable in view of abrasion resistance. Also, the particles under consideration may also have minute concavity and convexity of 1/10 or less of the particle size in height on the particle surface.

According to the invention, it is preferable that at least 70% of the inorganic porous material is composed of spherical particles, and the sphericity of the spherical particles is 0.5 to 1. The term sphericity according to the invention is defined as, in the case where a particle is projected, the ratio between the maximum value of diameter D₁ of a circle which completely inscribes the projected figure, and the minimum value of diameter D₂ of a circle which circumscribes the projected figure (D₁/D₂). Since the sphericity of a true sphere is 1.0, the upper limit of the sphericity is 1. The sphericity of the spherical particle used in the invention is preferably 0.5 to 1, and more preferably 0.7 to 1.

A printing plate obtained from the relief printing plate precursor for laser engraving to which a resin composition utilizing an inorganic porous material having a sphericity of 0.5 or greater is applied, has satisfactory abrasion resistance. The proportion occupied by spherical particles having a sphericity of 0.5 or greater in the inorganic porous material is preferably at least 70%, and more preferably at least 90%. The sphericity may also be measured based on photographs taken using a scanning electron microscope. In that case, it is preferable to take photographs at a magnification which allows at least about 100 particles to appear on the monitor screen. Although the values of D₁ and D₂ are measured based on photographs, it is preferable to process the photographs using an apparatus for digitalization such as a scanner, and then to perform data processing using an image analysis software.

According to the invention, the inorganic porous material is preferably composed of regular polyhedral particles. The regular polyhedral particles according to the invention are meant to include a regular polyhedron having at least four sides, and a particle approximating a regular polyhedron. The “particle approximating a regular polyhedron” is defined as a particle for which the ratio between the diameter D₃ of the smallest sphere which completely circumscribes the particle under consideration, and the diameter D₄ of the largest sphere which completely inscribes the particle (that is, D₃/D₄), is 1 to 3, preferably 1 to 2, and more preferably L to 1.5. A polyhedral particle having an indefinitely large number of strokes is a spherical particle. The aforementioned value of D₃/D₄ may also be measured based on photographs taken using a scanning electron microscope, in the same manner as for the sphericity.

Furthermore, the inorganic porous material used in the invention preferably has a standard deviation for the particle size distribution of 10 μm or less, more preferably 5 μm or less, and even more preferably 3 μm or less. The standard deviation of the particle size distribution is preferably 80% or less, more preferably 60% or less, and even more preferably 40% or less, of the number average particle size. In the particle size distribution of the inorganic porous material, if the standard deviation is 10 μm or less and is 80% or less of the number average particle size, it implies that particles having large particle sizes are not incorporated therein.

Since the thixotropic properties of the resin composition are prevented from undergoing an extreme increase by suppressing the presence of particles having much larger particle sizes than the number average particle size, production of sheet-like or cylindrical molded objects may also be easily achieved. In the case of molding a resin composition using an extruder, when a resin composition having extremely high thixotropic properties is used, there occur process-related problems such as that it is required to set the temperature high in order to fluidize the resin composition, and since the torque exerted on the axis until the resin begins to move is increased, the load exerted on the apparatus is increased. There is also a problem that it requires a lot of time to remove the air bubble in the resin composition. Furthermore, when an inorganic porous material having a narrow particle size distribution is used, an effect of enhancing the abrasion resistance of a resin molded product obtained from the resin composition may also be obtained. In this regard, it is speculated to be because, when particles having a large particle size distribution are used, this implies an increase in the probability of particles having large particle sizes being incorporated, and thus incorporation of particles having large particle sizes makes it easier for the particles exposed at the surface of the printing plate, to escape from the surface. In particular, when the probability of the presence of particles having large particle sizes of greater than 10 μm increases, the tendency described above becomes more conspicuous.

Furthermore, although the reasons are not clear, when an inorganic porous material having a small standard deviation in the particle size distribution is used, an enhancement of notch property may be observed upon the application of the resin composition of the invention to a relief printing plate precursor for laser engraving. Here, the notch property is defined such that when a cut of a certain depth is inserted using a cutter on a printing plate precursor having a certain thickness and a certain width, and the printing plate precursor is bent along the cut part in a direction of 180° so that the cut comes to the outer side, the retention time taken until the printing plate precursor is completely broken off is designated as the notch property. Therefore, a printing plate precursor having high notch property implies that the aforementioned retention time is long, and a printing plate having high notch property has fewer occurrences of defects such as cracks in the micropattern. An excellent printing plate precursor has a retention time of 10 seconds or longer, more preferably 20 seconds or longer, and even more preferably 40 seconds or longer, in the evaluation of notch property.

The inorganic porous material according to the invention may also allow incorporation of organic coloring matters such as pigments and dyes, which absorb light at the wavelengths of laser light, into the pores or voids of the porous material. The surface of the inorganic porous material is subjected to a surface modification treatment by coating the surface with a silane coupling agent, a titanium coupling agent or other organic compounds, and thereby the porous material may be turned into more hydrophilized or hydrophobized particles.

As for the inorganic porous material according to the invention, commercially available products may also be used. Examples of commercially available products include SYLOSPHERE C-1504, SYLYSIA 350, SYLYSIA310P, SYLYSIA 710, SYLYSIA 730, SYLYSIA 250N, SYLOPHOBIC 702, SYLOMASK 52, SYLOMASK 55 (trade names, all manufactured by Fuji Silysia Chemical Ltd.), CURPLEX #80, CURPLEX #67, CURPLEX# 1120, CURPLEX FPS-1, CURPLEX FPS-2, CURPLEX FPS-3, CURPLEX FPS-5, CURPLEX BS-321 BF (trade names, all manufactured by DSL Japan Co., Ltd.), MICLOID ML-367, MICLOID ML-386, MICLOID ML-836 (trade names, all manufactured by Tokai Chemical Industry Co., Ltd.), SUNSPHERE H-31, SUNSPHERE H-32, SUNSPHERE H-51-ET, SUNSPHERE H-52-ET (trade names, all manufactured by AGC Si-Tech Co., Ltd.), and the like.

The inorganic porous material contained in the resin composition of the invention may be composed solely of one species, or may also be composed of two or more species in combination.

The content of the inorganic porous material in the resin composition of the invention is preferably from 0.01% by mass to 60% by mass, more preferably from 0.05% by mass to 40% by mass, and even more preferably from 0.1% by mass to 20% by mass, with respect to the total content of solids contained in the resin composition.

(B) Binder Polymer

The resin composition of the invention contains a binder polymer. The binder polymer is a main component contained in the resin composition for laser engraving, and from the viewpoint of recording sensitivity to laser light, a thermoplastic resin, a thermoplastic elastomer or the like may be used in accordance with the purpose. For example, in the case of using the binder polymer for the purpose of curing by heating or exposure to thereby enhance the strength, a polymer having a carbon-carbon unsaturated bond in the molecule is selected as the binder polymer. In the case where formation of a pliable film with flexibility is regarded as the purpose, a soft resin or a thermoplastic elastomer is selected.

In the case of applying the resin composition for laser engraving to a relief forming layer in the relief printing plate precursor for laser engraving, it is preferable to use an alcoholphilic polymer from the viewpoints of ease in the production of the composition for relief forming layer, and enhancement of resistance to oily inks in the resulting relief printing plates. Furthermore, a polymer including a partial structure which thermally degrades by exposure or heating during engraving is preferable, from the viewpoint of laser engraving sensitivity.

As such, binder polymers pursuant to the purpose may be selected while properties suited to the application uses of the resin composition for laser engraving are taken into consideration, and the binder polymers may be used singly, or in combination of two or more species thereof.

As for the binder polymer that is contained in the resin composition of the invention, polymers having a glass transition temperature (° C.) of from 20° C. to 200° C. are preferable, polymers having a glass transition temperature of from 20° C. to 150° C. are more preferable, and polymers having a glass transition temperature of from 25° C. to 120° C. are even more preferable.

Suitable examples of the binder polymer according to the invention include at least one selected from the group consisting of a polyester, a polyurethane, a polyvinyl butyral, a polyvinyl alcohol, and a polyamide.

The total amount of the binder polymer in the resin composition of the invention is preferably from 1% by mass to 99% by mass, and more preferably from 5% by mass to 80% by mass, with respect to the total solid content of the composition.

As for the binder polymer that is contained in the resin composition of the invention, more preferable polymers include (A) a binder polymer which is insoluble in water but soluble in an alcohol having 1 to 4 carbon atoms (hereinafter, may also be referred to as “binder (A)”), and (B) at least one polyester selected from the group consisting of polyesters including a hydroxycarboxylic acid unit, and derivatives thereof, polycaprolactone (PCL) and derivatives thereof, poly(butylenesuccinic acid) and derivatives thereof (hereinafter, may also be referred to as “binder (B)”).

Hereinafter, these binder (A) and binder (B) will be explained.

Binder (A)

The binder (A), which is one of a suitable binder polymer for the resin composition of the invention, is a binder polymer which is insoluble in water but soluble in an alcohol having 1 to 4 carbon atoms.

This binder (A) is a polymer having a structure different from that of the binder (B) described later.

The binder (A) according to the invention has a characteristic being highly polar but water-insoluble, so that when the resin composition of the invention is used in a relief forming layer in the relief printing plate precursor, both aqueous ink suitability and UV ink suitability may be achieved.

Hereinafter, the alcohol having 1 to 4 carbon atoms may be referred to as lower alcohol.

While the action mechanism caused by the use of the binder (A) is unclear, if a relief printing plate precursor, which is a suitable embodiment of application of the resin composition of the invention, is taken as an example, the mechanism is supposed be as follows.

Since the binder (A) is water-insoluble, its suitability for aqueous ink is enhanced, and the binder swells in the aqueous ink during printing so that the binder may prevent low molecular weight components in the relief layer from bleeding out, and thus prevent the film strength from being decreased. Furthermore, since the binder (A) is soluble in alcohol, the alcohol molecules in the solvent that is used at the time of forming a relief forming layer have high affinity to this binder (A). As a result, it is supposed that the chain-like structure of the binder (A) may be broken down; that is, voids at the molecular level may be effectively formed in the polymer structure. Thereby, it becomes easy for the components for combined use that are contained in the relief forming layer to penetrate into the broken-down parts of the binder (A) as described above, that is, the voids at the molecular level, and a homogeneous relief forming layer in which the binder (A) and other components are mixed at the molecular level may be obtained. Thus, it is supposed that, as a result, the binder (A) imparts properties whereby such a relief forming layer is less likely to be subject to damage attributable to penetration of various inks, as compared to films that are not homogeneous at the molecular level.

Herein, in the invention, the term “insoluble” in a predetermined liquid refers to that when 0.1 g of a binder polymer and 2 ml of a predetermined liquid (e.g. water or organic solvent) are mixed, sealed, allowed to stand at room temperature for 24 hours, and observed visually, precipitation of the binder polymer is recognized, or precipitation is not recognized but the solution (dispersion) is cloudy. The term “soluble” refers to the case where, under the above condition, when observed visually, there is no precipitate, and a transparent and uniform state is given.

The binder (A) in the invention is required to be soluble in an alcohol having 1 to 4 carbon atoms. Examples of the alcohol having 1 to 4 carbon atoms include methanol, ethanol, 2-propanol, 1-propanol, 1-methoxy-2-propanol, 1-butanol, and tert-butanol from a viewpoint of good UV ink suitability. The binder (A) is preferably soluble in at least one of these alcohols.

The binder (A) is more preferably soluble in at least one of methanol, ethanol, 2-propanol, and 1-methoxy-2-propanol, and particularly soluble in all of methanol, ethanol, and 1-methoxy-2-propanol.

When the binder (A) which is insoluble in the ester solvent is selected, UV ink suitability of the invention is further improved. Thereby, a phenomenon of elution of low molecular components from the relief layer due to swelling of the relief layer by a UV ink during printing can be suppressed so that the deterioration of the film strength of the relief forming can be prevented.

The glass transition temperature of the binder (A) is preferably from 20° C. to 200° C., more preferably from 20° C. to 170° C., particularly preferably from 25° C. to 150° C. from a viewpoint of balance between an engraving sensitivity and film forming property.

In the invention, a glass transition temperature (Tg) of room temperature or higher refers to a Tg of 20° C. or higher.

In the case where the binder (A) which may be used in the invention has the above range of the glass transition temperature, when the polymer is combined with (E) a photothermal conversion agent described later, which is a preferable additional component for constituting the relief forming layer in the invention, and which may absorb light having a wavelength of 700 nm to 1300 nm, an engraving sensitivity is improved. The binder polymer having such a glass transition temperature is referred to as “non-elastomer”, hereinafter.

That is, the elastomer is generally academically defined as a polymer having a glass transition temperature of a normal temperature or lower (see, Kagaku Daijiten second edition, edited by Foundation for Advancement of International Science, published by Maruzen, p. 154). Therefore, the non-elastomer refers to a polymer having a glass transition temperature higher than a normal temperature.

When a glass transition temperature of the binder (A) is room temperature (20° C.) or higher, since the binder (A) has a glass state at a normal temperature, the binder (A) is in the state where thermal molecular movement is considerably suppressed as compared with the case where the binder (A) has a rubber state.

In laser engraving on the relief printing plate precursor of the invention, at laser irradiation (preferably, at infrared laser irradiation), applied heat and heat produced by the function of a (E) photothermal conversion agent optionally used are transmitted to the binder (A) at the periphery, and this is thermally decomposed and dissipated and, as a result, engraved to form a concave portion.

In a preferable embodiment of the invention, it is thought that when the (E) photothermal conversion agent is present in the state where thermal molecular movement of the binder (A) is suppressed, heat transmission to, and thermal decomposition of the binder (A) effectively occur, and it is presumed that an engraving sensitivity has been further increased due to such an effect.

On the other hand, in the state (rubber state) where the glass transition temperature is lower than room temperature and thermal molecular movement of the binder (A) is not suppressed, since due to an intensity of its vibration, that is, thermal molecular movement, an intermolecular distance between the (E) photothermal conversion agent and the binder (A) becomes great, and a volume (space) present between them becomes very great, it is presumed that not only an efficacy of heat transmission from the (E) photothermal conversion agent to the binder (A) is reduced, but also the transmitted heat contributes to active thermal movement, heat loss is generated, and contribution to occurrence of effective thermal decomposition is decreased, and thereby, it is difficult to contribute to improvement in an engraving sensitivity.

From the foregoing, specific examples of the non-elastomer which are particularly preferable embodiments of the binder (A) preferably used in the invention are as follows.

Examples of the particularly preferable binder (A) in the invention include a polyvinyl butyral (PVB) derivative, an alcohol-soluble polyamide, a cellulose derivative, and an acrylic resin, from a viewpoint of that both of aqueous ink suitability and UV ink suitability are realized, and an engraving sensitivity is high, and film forming property is also good.

(1) Polyvinyl Butyral and Derivatives Thereof.

As polyvinyl butyral (hereinafter, referred to as PVB), a homopolymer may be used, or a polyvinyl butyral derivative may be used.

A content of butyral in the PVB derivative (total mole number of raw material monomer is 100%) is preferably 30% to 90%, more preferably 50% to 85%, particularly preferably 55% to 78%.

From a viewpoint that balance between an engraving sensitivity and film forming property is retained, a weight average molecular weight of PVB and a derivative thereof is preferably 5000 to 800000, more preferably 8000 to 500000. Further, from a viewpoint of improvement in the rinsing property of an engraving residue, 50000 to 300000 is particularly preferable.

PVB and a derivative thereof are also available as a commercialized product, and preferable examples, from a viewpoint of alcohol solubility (particularly, ethanol), include “ESLEC B” Series, “ESLEC K (KS)” Series manufactured by Sekisui Chemical Co., Ltd., and “Denka Butyral” manufactured by Denki Kagaku Kogyo Co., Ltd. From a viewpoint of alcohol solubility (particularly ethanol), further preferable are “ESLEC B” Series manufactured by Sekisui Chemical Co., Ltd. and “Denka Butyral” manufactured by Denki Kagaku Kogyo Co., Ltd., and particularly preferable are “BL-1”, “BL-1H”, “BL-2”, “BL-5”, “BL-S”, “BX-L”, “BM-S”, “BH-S” in “ESLEC B” Series manufactured by Sekisui Chemical Co., Ltd., and “#3000-1”, “#3000-2”, “#3000-4”, “#4000-2”, “#6000-C”, “#6000-EP”, “#6000-CS”, “#6000-AS” in “Denka Butyral” manufactured by Denki Kagaku Kogyo Co., Ltd.

When a film of the relief forming layer, which is formed by applying the resin composition of the invention, is made using PVB as the binder (A), a method of casting and drying a solution of the polymer dissolved in a solvent is preferable from a viewpoint of smoothness of a surface of a film.

(2) Alcohol-Soluble Polyamide

Since a polyamide in which a polar group such as polyethylene glycol and piperazine is introduced into a main chain improves alcohol solubility due to working of the polar group, it is suitable as the binder (A) used in the invention.

By reacting ε-caprolactam and/or adipic acid with polyethylene glycol having both terminals modified with amine, a polyamide having a polyethylene glycol unit (also called polyethylene oxide segment) is obtained and, by reacting this with piperazine, a polyamide having a piperazine skeleton is obtained.

As a polyamide containing a polyethylene glycol unit, usually, polyether amide obtained by polycondensing or copolycondensing α•ω-diaminoproplypolyoxyethylene as at least a part of a raw material diamine component by the known method (e.g. JP-A No. 55-79437), or polyether ester amide obtained by polycondensing or copolycondensing polyethylene glycol as at least a part of a raw material diol component by the known method (e.g. JP-A No. 50-159586) is used without any limitation, and a polymer having an amide bond in a main chain may be widely used.

Herein, a number average molecular weight of the polyethylene oxide segment in a polyamide is preferably in the range of 150 to 5000, more preferably in the range of 200 to 3000 from a viewpoint of the form retainability of the relief forming layer. A number average molecular weight of these polyamides having the polyethylene oxide segment is preferably in the range of 5000 to 300000, further preferably in the range of 10000 to 200000, particularly preferably in the range of 10000 to 50000.

As the polyamide, a polyamide having a highly polar unit such as polyethylene oxide in a main chain is preferably used, but since even when a side chain of a polyamide has a highly polar functional group, the same function may be obtained, a polyamide having a polar group in a side chain is also suitable in the binder (A) in the invention.

From a viewpoint of an engraving sensitivity, more preferable is the case where a side chain of a polyamide has a highly polar functional group. As such a polyamide, specifically, methoxymethylated polyamide, and methoxymethylated nylon are preferable. As a commercialized product of such a polyamide derivative, a methoxymethylated polyamide “TORESIN” Series manufactured by Nagase Chemtex is preferable. Particularly preferable is a methoxymethylated polyamide “TORESIN F-30K”, and “TORESIN EF-30T” manufactured by Nagase Chemitex.

(3) Cellulose Derivative

Usual cellulose is hardly dissolved in water and an alcohol, but water- or solvent-solubility may be controlled by modifying remaining OH of a glucopyranose unit with a specified functional group, and a cellulose derivative which is thus insoluble in water, but is made to be soluble in an alcohol having 1 to 4 carbon atoms is also suitable as the binder (A) used in the invention.

Examples of the cellulose derivative suitable in the invention include alkylcellulose such as ethylcellulose and methylcellulose, hydroxyethylenecellulose, hydroxypropylenecellulose, and cellulose acetate butyrate, which have physical property of being water-insoluble and lower alcohol-soluble.

Further, specific examples thereof include Metholose Series manufactured by Shin-Etsu Chemical Co., Ltd. This series is such that a part of a hydrogen atom of a hydroxy group of cellulose is replaced with a methyl group (—CH₃), a hydroxypropyl group (—CH₂CHOHCH₃), or a hydroxyethyl group (—CH₂CH₂OH).

In addition, in the invention, particularly preferable in solubility in a lower alcohol and an engraving sensitivity is alkylcellulose, inter alia, ethylcellulose and methylcellulose.

(4) Epoxy Resin

As a water-insoluble and alcohol-soluble epoxy resin which may be used in the invention, a modified epoxy resin in which a bisphenol A-type epoxy resin or a bisphenol A-type epoxy resin is high-molecularized or highly functionalized with a modifying agent is preferable from a viewpoint of water-insolubility. Particularly preferable is a modified epoxy resin.

Preferable examples of the modified epoxy resin include “Arakyd 9201N”, “Arakyd 9203N”, “Arakyd 9205”, “Arakyd 9208”, “KA-1439A”, “MODEPICS 401”, and “MODEPICS 402” manufactured by Arakawa Chemical Industries Ltd.

As the binder (A) in the invention, an acryl resin and polyurethane as shown below may be preferably used as far as they are water-insoluble and lower alcohol-soluble.

(5) Acrylic Resin

As the binder (A) in the invention, a water-insoluble and lower alcohol-soluble acryl resin may be also used.

As such an acryl resin, an acryl resin obtained by using the known acryl monomer, solubility of which has been controlled so as to satisfy the aforementioned physical conditions, may be used. As an acryl monomer used in synthesizing an acryl resin, for example, (meth)acrylic acid esters, and crotonic acid esters, (meth)acrylamides are preferable. Examples of such a monomer include the following compounds.

That is, examples of (meth)acrylic acid esters include methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, n-hexyl (meth)acrylate, 2-ethylhexyl (meth)acrylate, acetoxyethyl (meth)acrylate, phenyl (meth)acrylate, 2-hydroxyethyl (meth)acry late, 2-hydroxypropyl (meth)acrylate, 4-hydroxybutyl (meth)acry late, 2-methoxyethyl (meth)acry late, 2-ethoxyethyl (meth)acrylate, 2-(2-methoxyethoxy)ethyl (meth)acrylate, cyclohexyl (meth)acrylate, benzyl (meth)acrylate, diethylene glycol monomethyl ether (meth)acrylate, diethylene glycol monoethyl ether (meth)acrylate, diethylene glycol monophenyl ether (meth)acrylate, triethylene glycol monomethyl ether (meth)acrylate, triethylene glycol monoethyl ether (meth)acrylate, dipropylene glycol monomethyl ether (meth)acry late, polyethylene glycol monomethyl ether (meth)acry late, polypropylene glycol monomethyl ether (meth)acrylate, monomethyl ether (meth)acrylate of a copolymer of ethylene glycol and propylene glycol, N,N-dimethylaminoethyl (meth)acrylate, N,N-diethylaminoethyl (meth)acrylate, and N,N-dimethylaminopropyl (meth)acrylate.

From a viewpoint of alcohol solubility, diethylene glycol monomethyl ether (meth)acrylate, diethylene glycol monoethyl ether (meth)acrylate, diethylene glycol monophenyl ether (meth)acrylate, triethylene glycol monomethyl ether (meth)acrylate, triethylene glycol monoethyl ether (meth)acrylate, dipropylene glycol monomethyl ether (meth)acrylate, polyethylene glycol monomethyl ether (meth)acrylate, polypropylene glycol monomethyl ether (meth)acrylate, and monomethyl ether (meth)acrylate of a copolymer of ethylene glycol and propylene glycol are preferable.

Examples of crotonic acid esters include butyl crotonate, and hexyl crotonate.

Examples of (meth)acrylamides include (meth)acrylamide, N-methyl(meth)acrylamide, N-ethyl(meth)acrylamide, N-propyl(meth)acrylamide, N-n-butyl(meth)acrylamide, N-tert-butyl(meth)acrylamide, N-cyclohexyl(meth)acrylamide, N-(2-methoxyethyl)(meth)acrylamide, N,N-dimethyl(meth)acrylamide, N,N-diethyl(meth)acrylamide, N-phenyl(meth)acrylamide, N-benzyl(meth)acrylamide, and (meth)acryloylmorpholine.

As the acryl resin, a modified acryl resin containing an acryl monomer having a urethane group or a urea group may be also preferably used.

Examples of an acryl monomer used in synthesis of an acryl resin used as the binder (A) include compounds such as the following exemplified monomers (AM-1) to (AM-22).

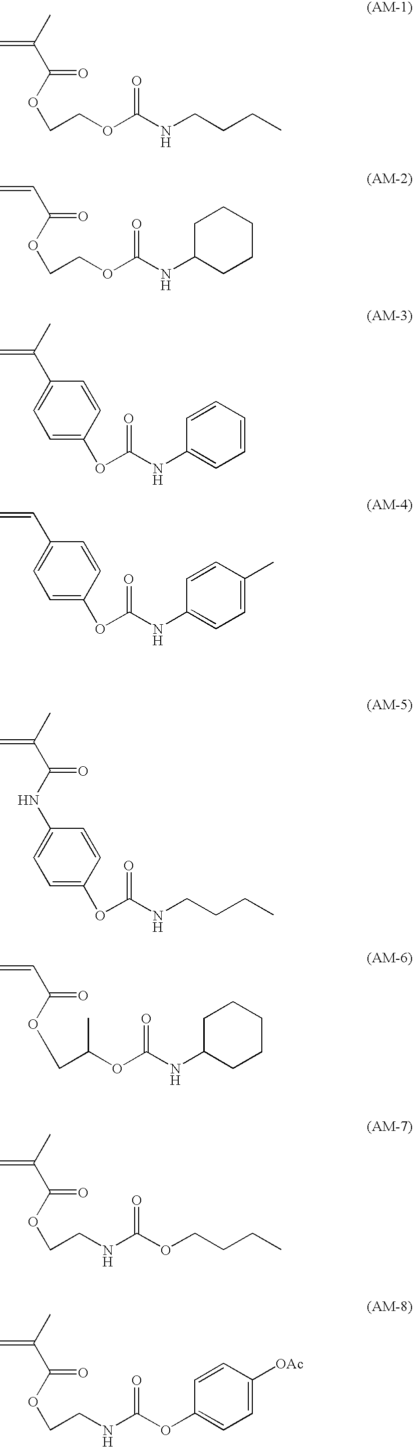

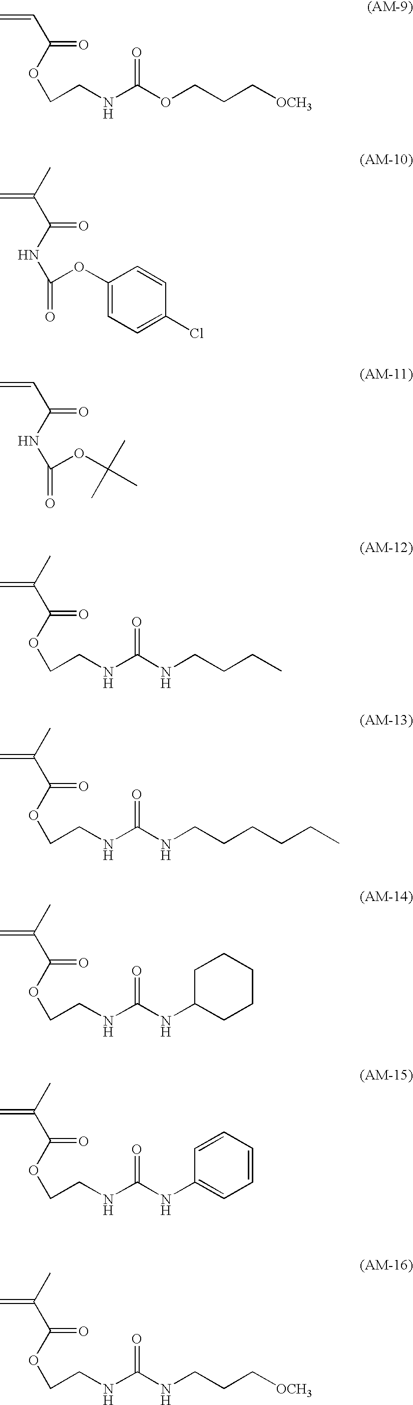

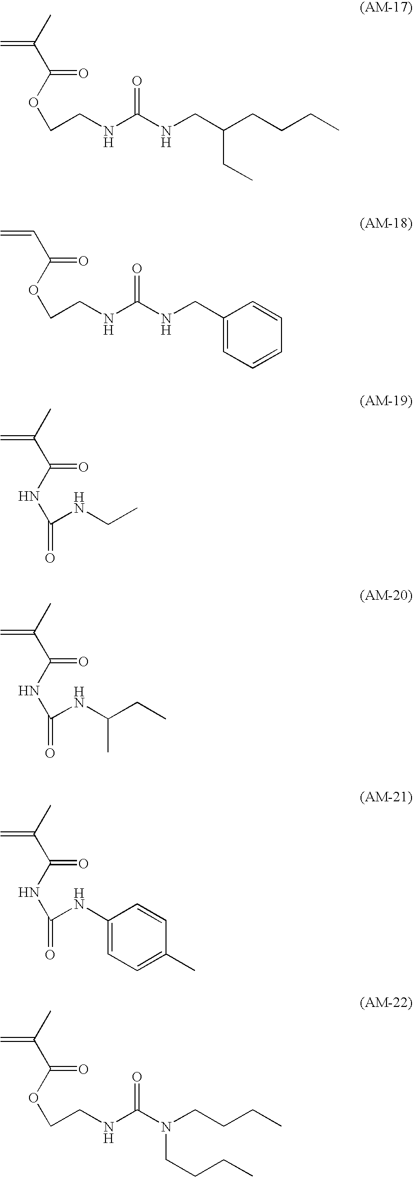

Examples of the acryl resin which may be suitably used as the binder (A) are shown below together with a weight average molecular weight measured by the GPC method [described as Mw (GPC)], but the acryl resin which may be used in the invention is not limited to them as far as it has the aforementioned preferable properties.

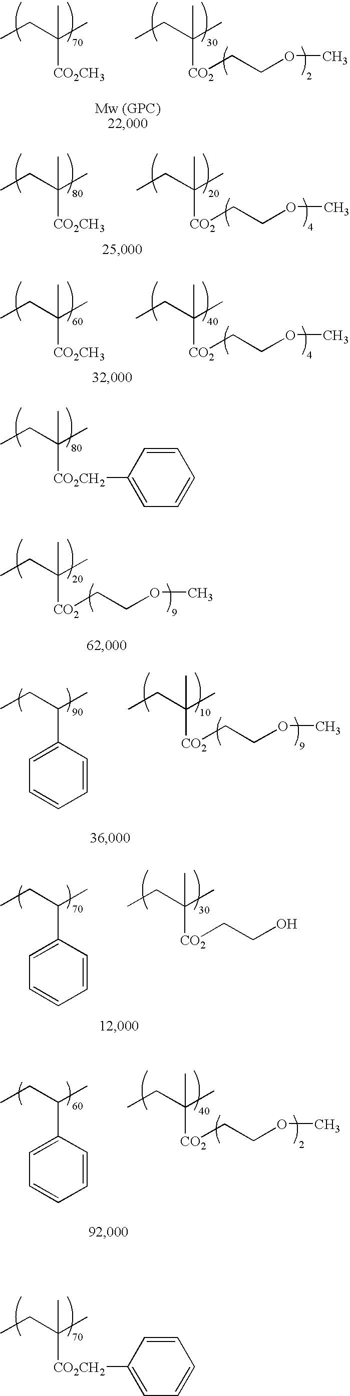

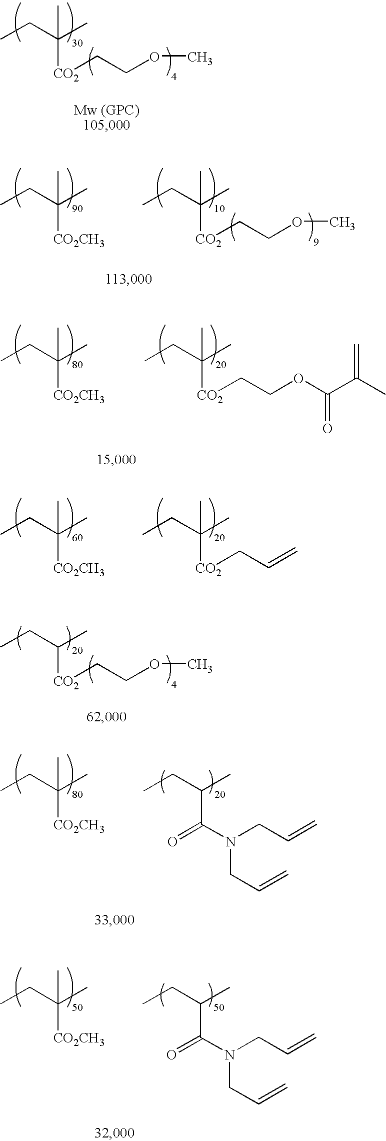

(6) Polyurethane Resin

As the binder (A) a water-insoluble and lower alcohol-soluble polyurethane resin may be also used.

A polyurethane resin which may be used as the specified alcoholphilic polymer in the invention is a polyurethane resin having, as a fundamental skeleton, a structural unit which is a reaction product of at least one kind of a diisocyanate compound represented by the following Formula (U-1), and at least one kind of a diol compound represented by the following Formula (U-2).

OCN—X⁰—NCO (U-1)

HO—Y⁰—OH (U-2)

In Formulae (U-1) and (U-2), X⁰ and Y⁰ each represent independently a divalent organic residue, provided that at least one of organic residues represented by X⁰ and Y⁰ is linked to a NCO group or an OH group through an aromatic group.

Diisocyanate Compound

It is preferable that in a diisocyanate compound represented by Formula (U-1), an organic residue represented by X⁰ contains, in a structure, an aromatic group directly linked to a NCO group.

A preferable diisocyanate compound is a diisocyanate compound represented by the following Formula (U-3).

OCN-L¹-NCO (U-3)

In Formula (U-3), L¹ represents a divalent aromatic hydrocarbon group optionally having a substituent. Examples of the substituent include an alkyl group, an aralkyl group, an aryl group, an alkoxy group, an aryloxy group, and a halogen atom (—F, —Cl, —Br, —I). If necessary, L¹ may have other functional group which does not react with an isocyanate group, for example, an ester group, a urethane group, an amido group, and a ureido group.

Examples of the diisocyanate compound represented by Formula (U-3) include the following compounds.

That is, examples of the aromatic diisocyanate compound include 2,4-tolylene diisocyanate, 2,4-tolylene diisocyanate dimer, 2,6-tolylenedilene diisocyanate, p-xylylene diisocyanate, m-xylylene diisocyanate, 4,4′-diphenylmethane diisocyanate, 1,5-naphthylene diisocyanate, and 3,3′-dimethylbiphenyl-4,4′-diisocyanate.

Particularly, from a viewpoint of thermal decomposability, 4,4′-diphenylmethane diisocyanate, and 1,5-naphthylene diisocyanate are preferable.

The polyurethane resin used as the binder (A) may be a polymer synthesized by using a diisocyanate compound other than the aforementioned diisocyanate compounds, for example, from a viewpoint that compatibility with other components in the resin composition is improved, and storage stability is improved.

Examples of the diisocyanate compound which may be used together include aliphatic diisocyanate compounds such as hexamethylene diisocyanate, trimethylhexamethylene diisocyanate, lysine diisocyanate, and dimer acid diisocyanate; alicyclic diisocyanate compounds such as isophorone diisocyanate, 4,4′-methylene bis(cyclohexylisocyanate), methylcyclohexane-2,4 (or 2,6) diisocyanate, 1,3-(isocyanatemethyl)cyclohexane; and diisocyanate compounds which are a reaction product of diol and diisocyanate, such as an adduct of 1 mol of 1,3-butylene glycol and 2 mol of tolylene diisocyanete.

Diisocyanate obtained by adding a monofunctional alcohol to one of three NCOs of triisocyanate may be also used.

Diol Compound

It is preferable that in the diol compound represented by Formula (U-2), an organic residue represented by Y⁰ contains, in a structure, an aromatic group directly linked to an OH group.

More specifically, diol compounds represented by the following formulas (A-1) to (A-3) are preferable.

HO—Ar¹—OH Formula (A-1)

HO—(Ar¹—Ar²)ₘ—OH Formula (A-2)

HO—Ar¹—X—Ar²—OH Formula (A-3)

In Formulae (A-1) to (A-3), Ar¹ and Ar² may be the same or different, and each represent an aromatic ring. Examples of such an aromatic ring include a benzene ring, a naphthalene ring, an anthracene ring, a pyrene ring, and a heterocyclic ring. These aromatic rings may have a substituent. Examples of the substituent include an alkyl group, an aralkyl group, an aryl group, an alkoxy group, an aryloxy group, and a halogen atom (—F, —Cl, —Br, —I).

From a viewpoint of easy availability of a raw material, preferable is a benzene ring and a naphthalene ring. Also in view of film forming property, a benzene ring is particularly preferable.

X is a divalent organic residue. And, m is preferably 1 to 3, particularly preferably 1, from a viewpoint of film forming property.

Preferable examples of the diol compound represented by Formula (A-1) are 1,4-dihydroxybenzene, and 1,8-dihydroxynaphthalene.

Preferable examples of the diol compound represented by Formula (A-2) are 4,4-dihydroxybiphenyl, and 2,2-hydroxybinaphthyl.

Preferable examples of the diol compound represented by Formula (A-3) are bisphenol A, and 4,4-bis(hydroxyphenyl)methane.

The polyurethane resin used as the binder (A) in the invention may be a polymer synthesized by using an additional diol compound other than the aforementioned diol compounds, for example, from a viewpoint that compatibility with other components in the resin composition is improved, and storage stability is improved.

Examples of the diol compound which may be used together include a polyether diol compound, a polyester diol compound, and a polycarbonate diol compound.

Examples of the polyether diol compound include compounds represented by the following formulas (U-4), (U-5), (U-6), (U-7), and (U-8), and a random copolymer of ethylene oxide and propylene oxide having hydroxyl groups at the terminal positions.

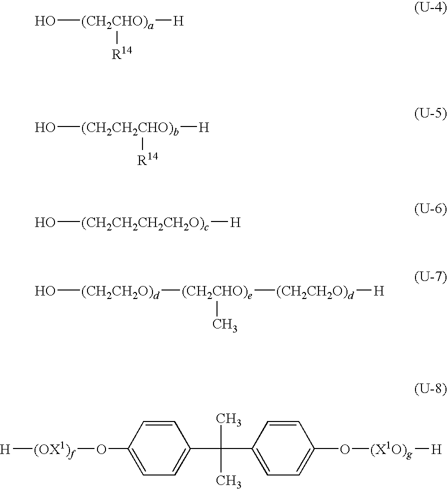

In Formulae (U-4) to (U-8), R¹⁴ represents a hydrogen atom or a methyl group, and X¹ represents the following groups. And, a, b, c, d, e, f, and g each indicate independently an integer of 2 or more, preferably an integer of 2 to 100.

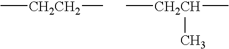

Examples of the polyether diol compounds represented by Formulae (U-4) and (U-5) include the following compounds.

That is, examples thereof include diethylene glycol, triethylene glycol, tetraethylene glycol, pentaethylene glycol, hexaethylene glycol, heptaethylene glycol, octaethylene glycol, di-1,2-propylene glycol, tri-1,2-propylene glycol, tetra-1,2-propylene glycol, hexa-1,2-propylene glycol, di-1,3-propylene glycol, tri-1,3-propylene glycol, tetra-1,3-propylene glycol, di-1,3-butylene glycol, tri-1,3-butylene glycol, hexa-1,3-butylene glycol, polyethylene glycol having a weight average molecular weight of 1000, polyethylene glycol having a weight average molecular weight of 1500, polyethylene glycol having a weight average molecular weight of 2000, polyethylene glycol having a weight average molecular weight of 3000, polyethylene glycol having a weight average molecular weight of 7500, polypropylene glycol having a weight average molecular weight of 400, polypropylene glycol having a weight average molecular weight of 700, polypropylene glycol having a weight average molecular weight of 1000, polypropylene glycol having a weight average molecular weight of 2000, polypropylene glycol having a weight average molecular weight of 3000, and polypropylene glycol having a weight average molecular weight of 4000.

Examples of the polyether diol compound represented by Formula (U-6) include the following compounds.

That is, examples thereof include PTMG650, PTMG1000, PTMG2000, and PTMG3000 (trade name) manufactured by Sanyo Chemical Industries, Ltd.

Further, examples of the polyether diol compound represented by Formula (U-7) include the following compounds.

That is, examples thereof include New Pole PE-61, New Pole PE-62, New Pole PE-64, New Pole PE-68, New Pole PE-71, New Pole PE-74, New Pole PE-75, New Pole PE-78, New Pole PE-108, New Pole PE-128, New Pole PE-61 (trade name) manufactured by Sanyo Chemical Industries, Ltd.

Examples of the polyether diol compound represented by Formula (U-8) include the following compounds.

That is, examples thereof include New Pole BPE-20, New Pole BPE-20F, New Pole BPE-20NK, New Pole BPE-20T, New Pole BPE-20G, New Pole BPE-40, New Pole BPE-60, New Pole BPE-100, New Pole BPE-180, New Pole BPE-2P, New Pole BPE-23P, New Pole BPE-3P, and New Pole BPE-5P (trade name) manufactured by Sanyo Chemical Industries, Ltd.

Examples of the random copolymer of ethylene oxide and propylene oxide having hydroxy groups at the terminal positions include the following copolymers.

That is, examples thereof include New Pole 50HB-100, New Pole 50HB-260, New Pole 50HB-400, New Pole 50HB-660, New Pole 50HB-2000, and New Pole 50HB-5100 (trade name) manufactured by Sanyo Chemical Industries, Ltd.

Examples of the polyester diol compound include compounds represented by the following formulas (U-9), and (U-10).

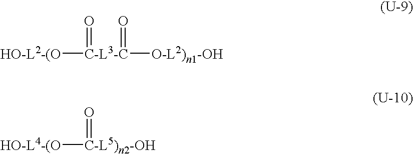

In Formulae (U-9) and (U-10), L², L³, and L⁴ may be the same or different, and each represent a divalent aliphatic or aromatic hydrocarbon group, and L⁵ represents a divalent aliphatic hydrocarbon group. Preferably, L² to L⁴ each represent independently an alkylene group, an alkenylene group, an alkynylene group, or an allylene group, and L⁵ represents an alkylene group. In L² to L⁵, other functional group which does not react with an isocyanate group, for example, an ether group, a carbonyl group, an ester group, a cyano group, an olefin group, a urethane group, an amido group, a ureido group, or a halogen atom may be present. And, n1 and n2 are an integer of 2 or more, respectively, preferably represent an integer of 2 to 100.

Examples of the polycarbonate diol compound include a compound represented by Formula (U-11).

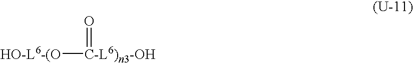

In Formula (U-11), two L⁶s may be the same or different, and each represent a divalent aliphatic or aromatic hydrocarbon group. Preferably, L⁶ represents an alkylene group, an alkenylene group, an alkynylene group, or an arylene group. In L⁶, other functional group which does not react with an isocyanate group, for example, an ether group, a carbonyl group, an ester group, a cyano group, an olefin group, a urethane group, an amido group, a ureido group, or a halogen atom may be present. And, n3 is an integer of 2 or more, preferably represents an integer of 2 to 100.

Examples of the diol compounds represented by Formula (U-9), (U-10), or (U-11) include the following compounds [exemplified compounds (No. 1) to (No. 18)]. In examples, n represents an integer of 2 or more.

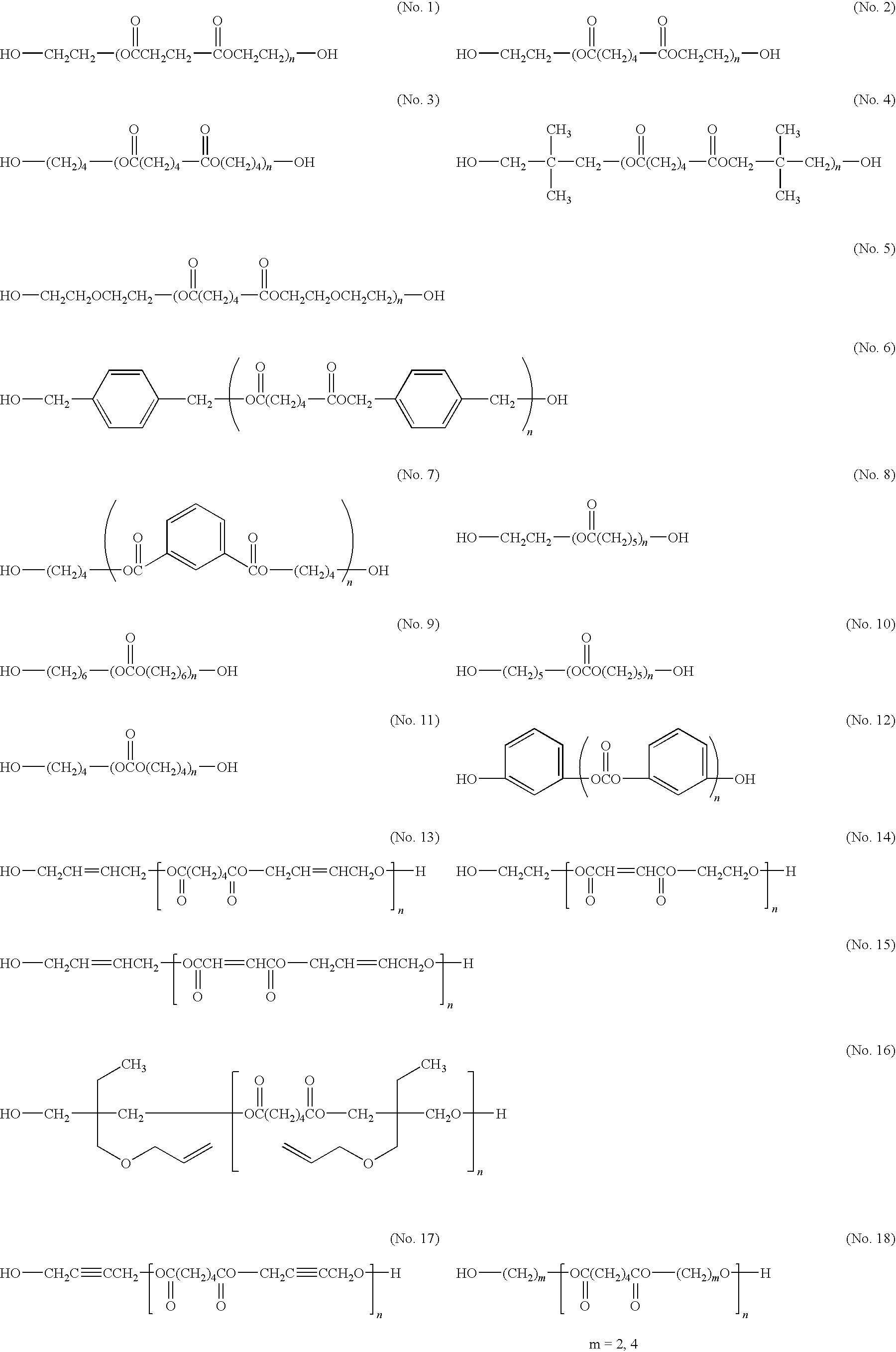

In addition, for synthesizing a polyurethane resin used as the binder (A), in addition to the aforementioned diol compounds, a diol compound having a substituent which does not react with an isocyanate group may be used together. Examples of such a diol compound include the following compounds.

That is, for example, compounds represented by the following formulas (U-12), and (U-13) are used.

HO-L⁷-O—CO-L⁸-CO—O-L⁷-OH (U-12)

HO-L⁸-CO—O-L⁷-OH (U-13)

In Formulae (U-12) and (U-13), L⁷ and L⁸ may be the same or different, and each represent a divalent aliphatic hydrocarbon group, aromatic hydrocarbon group or heterocyclic group, each optionally having a substituent (e.g. alkyl group, aralkyl group, aryl group, alkoxy group, aryloxy group, halogen atom (—F, —Cl, —Br, —I) etc.). If necessary, L⁷ and L⁸ may have other functional group which does not react with an isocyanate group, for example, a carbonyl group, an ester group, a urethane group, an amido group, and a ureido group. L⁷ and L⁸ may form a ring.

Further, for synthesizing a polyurethane resin used as the binder (A), a diol compound having an acid group such as a carboxyl group, a sulfone group, and a phosphoric acid group may be used together. Particularly, a diol compound having a carboxyl group is preferable from a viewpoint of improvement in a film strength, and water resistance due to a hydrogen bond.

Examples of the diol compound having a carboxyl group include, for example, compounds represented by the following formulas (U-14) to (U-16).

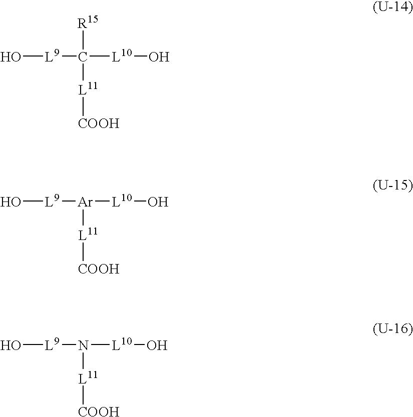

In Formulae (U-14) to (U-16), R¹⁵ represents a hydrogen atom, an alkyl group optionally having a substituent [e.g. cyano group, nitro group, halogen atom such as —F, —Cl, —Br, —I etc., —CONH₂, —COOR⁶, —OR¹⁶, —NHCONHR⁶, —NHCOOR⁶, —NHCOR¹⁶, —OCONHR¹⁶ (wherein R¹⁶ represents an alkyl group having 1 to 10 carbon atoms, or an aralkyl group having 7 to 15 carbon atoms) etc.], an aralkyl group, an aryl group, an alkoxy group, or an aryloxy group, preferably represents a hydrogen atom, an alkyl group having 1 to 8 carbon atoms, or an aryl group having 6 to 15 carbon atoms. L⁹, L¹⁰ and L¹¹ may be the same or different, and represent a single bond, or a divalent aliphatic or aromatic hydrocarbon group optionally having a substituent (for example, each group of alkyl, aralkyl, aryl, alkoxy, and halogeno is preferable), preferably represent an alkylene group having 1 to 20 carbon atoms, an arylene group having 6 to 15 carbon atoms, and further preferably represent an alkylene group having 1 to 8 carbon atoms. If necessary, L⁹ to L¹¹ may have other functional group which does not react with an isocyanate group, for example, a carbonyl group, an ester group, a urethane group, an amido group, a ureido group, or an ether group. Two or three of R⁵, L⁷, L8 and L⁹ may form a ring. Ar represents a trivalent aromatic hydrocarbon group optionally having a substituent, and preferably represents an aromatic group having 6 to 15 carbon atoms.

Examples of the diol compounds having a carboxyl group represented by Formulae (U-14) to (U-16) include the following compounds.

That is, examples of the diol compounds include 3,5-dihydroxybenzoic acid, 2,2-bis(hydroxymethyl)propionic acid, 2,2-bis(2-hydroxyethyl)propionic acid, 2,2-bis(3-hydroxypropyl)propionic aid, bis(hydroxymethyl)acetic acid, bis(4-hydroxyphenyl)acetic acid, 2,2-bis(hydroxymethyl)butyric acid, 4,4-bis(4-hydroxyphenyl)pentanoic acid, tartaric acid, N,N-dihydroxyethylglycine, and N,N-bis(2-hydroxyethyl)-3-carboxy-propionamide.

In addition, for synthesizing a polyurethane resin used as the binder (A), compounds obtained by ring-opening of tetracarboxylic acid dianhydrides represented by the following formulas (U-17) to (U-19) with a diol compound may be used together.

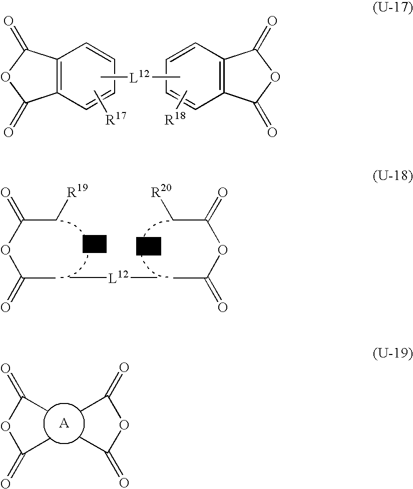

In Formulae (U-17) to (U-19), L¹² represents a single bond, a divalent aliphatic or aromatic hydrocarbon group optionally having a substituent (e.g. alkyl group, aralkyl group, aryl group, alkoxy group, halogeno group, ester group, and amido group are preferable), —CO—, —SO—, —SO₂—, —O—, or —S—, and preferably represents a single bond, a divalent aliphatic hydrocarbon group having 1 to 15 carbon atoms, —CO—, —SO₂—, —O—, or —S—. R¹⁷ and R¹⁸ may be the same or different, and represent a hydrogen atom, an alkyl group, an aralkyl group, an aryl group, an alkoxy group, or a halogeno group, and preferably represent a hydrogen atom, an alkyl group having 1 to 8 carbon atoms, an aryl group having 6 to 15 carbon atoms, an alkoxy group having 1 to 8 carbon atoms, or a halogeno group. Two of L¹², R¹⁷ and R¹⁸ may be linked to form a ring. R¹⁹ and R²⁰ may be the same or different, and represent a hydrogen atom, an alkyl group, an aralkyl group, an aryl group, or a halogeno group, and preferably represent a hydrogen atom, an alkyl group having 1 to 8 carbon atoms, or an aryl group having 6 to 15 carbon atoms. Two of L¹², R¹⁹ and R²⁰ may be linked to form a ring. L¹³ and L¹⁴ may be the same or different, and represent a single bond, a double bond, or a divalent aliphatic hydrocarbon group, and preferably represent a single bond, a double bond, or a methylene group. A represents a mononuclear or polynuclear aromatic ring, and preferably represents an aromatic ring having 6 to 18 carbon atoms.

Examples of the compounds represented by Formula (U-17), (U-18), or (U-19) include the following compounds.

That is, examples thereof include aromatic tetracarboxylic dianhydrides such as pyromellitic dianhydride, 3,3′,4,4′-benzophenonetetracarboxylic dianhydride, 3,3′40,4,4′-biphenyltetracarboxylic dianhydride, 2,3,6,7-naphthalenetetracarboxylic dianhydride, 1,4,5,8-naphthalenetetracarboxylic dianhydride, 4,4′-sulfonyldiphthalic dianhydride, 2,2-bis(3,4-dicarboxyphenyl)propane dianhydride, bis(3,4-dicarboxyphenyl)ether dianhydride, 4,4′-[3,3′-(alkylphosphoryidiphenylene)-bis(iminocarbonyl)]diphthalic dianhydride, an adduct of hydroquinonediacetate and trimellic anhydride, and an adduct of diacetyldiamine and trimellic anhydride; alicyclic tetracarboxylic dianhydrides such as 5-(2,5-dioxotetrahydrofuryl)-3-methyl-3-cyclohexyl-1,2-dicarboxylic anhydride (trade name: EPICHLONE B-4400, manufactured by Dainippon Ink and Chemicals Inc.), 1,2,3,4-cyclopentanetetracarboxylic dianhydride, 1,2,4,5-cyclohexanetetracarboxylic dianhydride, and tetrahydrofurantetracarboxylic dianhydride; and aliphatic tetracarboxylic dianhydrides such as 1,2,3,4-butanetetracarboxylic dianhydride and 1,2,4,5-pentanetetracarboxylic dianhydride.

As a method of introducing a compound obtained by ring-opening of these tetracarboxylic dianhydrides with a diol compound, into a polyurethane resin, for example, there are the following methods.
a) A method of reacting a compound having an alcoholic terminal obtained by ring-opening of a tetracarboxylic dianhydride with a diol compound, and a diisocyanate compound.
b) A method of reacting a urethane compound having an alcoholic terminal obtained by reacting a diisocyanate compound under the condition of an excessive diol compound, and a tetracarboxylic dianhydride.

Examples of the diol compound used in the ring-opening reaction thereupon include the following compounds.

That is, examples thereof include ethylene glycol, diethylene glycol, triethylene glycol, tetraethylene glycol, propylene glycol, dipropylene glycol, polyethylene glycol, polypropylene glycol, neopentyl glycol, 1,3-butylene glycol, 1,6-hexanediol, 2-butene-1,4-diol, 2,2,4-trimethyl-1,3-pentanediol, 1,4-bis-β-hydroxyethoxycyclohexane, cyclohaxanedimethanol, tricyclodecanedimethanol, hydrogenated bisphenol A, hydrogenated bisphenol F, an ethylene oxide adduct of bisphenol A, an propylene oxide adduct of bisphenol A, an ethylene oxide adduct of bisphenol F, a propylene oxide adduct oxide of bisphenol F, an ethylene oxide adduct of hydrogenated bisphenol A, a propylene oxide adduct of hydrogenated bisphenol A, hydroquinonedihydroxyethyl ether, p-xylylene glycol, dihydroxyethylsulfone, bis(2-hydroxyethyl)-2,4-tolylene dicarbamate, 2,4-tolylene-bis(2-hydroxyethylcarbamide), bis(2-hydroxyethyl)-m-xylylene dicarbamate, and bis(2-hydroxyethyl)isophthalate.

Other Copolymerizable Components

A polyurethane resin used as the binder (A) in the invention may contain an organic group containing at least one of an ether bond, an amido bond, a urea bond, an ester bond, a urethane bond, a biuret bond, and an allophanate bond as a functional group, in addition to a urethane bond.

It is preferable that a polyurethane resin used as the binder (A) further has a unit having an ethylenic unsaturated bond. It is preferable that the polyurethane resin having a unit having an ethylenic unsaturated bond has at least one of functional groups represented by the following formulas (E1) to (E3) in a side chain of a polyurethane resin. First, functional groups represented by the following formulas (E1) to (E3) will be explained.

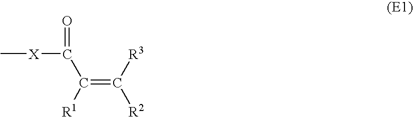

In Formula (E1), R¹ to R³ each represent independently a hydrogen atom or a monovalent organic group. Examples of R¹ include preferably a hydrogen atom, and an alkyl group optionally having a substituent and, among them, a hydrogen atom, and a methyl group are preferable due to high radical reactivity. R² and R³ each represent independently a hydrogen atom, a halogen atom, an amino group, a carboxyl group, an alkoxycarbonyl group, a sulfo group, a nitro group, a cyano group, an alkyl group optionally having a substituent, an aryl group optionally having a substituent, an alkoxy group optionally having a substituent, an aryloxy group optionally having a substituent, an alkylamino group optionally having a substituent, an arylamino group optionally having a substituent, an alkylsulfonyl group optionally having a substituent, or an arylsulfonyl group optionally having a substituent and, among them, a hydrogen atom, a carboxyl group, an alkoxy carbonyl group, an alkyl group optionally having a substituent, and an aryl group optionally having a substituent are preferable due to high radical reactivity.

X represents an oxygen atom, a sulfur atom, or —N(R¹²)—, and R¹² represents a hydrogen atom, or a monovalent organic group. Herein, example of the monovalent organic group include an alkyl group optionally having a substituent. Among them, R¹ is preferably a hydrogen atom, a methyl group, an ethyl group, or an isopropyl group due to high radical reactivity.

Herein, examples of the substituent which may be introduced include an alkyl group, an alkenyl group, an alkynyl group, an aryl group, an alkoxy group, an aryloxy group, a halogen atom, an amino group, an alkyl amino group, an arylamino group, a carboxyl group, an alkoxycarbonyl group, a sulfo group, a nitro group, a cyano group, an amido group, an alkylsulfonyl group, and an arylsulfonyl group.

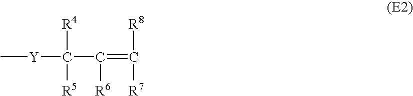

In Formula (E2), R⁴ to R⁸ each represent independently a hydrogen atom or a monovalent organic group. R⁴ to R⁸ preferably represent a hydrogen atom, a halogen atom, an amino group, a dialkylamino group, a carboxyl group, an alkoxycarbonyl group, a sulfo group, a nitro group, a cyano group, an alkyl group optionally having a substituent, an aryl group optionally having a substituent, an alkoxy group optionally having a substituent, an aryloxy group optionally having a substituent, an alkylamino group optionally having a substituent, an arylamino group optionally having a substituent, an alkylsulfonyl group optionally having a substituent, and an arylsulfonyl group optionally having a substituent and, among them, a hydrogen atom, a carboxyl group, an alkoxycarbonyl group, an alkyl group optionally having a substituent, and an aryl group optionally having a substituent are preferable.

As a group which may be introduced as the substituent, the same substituents as those for Formula (E1) are exemplified. Y represents an oxygen atom, a sulfur atom, or —N(R¹²)—. R¹² has the same meaning as that of R¹² of Formula (E1), and a preferable example is similar.

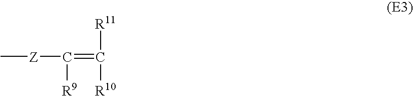

In Formula (E3), R⁹ to R¹¹ each represent independently a hydrogen atom or a monovalent organic group. Examples of R⁹ include preferably a hydrogen atom and an alkyl group optionally having a substituent and, among them, a hydrogen atom, and a methyl group are preferable due to high radical reactivity. R¹⁰ and R¹¹ each represent independently a hydrogen atom, a halogen atom, an amino group, a dialkylamino group, a carboxyl group, an alkoxycarbonyl group, a sulfo group, a nitro group, a cyano group, an alkyl group optionally having a substituent, an aryl group optionally having a substituent, an alkoxy group optionally having a substituent, an aryloxy group optionally having a substituent, an alkylamino group optionally having a substituent, an arylamino group optionally having a substituent, an alkylsulfonyl group optionally having a substituent, or an arylsulfonyl group optionally having a substituent and, among them, a hydrogen atom, a carboxyl group, an alkoxycarbonyl group, an alkyl group optionally having a substituent, and an aryl group optionally having a substituent are preferable due to high radical reactivity.

Herein, as a group which may be introduced as the substituent, the same groups as those for Formula (E1) are exemplified. Z represents an oxygen atom, a sulfur atom, —N(R¹³)—, or a phenylene group optionally having a substituent. R¹³ represents an alkyl group optionally having a substituent and, inter alia, a methyl group, an ethyl group, and an isopropyl group are preferable due to high radical reactivity.

As a method of introducing an ethylenic unsaturated bond into a side chain of a polyurethane resin, a method of using a diol compound containing an ethylenic unsaturated bond as a raw material for producing a polyurethane resin is also suitable. Such a diol compound may be a commercially available compound such as trimethylolpropane monoallyl ether, or may be a compound which is easily produced by a reaction of a halogenated diol compound, a triol compound, or an aminodiol compound, and a carboxylic acid, acid chloride, isocyanate, alcohol, amine, thiol, or a halogenated alkyl compound containing an ethylenic unsaturated bond. Specific examples of these compounds are not limited to, but include the following compounds.

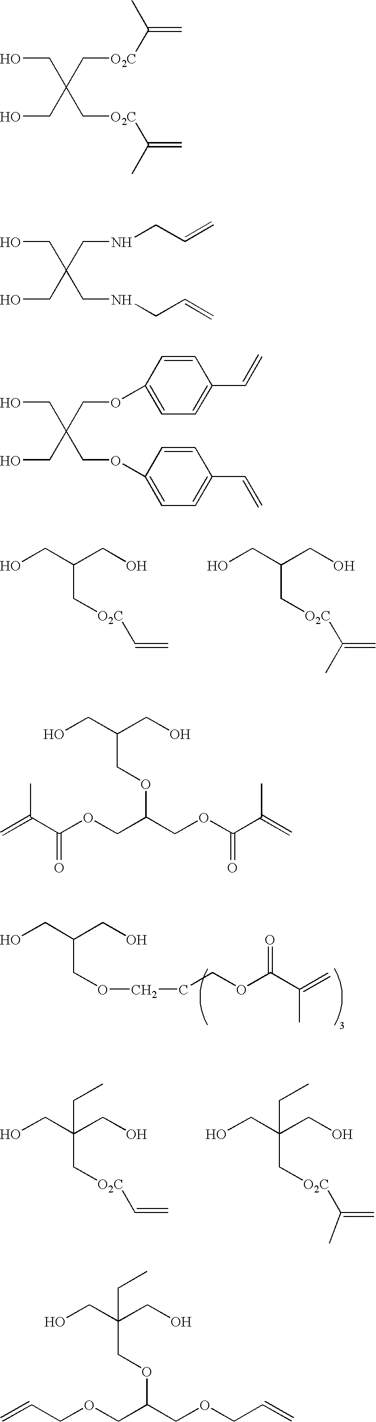

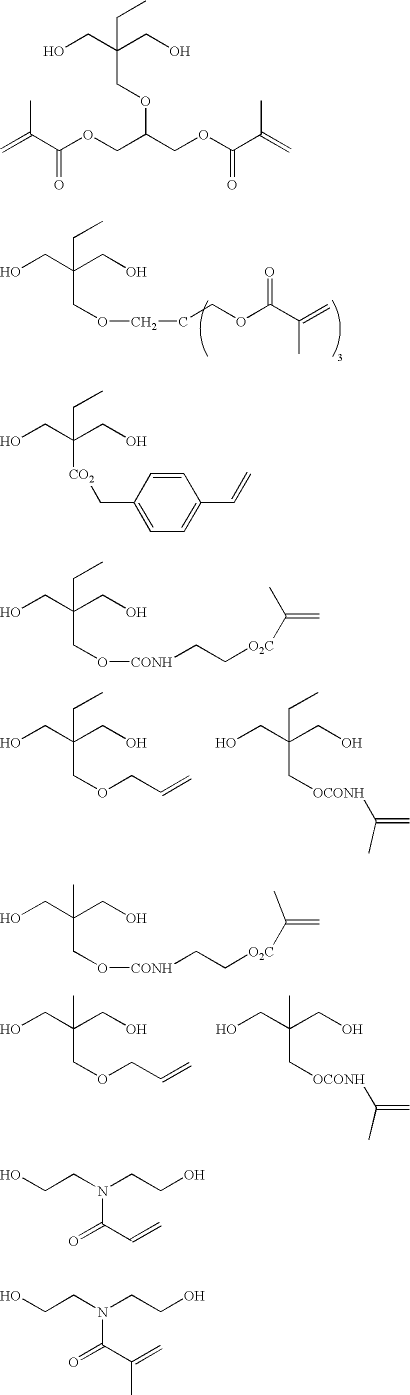

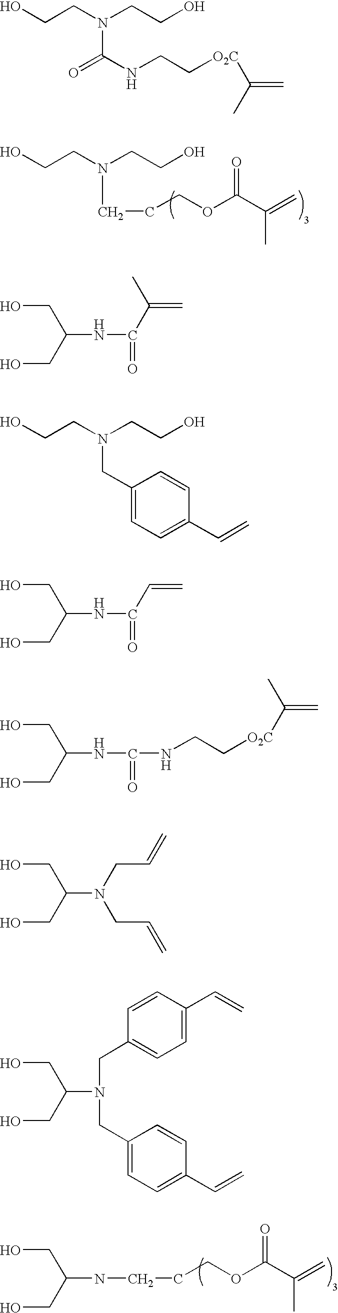

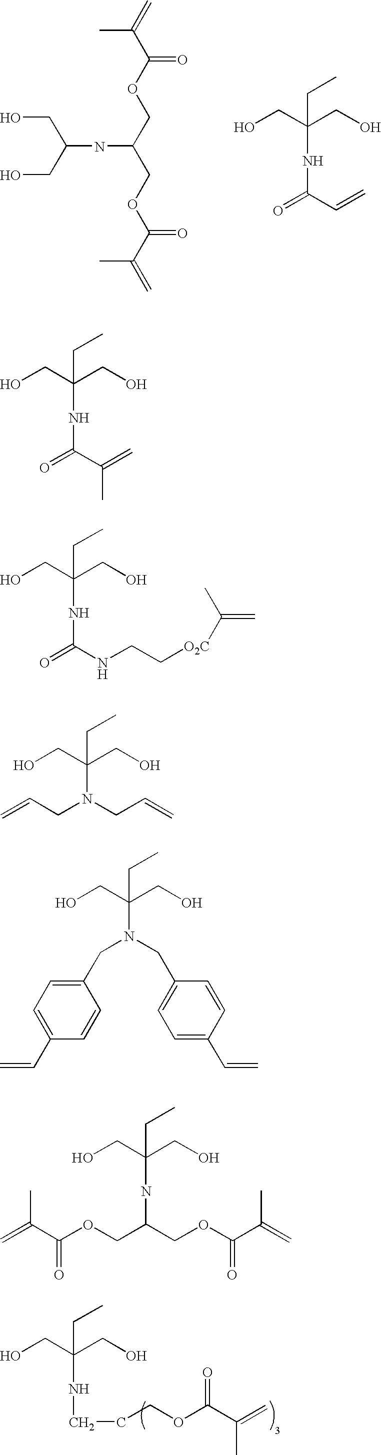

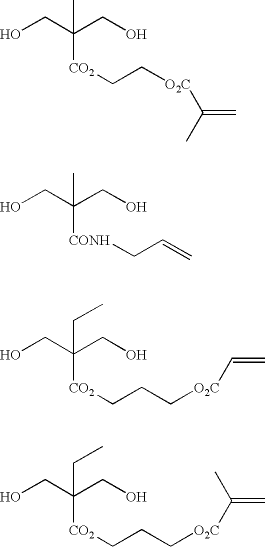

In addition, as a more preferable polyurethane resin, a polyurethane resin obtained using a diol compound represented by the following Formula (G) as at least one of diol compounds having an ethylenic unsaturated bond group upon synthesis of a polyurethane resin is exemplified.

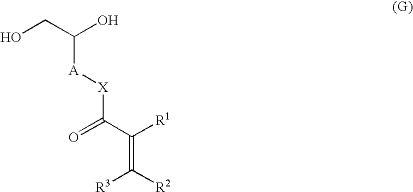

In Formula (G), R¹ to R³ each represent independently a hydrogen atom or a monovalent organic group, A represents a divalent organic residue, X represents an oxygen atom, a sulfur atom, or —N(R¹²)—, and R¹² represents a hydrogen atom, or a monovalent organic group.

R¹ to R³ and X in this Formula (G) have the same meanings as those of R¹ to R³ and X in Formula (E1), and a preferable embodiment is similar.

A divalent organic residue represented by the A is a divalent organic linking group which contains a carbon atom and a hydrogen atom, and optionally an atom selected from an oxygen atom, a nitrogen atom, and a sulfur atom. Preferable is a divalent organic linking group which is constructed by suitably combining —C(═O)—, —C(═O)—O—, —C(═O)—NH—, —NH—C(═O)—O—, —NH—C(═O)—NH—, alkylene group, allylene group, or a group constructed by combining them and further —O—, —S—, or —NH—. The number of atoms constructing a linking chain contained in this divalent organic linking group is suitably within 60 and, from a viewpoint that film forming property is kept good, is preferably within 50, more preferably within 40.

It is thought that, by using a polyurethane resin derived from these diol compounds, the effect of suppressing excessive molecular motion of a polymer main chain due to a secondary alcohol having great steric hindrance is obtained, and improvement in a film strength of the film formed by using the resin composition of the invention is attained.

Examples of the diol compound represented by Formula (G) which is suitably used in synthesizing a polyurethane resin will be shown below.

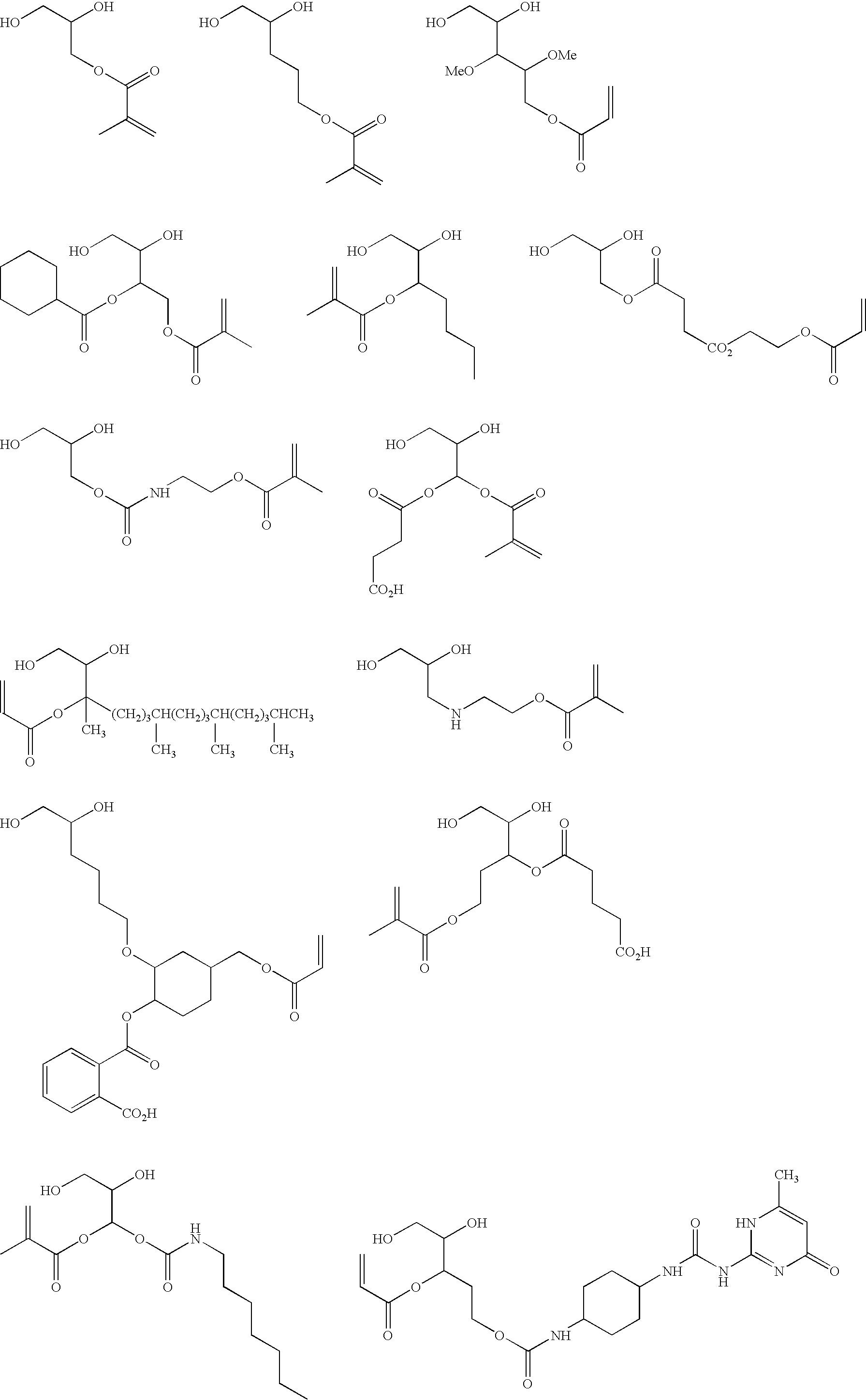

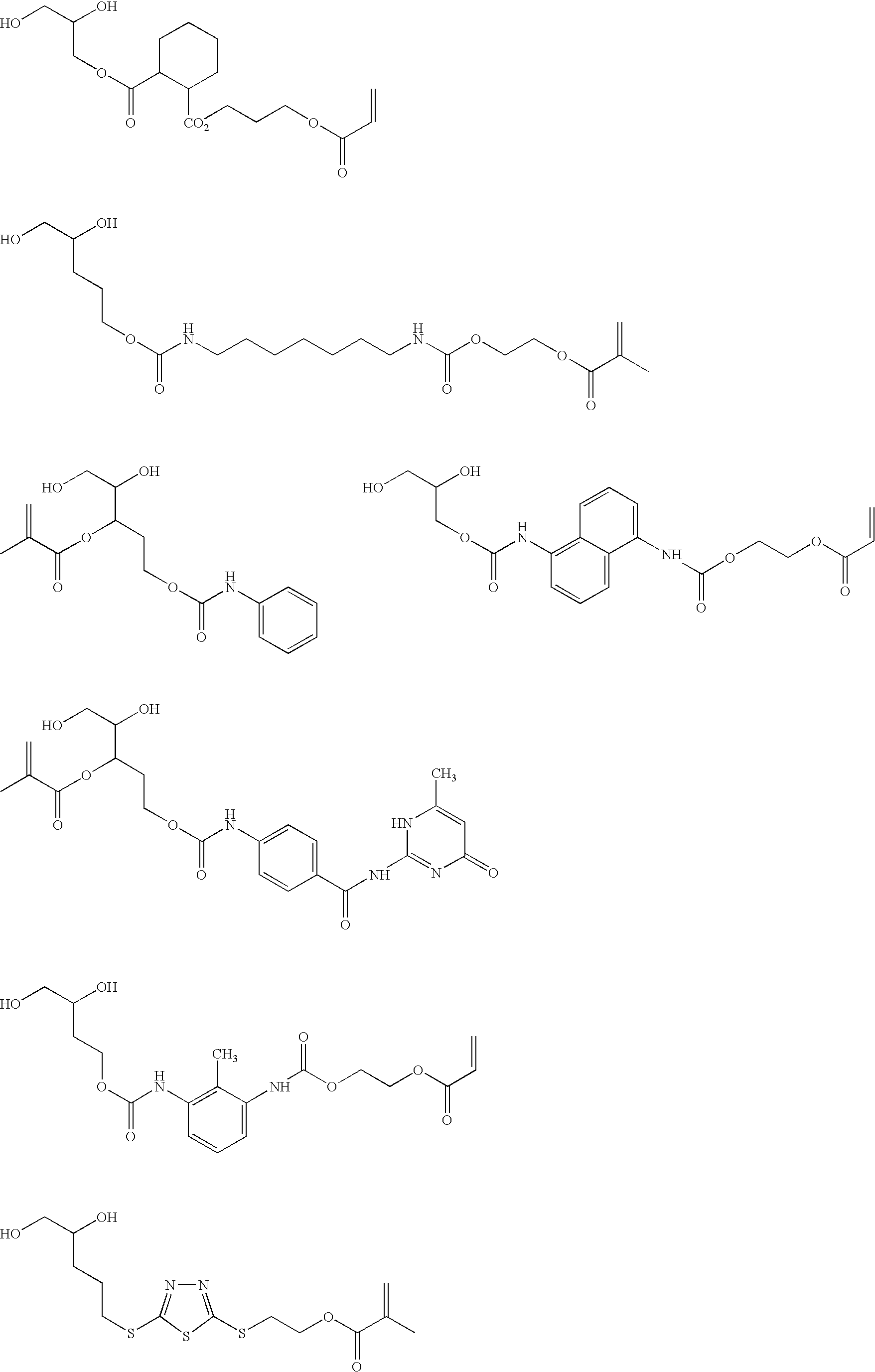

When synthesizing a polyurethane resin under the NCO group excessive condition where an NCO/OH ratio is 1 or more, a main chain terminal is an NCO group, and thus, by separately adding hereto an alcohol having an ethylenic unsaturated bond (2-hydroxyethyl (meth)acrylate, trade name: BLEMMER PME200, manufactured by NOF Corporation) etc.), an ethylenic unsaturated bond may be introduced into a main chain terminal.

That is, as a polyurethane resin suitable in the invention, a resin having an ethylenic unsaturated group not only in a side chain but also in a main chain terminal is also preferable.

As a polyurethane resin suitable in the invention, as described above, in addition to a resin having an ethylenic unsaturated bond in a side chain, a resin having an ethylenic unsaturated bond in a main chain terminal and/or a main chain is also suitably used.

As a method of introducing an ethylenic unsaturated bond into a main chain terminal of a polyurethane resin, there is the following method.

That is, when synthesizing a polyurethane resin, in a step of treating an isocyanate group remaining in a main chain terminal of the resulting intermediate product with alcohols or amines, alcohols or amines having an ethylenic unsaturated group may be used.

As a method of introducing an ethylenic unsaturated bond into a main chain of a polyurethane resin, there is a method of using a diol compound having an ethylenic unsaturated bond in a chain linking an OH group and an OH group in synthesis of a polyurethane resin. Examples of the diol compound having an ethylenic unsaturated bond in a chain linking an OH group and an OH group include the following compounds.

That is, examples thereof include cis-2-butene-1,4-diol, trans-2-butene-1,4-diol, and polybutadiendiol.

From a viewpoint that an introduction amount is easily controlled, and an introduction amount may be increased, or a crosslinking reaction efficacy is improved, it is preferable that an ethylenic unsaturated bond is introduced into a side chain rather than into a main chain terminal of a polyurethane resin.

As an ethylenic unsaturated bond group to be introduced, from a viewpoint of crosslinked cured film forming property, a mathacryloyl group, an acryloyl group, and styryl group are preferable and, a methacryloyl group and an acryloyl group are more preferable. From a viewpoint of realization of both of forming property and unused stock storability of a crosslinked cured film, a methacryloyl group is further preferable.

Regarding an amount of an ethylenic unsaturated bond contained in a polyurethane resin used in the invention, an ethylenic unsaturated bond group is contained in a side chain in an amount of preferably 0.3 meq/g or more, further preferably 0.35 to 1.50 meq/g as expressed by equivalent. That is, a polyurethane resin containing a methacryloyl group in a side chain in an amount of 0.35 to 1.50 meq/g is most preferable.

A weight average molecular weight of a polyurethane resin as the binder (A) in the invention is preferably 10,000 or more, more preferably in the range of 40,000 to 200,000. Particularly, when a polyurethane resin having a molecular weight in this range is used, a strength of a formed resin molded product such as relief layer is excellent.

A polyurethane resin used as the binder (A) in the invention is synthesized by heating the diisocyanate compound and the diol compound in an aprotic solvent with the addition of the known catalyst having activity according to each reactivity. A molar ratio (Mₐ:M_{b}) of the diisocyanate and diol compounds used in synthesis is preferably 1:1 to 1.2:1.1 and, by treating with alcohols or amines, a product having desired physical properties such as a molecular weight and a viscosity is synthesized in such a final form that an isocyanate group does not remain.

Inter alia, synthesis using a bismuth catalyst is more preferable than a tin catalyst which has been previously used frequently, from a viewpoint of the environment and a polymerization rate. As such a bismuth catalyst, trade name: NEOSTAN U-600 manufactured by NITTO CHEMICAL INDUSTRY co., ltd. is particularly preferable.

Examples of the specified polyurethane resin used in the invention are shown below, but the invention is not limited by them.

| Polyurethane | | |
|---|---|---|
| resin | Diisocyanate compound used (mol %) | |
| P-1 | 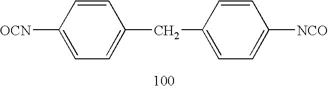 | |
| P-2 | 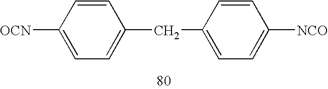 | |
| | 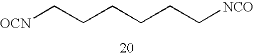 | |
| P-3 | 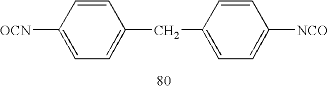 | |
| | 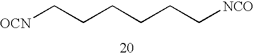 | |
| P-4 | 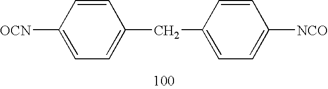 | |
| P-5 | 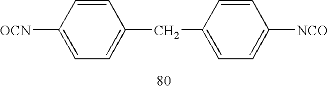 | |
| | 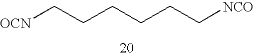 | |
| P-6 | 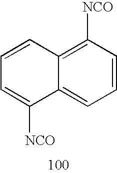 | |
| P-7 | 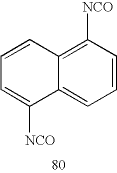 | |
| | 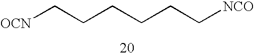 | |
| P-8 | 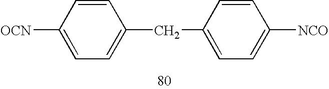 | |
| | 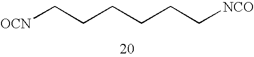 | |
| P-9 | 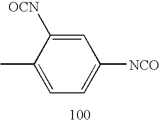 | |
| P-10 | 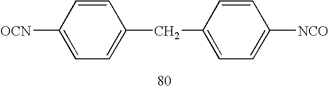 | |
| | 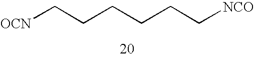 | |
| P-11 | 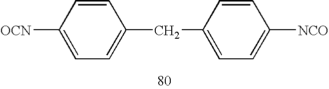 | |
| | 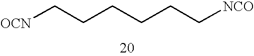 | |
| P-12 | 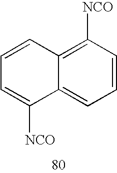 | |
| | 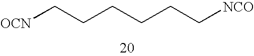 | |
| P-13 | 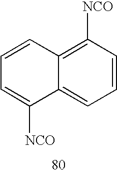 | |
| | 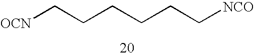 | |
| P-14 | 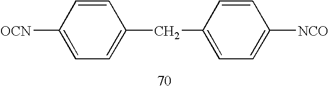 | |
| | 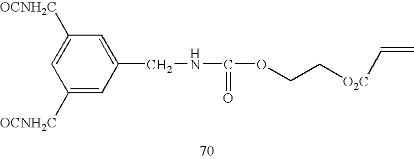 | |
| P-15 | 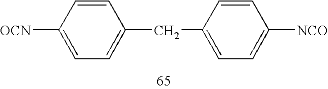 | |
| | 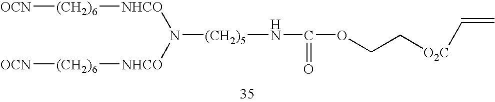 | |
| P-16 | 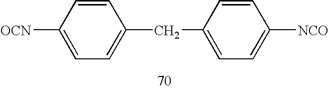 | |
| | 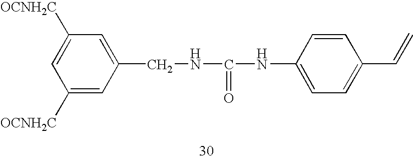 | |
| P-17 | 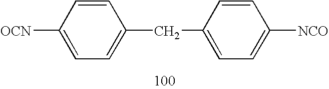 | |
| P-18 | 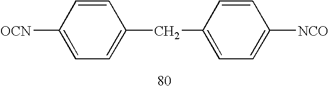 | |
| | 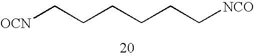 | |
| P-19 | 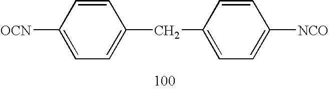 | |
| P-20 | 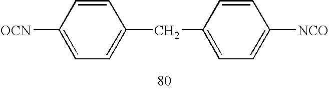 | |
| | 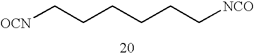 | |
| P-21 | 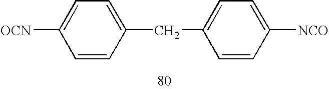 | |
| | 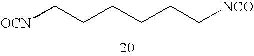 | |
| P-22 | 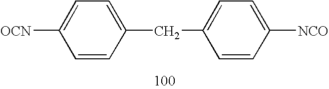 | |
| P-23 | 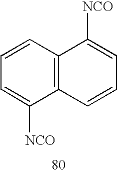 | |
| | 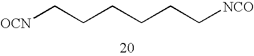 | |
| P-24 | 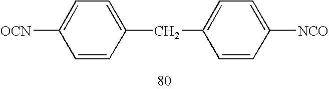 | |
| | 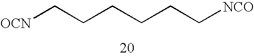 | |
| P-25 | 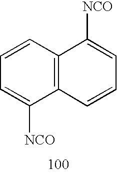 | |
| P-26 | 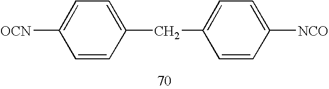 | |
| | 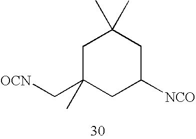 | |
| P-27 | 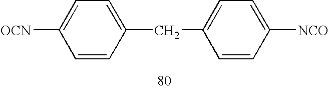 | |
| | 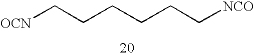 | |
| P-28 | 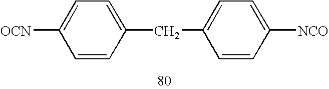 | |
| | 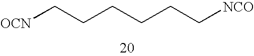 | |
| P-29 | 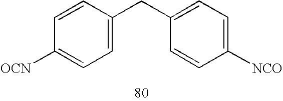 | |
| | 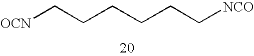 | |
| P-30 | 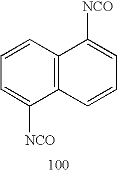 | |
| P-31 | 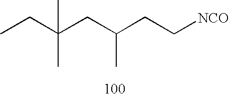 | |
| P-32 | 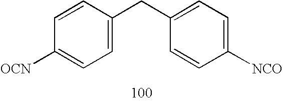 | |
| P-33 | 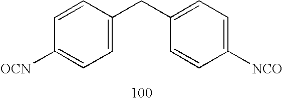 | |
| Polyurethane | | |
| resin | Diolcompoundused (mol %) | Mw |
| P-1 | 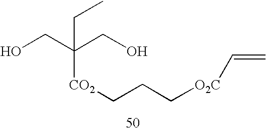 | 95,000 |
| | 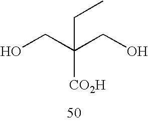 | |
| P-2 | 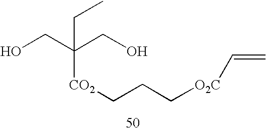 | 98,000 |
| | 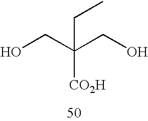 | |
| P-3 | 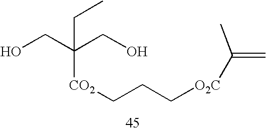 | 103,000 |
| | 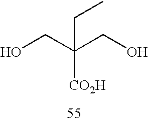 | |
| P-4 | 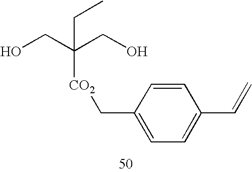 | 108,000 |
| | 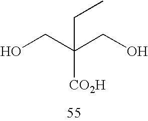 | |
| P-5 | 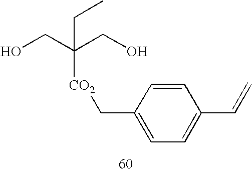 | 99,000 |
| | 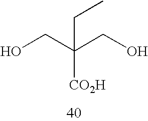 | |
| P-6 | 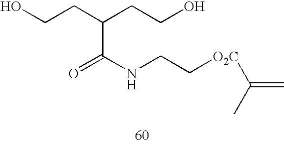 | 96,000 |
| | 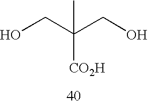 | |
| P-7 | 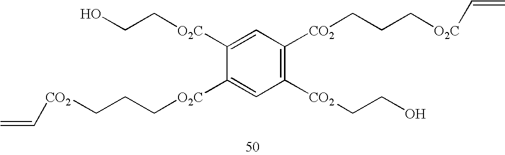 | 68,000 |
| | 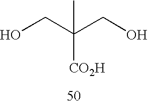 | |
| P-8 | 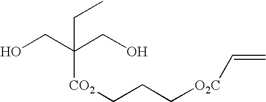 | 96,000 |
| | 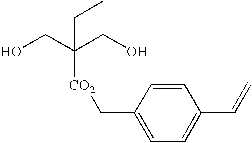 | |
| | 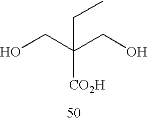 | |
| P-9 | 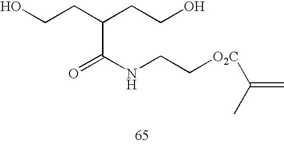 | 100,000 |
| | 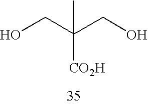 | |
| P-10 | 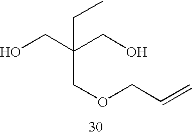 | 69,000 |
| | 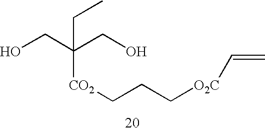 | |
| | 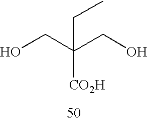 | |
| P-11 | 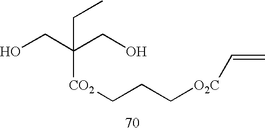 | 120,000 |
| | 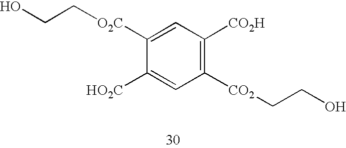 | |
| P-12 | 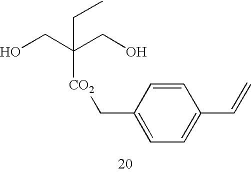 | 78,000 |
| | 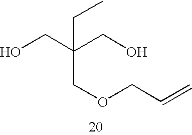 | |
| | 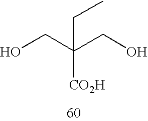 | |
| P-13 | 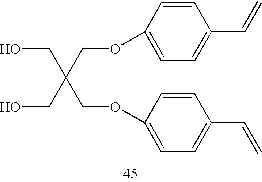 | 103,000 |
| | 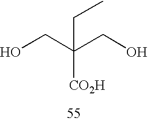 | |
| P-14 | 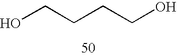 | 65,000 |
| | 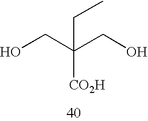 | |
| P-15 | 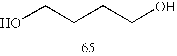 | 78,000 |
| | 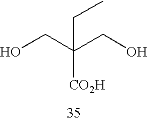 | |
| P-16 | 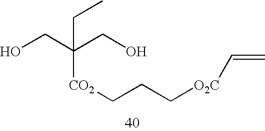 | 69,000 |
| | 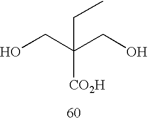 | |
| P-17 | 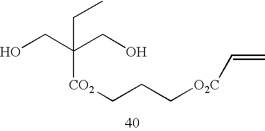 | 99,000 |
| | 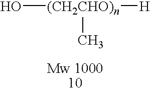 | |
| | 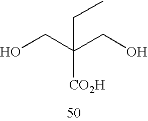 | |
| P-18 | 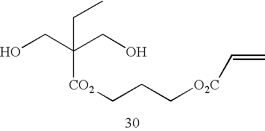 | 87,000 |
| | 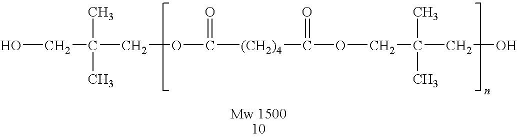 | |
| | 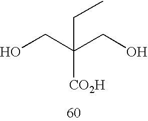 | |
| P-19 | 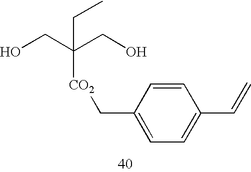 | 97,000 |
| | HO—(CH₂CH₂CH₂CH₂O)ₙ—H | |
| | Mw 2000 | |
| | 10 | |
| | 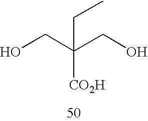 | |
| P-20 | 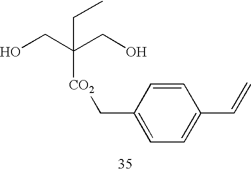 | 103,000 |
| | 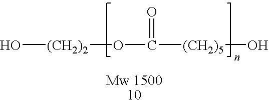 | |
| | 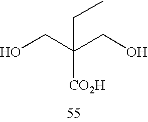 | |
| P-21 | 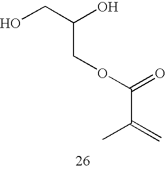 | 60,000 |
| | 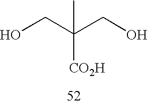 | |
| | 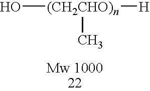 | |
| P-22 | 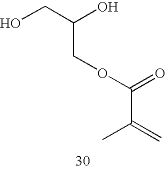 | 70,000 |
| | 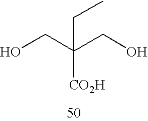 | |
| | 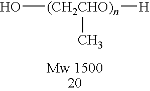 | |
| P-23 | 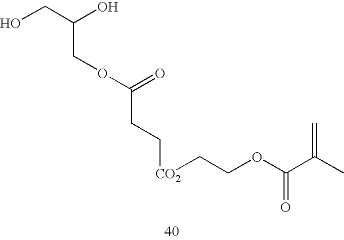 | 50,000 |
| | 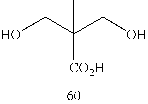 | |
| P-24 | 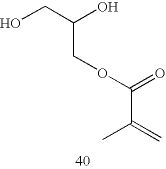 | 75,000 |
| | 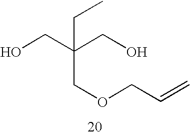 | |
| | 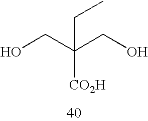 | |
| P-25 | 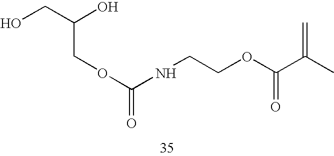 | 80,000 |
| | 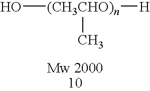 | |
| | 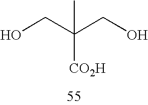 | |
| P-26 | 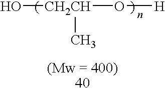 | 50,000 |
| | 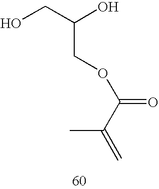 | |
| P-27 | 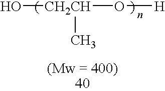 | 60,000 |
| | 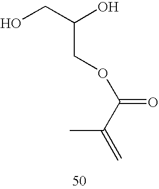 | |
| | 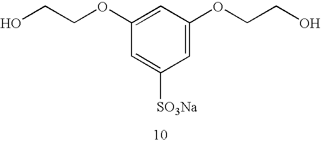 | |
| P-28 | 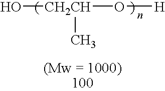 | 59,000 |
| P-29 | 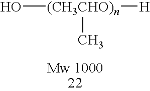 | 63,000 |
| | 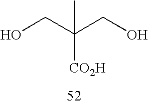 | |
| | 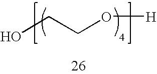 | |
| P-30 | 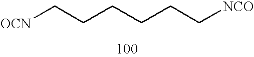 | 32,000 |
| P-31 | 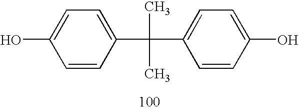 | 21,000 |
| P-32 | 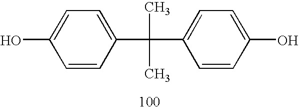 | 29,000 |
| P-33 | 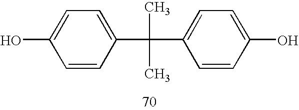 | 41,000 |
| | 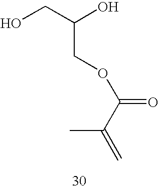 | |

A polyurethane resin as the binder (A) in the invention has the characteristic that it is thermally decomposed at a relatively low temperature (lower than 250° C.) as compared with a binder polymer used in the normal resin composition for laser engraving (in the case of a commercially available general-use resin, it is thermally decomposed at a high temperature of 300° C. to 400° C. in most cases). Therefore, the resin composition containing such a polyurethane resin may be decomposed at a high sensitivity.

In addition, in a system in which such a polyurethane resin is used as the binder (A) and an additional binder polymer described later is used together, even in the state where these polymers are not uniformly mixed and are phase-separated, first, this polyurethane resin is decomposed by heat production with laser irradiation and, as a result, a gas (nitrogen etc.) generated upon thermal decomposition and vaporization of the polyurethane resin assists and promotes vaporization of the additional binder polymer. For this reason, the relief forming layer using such a polyurethane resin as the specified alcoholphilic polymer also has an advantage that, even when the additional binder polymer is present, laser decomposability is improved, and a high sensitivity is attained.

The content of the binder (A) in the resin composition of the invention is preferably 2% by mass to 95% by mass, more preferably 5% by mass to 80% by mass, and particularly preferably 10% by mass to 60% by mass, from the viewpoint of satisfying, in a well-balanced manner, the shape retention, water resistance and engraving sensitivity of the resin molded product formed from the resin composition.

Binder (B)

The binder (B), which is one of a suitable binder polymer for the resin composition of the invention, is at least one polyester selected from the group consisting of a polyester including a hydroxycarboxylic acid unit and derivatives thereof, polycaprolactone (PCL) and derivatives thereof, and poly(butylenesuccinic acid) and derivatives thereof. The binder (B) may be contained in the resin composition of the invention individually or in combination thereof.

In the invention, the term “polyester including a hydroxycarboxylic acid unit” refers to a polyester obtainable by a polymerization reaction using a hydroxycarboxylic acid as one of the raw materials. Furthermore, according to the present specification, the term “hydroxycarboxylic acid” refers to a compound having at least one OH group and at least one COOH group in the molecule. It is preferable that the at least one OH group and the at least one COOH group of the “hydroxycarboxylic acid” exist closely to each other, and it is also preferable that the OH group and the COOH group are linked through a linker having 6 or fewer atoms, and more preferably 4 or fewer atoms.

Specific example of the binder (B) is preferably selected from the group consisting of a polyhydroxyalkanoate (PHA), a lactic acid-based polymer, a polyglycolic acid (PGA), a polycaprolactone (PCL) and a poly(butylenesuccinic acid), and derivatives or mixtures thereof.

When the binder (B) is used, an action mechanism thereof is not clear, but is supposed to be as follows.

The binder (B) is characterized in that when it is thermally decomposed (that is, at a time corresponding to the occasion of laser engraving according to the present application), a part of the main chain is thermally decomposed at a relatively low temperature, such as approximately 300° C., and a depolymerization reaction (which is a reverse reaction of a polymerization reaction, whereby the polymer is thermally broken down into the raw material low molecular weight monomer units) occurs beginning from this part.

The laser engraving (particularly, in the case of near-infrared laser light) that is carried out on the resin composition of the invention is thought to include five steps: (1) light absorption by a compound having a maximum absorption wavelength at 700 to 1300 nm [symbol] (2) photothermal conversion by the compound having a maximum absorption wavelength at 700 to 1300 nm [symbol] (3) heat transfer from the compound having a maximum absorption wavelength at 700 to 1300 nm to a binder existing nearby [symbol] (4) thermal decomposition of the binder [symbol] (5) dissipation of the decomposed binder.

Since the binder (B) has the characteristic of low temperature thermal decomposition and the characteristic of depolymerization as described above, the step (4) is accelerated by the characteristic of low temperature thermal decomposition, and since the low molecular weight monomers (many of which volatilize below 250° C.) generated by depolymerization are instantly volatilized, the step (5) occurs very efficiently. Thus, it is thought that these two effects result in a large increase in laser engraving sensitivity.

Examples of the binder (B), which are obtainable by a polymerization reaction using hydroxycarboxylic acid as one of raw materials, are shown below.

As the PHA of the binder (B), those polymers having a repeating monomer unit represented by the following Formula (a) are preferable.

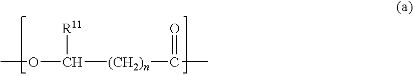

In Formula (a), n represents an integer from 1 to 5; and R¹¹ represents a hydrogen atom, an alkyl group organ alkenyl group. These alkyl group and alkenyl group are preferably such groups having 1 to 20 carbon atoms. Here, the polymer may be a homopolymer in which the combination of R¹¹ and n is fixed to be constant, or may be a copolymer having at least two different repeating monomer units with different combinations of R¹¹ and n. The copolymer may be a random copolymer, a block copolymer, an alternating copolymer or a graft copolymer. The molecular weight of PHA is in the range of from 500 to 5,000,000 g/mol, preferably from 1,000 to 2,500,000 g/mol, and more preferably from 2,500 to 1,000,000 g/mol.

Examples of PHA that are applicable to the invention include poly-3-hydroxybutyrate, poly-3-hydroxyvalerate, poly-3-hydroxyheptanoate, poly-3-hydroxyoctanoate, poly-4-hydroxybutyrate, poly(3-hydroxybutyrate-co-3-hydroxyvalerate), poly(3-hydroxybutyrate-co-4-hydroxybutyrate), poly(3-hydroxybutyrate-co-3-hydroxyoctanoate), and other copolymers. The copolymers of PHA mentioned herein usually have 40 to 100%, and preferably 60 to 98%, of a 3-hydroxybutyrate monomer.

Additionally, as the binder (B), copolymers using the monomers mentioned as those usable in the polyester that may be used in combination, which will be described later, as the co-monomers that are copolymerizable with the repeating monomer unit represented by Formula (a), may also be used.

The lactic acid-based polymer that may be used in the invention is a polylactic acid (in Formula (a), R¹¹ is a methyl group, and n=0) or a copolymer of lactic acid and hydroxycarboxylic acid. Examples of the hydroxycarboxylic acid include glycolic acid (in Formula (a), R¹¹ is H, and n=0), hydroxybutyric acid, hydroxyvaleric acid, hydroxypentanoic acid, hydroxycaproic acid, hydroxyheptanoic acid, and the like. A preferred molecular structure of polylactic acid consists of 85 to 100% by mole of either an L-lactic acid unit or a D-lactic acid unit, and 0 to 15% by mole of the corresponding enantiomer lactic acid unit. The copolymer of lactic acid and hydroxycarboxylic acid includes 85% by mole or more and less than 100% by mole of either an L-lactic acid unit or a D-lactic acid unit, and more than 0% to 15% by mole or less of a hydroxycarboxylic acid unit. In view of the ease of obtaining the raw material, the lactic acid that is used may be DL-lactic acid (racemate). Preferred hydroxycarboxylic acids include glycolic acid and hydroxycaproic acid.

Such a lactic acid-based polymer may be obtained by selecting a monomer having a required structure from L-lactic acid, D-lactic acid and hydroxycarboxylic acid to use the monomer as a raw material monomer, and subjecting the monomer to dehydration polycondensation. Preferably, the lactic acid-based polymer may be obtained by selecting a monomer having a required structure from lactide, which is a cyclic dimer of lactic acid; glycolide, which is a cyclic dimer of glycolic acid; lactone; and the like, and subjecting the monomer to ring-opening polymerization. Examples of the lactide include L-lactide, which is a cyclic dimer of L-lactic acid; D-lactide, which is a cyclic dimer of D-lactic acid; mesolactide, which is a cyclic dimerization product of D-lactic acid and L-lactic acid; and DL-lactide which is a racemic mixture of a D-lactide and an L-lactide. According to the invention, any lactide may be used, but as a main raw material, D-lactide, L-lactide, glycolide or caprolactone is preferred.

As the polylactic acid and the lactic acid-glycolic acid copolymer, polymers having a ratio of lactic acid/glycolic acid (molar ratio) of 100/0 to 30/70, and more preferably 100/0 to 40/60, and having a molecular weight of about 1,000 to 100,000, and more preferably 2,000 to 80,000, are exemplified.

Among the polylactic acid and the lactic acid-glycolic acid copolymer, the polylactic acid copolymer is preferred from the viewpoint that the polylactic acid copolymer maintains the film properties strong compared to the lactic acid-glycolic acid copolymer.

The polycaprolactone (PCL) that may be used as the binder (B) (in Formula (a), R¹¹ is H, and n=4) may be a homopolymer or a combination with other lactones, or may also be a polyester which is structurally identical with Formula (a), or the like.

The poly(butylenesuccinic acid) that may be used as the binder (B) is not a polyester formed only from a hydroxycarboxylic acid unit, but is a polymer synthesized from 1,4-butanediol and succinic acid. However, hydroxycarboxylic acid may be used in combination.

The polyester described as the binder (B) may be a copolymer using a copolymerizable comonomer which is exemplified as a monomer usable in the polyester described below.

When the binder (B) is used as the binder polymer, examples of the polyester which are preferably used in combination with the binder (B) are given below. However, poly(butylenesuccinic acid) may be used as the binder (B).

Such a polyester may be a polyester formed from an aliphatic (including alicyclic) glycol, an aromatic dicarboxylic acid or an acid anhydride thereof, or an aliphatic dicarboxylic acid or an acid anhydride thereof (hereinafter, simply referred to as aliphatic dicarboxylic acid) as the monomer, for the purpose of controlling water resistance or flexibility of the film.

Furthermore, if necessary, the polyester may also include, as a third component monomer, at least one polyfunctional component selected from a trifunctional or tetrafunctional polyhydric alcohol, and a polyvalent carboxylic acid (or an acid anhydride thereof).

Examples of the glycol that may be preferably used include ethylene glycol, 1,4-butanediol, 1,6-hexanediol, 1,8-octanediol, 1,10-decanediol, 1,4-cyclohexanediol and mixtures thereof, but are not intended to be limited to these.

Examples of the aromatic dicarboxylic acid that may be preferably used include terephthalic acid, isophthalic acid, phthalic acid, naphthalenedicarboxylic acid and mixtures thereof, but are not intended to be limited to these.

Examples of the aliphatic dicarboxylic acid that may be preferably used include succinic acid, adipic acid, suberic acid, sebacic acid, 1,10-decanedicarboxylic acid, succinic anhydride, 1,4-cyclohexanedicarboxylic acid and mixtures thereof, but are not intended to be limited to these.

As a particularly suitable embodiment of the binder (B), the lactic acid-based polymer is preferable, and from the viewpoint of high engraving sensitivity, the polylactic acid-based polymer and the polyglycolic acid-based polymer are more preferable.

In the case of using the binder (B) as the binder polymer, a content thereof is preferably from 5% by mass to 95% by mass, more preferably from 15% by mass to 85% by mass, and particularly preferably from 25% by mass to 70% by mass, with respect to the total solid content of the resin composition, from the viewpoint of maintaining the film properties and engraving sensitivity satisfactorily.

Other Binder Polymer

The resin composition of the invention may contain, in addition to the binder (A) and the binder (B), a known binder polymer which is not included in the binder (A) and the binder (B).

Hereinafter, such a binder polymer that is used in combination with the binder (A) and the binder (B) will be referred to as an “other binder” in the following descriptions.

As the other binder, usually a thermoplastic resin, a thermoplastic elastomer and the like are used according to the purpose, from the viewpoint of the recording sensitivity to laser light. That is, the other binder is used for the purpose of imparting desired properties to a resin molded product such as a relief forming layer, when used in combination with the binder (A) and the binder (B).

For example, when the other binder is used for the purpose of enhancing strength through curing by heating or exposure, a polymer having a carbon-carbon unsaturated bond in the molecule is selected. When the other binder is used for the purpose of forming a pliable film having flexibility, a soft resin or a thermoplastic elastomer is selected. From the viewpoints of the ease of preparation of a coating liquid for relief forming layer used for forming a relief forming layer, or an enhancement of resistance to oily ink in relief printing plates that are obtained, it is preferable to use a hydrophilic polymer or an alcoholphilic polymer.

From the viewpoint of laser engraving sensitivity, a polymer including a partial structure which is thermally decomposed by exposure or heating is preferable.

As such, binder polymers that are suitable for the purpose may be selected in consideration of the properties in accordance with the application use of the resin composition of the invention, and the other binder polymers may be used singly or in combination of two or more species thereof, together with the binder (A) and the binder (B) described above.

The total amount of the binder polymers (that is, the total amount of the binder (A), the binder (B) and the other binder) in the resin composition of the invention is preferably from 2% by mass to 99% by mass, and more preferably from 5% by mass to 80% by mass.

Hereinafter, various polymers that may be used as the other binder according to the invention will be described.

Polymer Having Carbon-Carbon Unsaturated Bond

A polymer having carbon-carbon unsaturated bonds in the molecule, which is not included in the binder (A) and the binder (B), may be suitably used as the other binder. The carbon-carbon unsaturated bonds may be present in either the main chain or the side chains, or may also be present in both of the chains. Hereinafter, the carbon-carbon unsaturated bond may also be simply referred to as an “unsaturated bond”, and a carbon-carbon unsaturated bond present at an end of the main chain or side chain may also be referred to as a “polymerizable group”.

In the case where the polymer has carbon-carbon unsaturated bonds in the main chain thereof, the polymer may have the unsaturated bonds at one terminal thereof, at both terminals thereof, and/or within the main chain thereof. Furthermore, in the case where the polymer has carbon-carbon unsaturated bonds in a side chain thereof, the unsaturated bonds may be directly attached to the main chain, and/or may be attached to the main chain via an appropriate linking group.

Examples of the polymer containing carbon-carbon unsaturated bonds in the main chain include SB (polystyrene-polybutadiene), SBS (polystyrene-polybutadiene-polystyrene), SIS (polystyrene-polyisoprene-polystyrene), SEBS (polystyrene-polyethylene/polybutylene-polystyrene), and the like.

In the case of using a polymer having a highly reactive polymerizable unsaturated group such as a methacryloyl group as the polymer having carbon-carbon unsaturated bonds in the side chain, a film having very high mechanical strength may be produced. Particularly, highly reactive polymerizable unsaturated groups may be relatively easily introduced into the molecule into polyurethane thermoplastic elastomers and polyester thermoplastic elastomers.

Any known method may be employed when introduce unsaturated bonds or polymerizable groups into the binder polymer. Examples of the method include: a method of copolymerizing the polymer with a structural unit having a polymerizable group precursor which is formed by attaching a protective group to the polymerizable group, and eliminating the protective group to restore the polymerizable group; and a method of producing a polymer compound having a plurality of reactive groups such as a hydroxyl group, an amino group, an epoxy group, a carboxyl group, an acid anhydride group, a ketone group, a hydrazine residue, an isocyanate group, an isothiacyanate group, a cyclic carbonate group or an ester group, subsequently reacting the polymer compound with a binding agent which has a plurality of groups capable of binding with the reactive group (for example, polyisocyanate and the like for the case of a hydroxyl group or an amino group), to thereby carry out adjustment of the molecular weight and conversion to a bindable group at the chain end, and then reacting this group which is capable of reacting with the terminal bindable group, with an organic compound having a polymerizable unsaturated group, to thus introduce a polymerizable group by means of a polymer reaction. When these methods are used, the amount of introduction of the unsaturated bond or the polymerizable group into the polymer compound may be controlled.

It is also preferable to use the polymer having an unsaturated bond in combination with a polymer which does not have an unsaturated bond. That is, since a polymer obtainable by adding hydrogen to the olefin moiety of the polymer having carbon-carbon unsaturated bonds, or a polymer obtainable by forming a polymer using as a raw material a monomer in which an olefin moiety has been hydrogenated, such as a monomer resulting from hydrogenation of butadiene, isoprene or the like, has excellent compatibility, the polymer may be used in combination with the polymer having unsaturated bonds, so as to regulate the amount of unsaturated bonds possessed by the binder polymer.

In the case of using these in combination, the polymer which does not have unsaturated bonds may be used in a proportion of generally 1 parts by mass to 90 parts by mass, and preferably 5 parts by mass to 80 parts by mass, with respect to 100 parts by mass of the polymer having unsaturated bonds.

As will be discussed later, in aspects where curability is not required for the binder polymer, such as in the case of using another polymerizable compound in combination, the binder polymer does not necessarily contain an unsaturated bond, and a variety of polymers which do not have unsaturated bonds may be solely used as the binder polymer in the relief forming layer. Examples of the polymer which does not have unsaturated bonds and can be used in such a case include polyesters, polyamides, polystyrene, acrylic resins, acetal resins, polycarbonates and the like.

The binder polymer suitable for the use in the invention, which may or may not have unsaturated bonds, has a number average molecular weight preferably in the range of from 1,000 to 1,000,000, and more preferably in the range of from 5,000 to 500,000. When the number average molecular weight of the binder polymer is in the range of 1,000 to 1,000,000, the mechanical strength of the film to be formed may be secured. Here, the number average molecular weight is a value measured using gel permeation chromatography (GPC), and reduced with respect to polystyrene standard products with known molecular weights.

Thermoplastic polymer and Polymer having decomposability

Examples of the other binder polymer which may be preferably used from the viewpoint of assuring laser engraving sensitivity include a thermoplastic polymer which can be liquefied by being imparted with energy by means of exposure and/or heating, and a polymer having a partial structure which can be decomposed by being imparted with energy by means of exposure and/or heating.

Examples of the polymer having decomposability include those polymers containing, as a monomer unit having in the molecular chain a partial structure which is likely to be decomposed and cleaved, styrene, α-methylstyrene, α-methoxystyrene, acryl esters, methacryl esters, ester compounds other than those described above, ether compounds, nitro compounds, carbonate compounds, carbamoyl compounds, hemiacetal ester compounds, oxyethylene compounds, aliphatic cyclic compounds, and the like.

In view of the reasons similar to those for the binder polymer (A), the other binder can be preferably selected from those having a glass transition temperature (Tg) of 20° C. or more and less than 200° C., more preferably from those having a Tg being in a range from 20° C. to 170° C., and particularly preferably from those having a Tg being in a range from 25° C. to 150° C.

Among these, polyethers such as polyethylene glycol, polypropylene glycol and polytetraethylene glycol, aliphatic polycarbonates, aliphatic carbamates, polymethyl methacrylate, polystyrene, nitrocellulose, polyoxyethylene, polynorbornene, polycyclohexadiene hydrogenation products, or a polymer having a molecular structure having many branched structures such as dendrimers, may be particularly preferably exemplified in terms of decomposability.

A polymer containing a number of oxygen atoms in the molecular chain is preferable from the viewpoint of decomposability. From this point of view, compounds having a carbonate group, a carbamate group or a methacryl group in the polymer main chain, may be suitably exemplified.

For example, a polyester or polyurethane synthesized from a (poly)carbonate diol or a (poly)carbonate dicarboxylic acid as the raw material, a polyamide synthesized from a (poly)carbonate diamine as the raw material, and the like may be exemplified as the examples of polymers having good thermal decomposability. These polymers may also be those containing a polymerizable unsaturated group in the main chain or the side chains. Particularly, in the case of a polymer having a reactive functional group such as a hydroxyl group, an amino group or a carboxyl group, it is also easy to introduce a polymerizable unsaturated group into such a thermally decomposable polymer.

The thermoplastic polymer may be an elastomer or a non-elastomer resin, and may be selected according to the purpose of the resin composition of the invention, while it can be preferably a non-elastomer resin, namely a polymer having a Tg of 20° C. or more and less than 200° C., more preferably those having a Tg being in a range from 20° C. to 170° C., and particularly preferably those having a Tg being in a range from 25° C. to 150° C.

Examples of the thermoplastic elastomer include urethane thermoplastic elastomers, ester thermoplastic elastomers, amide thermoplastic elastomers, silicone thermoplastic elastomers and the like. For the purpose of enhancing the laser engraving sensitivity of such a thermoplastic elastomer, an elastomer in which an easily decomposable functional group such as a carbamoyl group or a carbonate group has been introduced into the main chain, may also be used. A thermoplastic polymer may also be used as a mixture with the thermally decomposable polymer.

The thermoplastic elastomer is a material showing rubber elasticity at normal temperature, and the molecular structure includes a soft segment such as polyether or a rubber molecule, and a hard segment which prevents plastic deformation near normal temperature, as vulcanized rubber does. There exist various types of hard segments, such as frozen state, crystalline state, hydrogen bonding and ion bridging. Such thermoplastic elastomers may be suitable in the case of applying the resin composition of the invention to the production of, for example, relief printing plates requiring plasticity, such as flexo plates.

The kind of the thermoplastic elastomer can be selected according to the purpose. For example, in the case where solvent resistance is required, urethane thermoplastic elastomers, ester thermoplastic elastomers, amide thermoplastic elastomers and fluorine thermoplastic elastomers are preferable. In the case where thermal resistance is required, urethane thermoplastic elastomers, olefin thermoplastic elastomers, ester thermoplastic elastomers and fluorine thermoplastic elastomers are preferable. The hardness of a resin molded product formed from the resin composition can be largely varied according to the selection of the kind of the thermoplastic elastomer.

The use of the thermoplastic elastomer can be effective to provide flexibility to a film formed from the resin composition to provide a so-called flexo printing plate. The content of the thermoplastic elastomer compounded in the resin composition should be in a certain range so as not to adversely affect functions derived from the binder (A) and (B). Specifically, the content of the thermoplastic elastomer is 30% by mass or less with respect to the total amount of the binder (A) and (B).

Examples of the non-elastomeric resin include polyester resins include unsaturated polyester resins, polyamide resins, polyamideimide resins, polyurethane resins, unsaturated polyurethane resins, polysulfone resins, polyethersulfone resins, polyimide resins, polycarbonate resins, all aromatic polyester resins, and hydrophilic polymers containing hydroxyethylene units (for example, polyvinyl alcohol compounds).

(C) Thermopolymerization Initiator

The resin composition of the invention contains a thermopolymerization initiator. Any thermopolymerization initiator that is known to those having ordinary skill in the art may be used in the invention without particular limitation. Specific examples thereof are extensively described in Bruce M. Monroe, et al., Chemical Revue, 93, 435 (1993); R. S. Davidson, Journal of Photochemistry and Biology A: Chemistry, 73, 81 (1993); M. Tsunooka, et al., Prog. Polym. Sci., 21, 1 (1996); and the like. Also known is a family of compounds which oxidatively or reductively cause bond cleavage, such as those described in F. D. Saeva, Topics in Current Chemistry, 156, 59 (1990); G G. Maslak, Topics in Current Chemistry, 168, 1 (1993); H. B. Shuster, et al., JACS, 112, 6329 (1990); I. D. F. Eaton, et al., JACS, 102, 3298 (1980); and the like.

Regarding specific examples of a preferable thermopolymerization initiator, a radical polymerization initiator which generates a radical by heat energy, and initiates and promotes a polymerization reaction of a polymerizale compound will be described in detail below, but the invention is not limited by these descriptions.

In the invention, examples of a preferable radical polymerization initiator include (a) an organic peroxide, (b) a hexaarylbiimidazole compound, (c) an azo compound, and the like. Specific examples of the compounds (a) to (c) will be mentioned below, but the invention is not intended to be limited to these.

(a) Organic Peroxide

Examples of a preferable (c) organic peroxide as the radical polymerization initiator which may be used in the invention include almost all organic compounds having one or more oxygen-oxygen bonds in a molecule

Examples of the organic peroxide include methyl ethyl ketone peroxide, cyclohexanone peroxide, 3,3,5-trimethylcyclohexanone peroxide, methylcyclohexanone peroxide, acetylacetone peroxide, 1,1-bis(tertiary-butylperoxy)-3,3,5-trimethylcyclohexane, 1,1-bis(tertiary-butylperoxy)cyclohexane, 2,2-bis(tertiary-butylperoxy)butane, tertiary-butyl hydroperoxide, cumene hydroperoxide, diisopropylbenzene hydroperoxide, paramethane hydroperoxide, 2,5-dimethylhexane-2,5-dihydroperoxide, 1,1,3,3-tetramethylbutyl hydroperoxide, di-tertiary-butyl peroxide, tertiary-butylcumyl peroxide, dicumyl peroxide, bis(tertiary-butylperoxyisopropyl)benzene, 2,5-dimethyl-2,5-di(tertiary-butylperoxy)hexane, 2,5-xanoyl peroxide, succinic acid peroxide, benzoyl peroxide, 2,4-dichlorobenzoyl peroxide, meta-toluoyl peroxide, diisopropyl peroxydicarbonate, di-2-ethylhexyl peroxydicarbonate, di-2-ethoxyethyl peroxydicarbonate, dimethoxyisopropyl peroxycarbonate, di(3-methyl-3-methoxybutyl)peroxydicarbonate, tertiary-butyl peroxyacetate, tertiary-butyl peroxypivalate, tertiary-butyl peroxyneodecanoate, tertiary-butyl peroxyoctanoate, tertiary-butyl peroxy-3,5,5-trimethylhexanoate, tertiary-butyl peroxylaurate, tertiary carbonate, 3,3′40,4,4′-tetra-(t-butylperoxycarbonyl)benzophenone, 3,3′,4,4′-tetra-(t-amylperoxycarbonyl)benzophenone, 3,3′,4,4′-tetra-(t-hexylperoxycarbonyl)benzophenone, 3,3′,4,4′-tetra-(t-octylperoxycarbonyl)benzophenone, 3,3′,4,4′-tetra-(cumylperoxycarbonyl)benzophenone, 3,3′40,4,4′-tetra-(p-isopropylcumylperoxycarbonyl)benzophenone, carbonyl di(t-butylperoxy dihydrogen diphthalate), carbonyl di(t-hexylperoxy dihydrogen diphthalate), and the like.

Among them, as the organic peroxide, 3,3′,4,4′-tetra-(t-butylperoxycarbonyl)benzophenone, 3,3′,4,4′-tetra-(t-amylperoxycarbonyl)benzophenone, 3,3′,4,4′-tetra-(t-hexylperoxycarbonyl)benzophenone, 3,3′,4,4′-tetra-(t-octylperoxycarbonyl)benzophenone, t-butyl peroxybenzoate, dicumyl peroxide, 3,3′,4,4′-tetra-(cumylperoxycarbonyl)benzophenone, 3,3′,4,4′-tetra-(p-isopropylcumylperoxycarbonyl)benzophenone, di-t-butyl diperoxyisophthalate, and the like are preferable from the viewpoint of crosslinking property and storage stability of the film, and more preferred are t-butyl peroxybenzoate, dicumyl peroxide and t-butyl hydroperoxide.

The organic peroxide is found to be preferable as the polymerization initiator used in the invention in view of improving the crosslinking property of the resin composition as well as obtaining the unexpected effect of improving the engraving sensitivity.

In view of improving the engraving sensitivity, it is particularly preferable that the organic peroxide is combined with a binder polymer having a glass transition temperature that is not lower than ordinary ambient temperatures.

More specifically, when the resin composition is cured by thermal crosslinking with the organic peroxide, unreacted portions of the organic peroxide that have not been involved in radical generation may remain. The remaining organic peroxide may serve as an autoreactive additive, which may be exothermically decomposed during laser engraving. Consequently, the generated heat can be added to the laser energy, which may result in an increase in the engraving sensitivity.

In particular, when the glass transition temperature of the binder polymer is not lower than ordinary ambient temperatures, the heat generated by the decomposition of the organic peroxide can be efficiently transferred to the binder polymer, and effectively used for the thermal decomposition of the binder polymer, which may result in a further increase in engraving sensitivity.

These effects can be achieved to a remarkable degree when carbon black is used as the photo-thermal conversion agent, details of which are given in the explanation of the photo-thermal conversion agent. This is likely due to the fact that heat released from the carbon black is transferred to the organic peroxide to cause heat generation from the organic peroxide, which results in synergistic generation of thermal energy to be used for the decomposition of the binder polymer and the like.

(b) Hexaarylbiimidazole Compound

Examples of the hexaarylbiimidazole compound as the radical polymerization initiator which may be used in the invention include the rofin dimers described in Japanese Patent Application Publication (JP-B) Nos. 45-37377 and 44-86516, for example, 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole, 2,2′-bis(o-trifluorophenyl)-4,4′,5,5′-tetraphenylbiimidazole and the like.

(c) Azo Compound

Examples of the azo compound as the radical polymerization initiator which may be used in the invention include 2,2′-azobisisobutyronitrile, 2,2′-azobispropionitrile, 1,1′-azobis(cyclohexane-1-carbonitrile), 2,2′-azobis(2-methylbutyronitrile), 2,2′-azobis(2,4-dimethylvaleronitrile), 2,2′-azobis(4-methoxy-2,4-dimethylvaleronitrile), 4,4′-azobis(4-cyanovaleric acid), dimethyl 2,2′-azobisisobutyrate, 2,2′-azobis(2-methylpropionamidoxime), 2,2′-azobis[2-(2-imidazolin-2-yl)propane], 2,2′-azobis{2-methyl-N-[1,1-bis(hydroxymethyl)-2-hydroxyethyl]propionamide}, 2,2′-azobis[2-methyl-N-(2-hydroxyethyl)propionamide], 2,2′-azobis(N-butyl-2-methylpropionamide), 2,2′-azobis(N-cyclohexyl-2-methylpropionamide), 2,2′-azobis[N-(2-propenyl)-2-methylpropionamide], 2,2′-azobis(2,4,4-trimethylpentane), and the like.

In the total solid content of the resin composition of the invention, the (C) thermopolymerization initiator may be added in a proportion of preferably from 0.01% by mass to 10% by mass, and more preferably from 0.1% by mass to 3% by mass.

The thermopolymerization initiators may be suitably used individually or in combination of two or more species.

(D) Polymerizable Compound

The resin composition of the invention contains a polymerizable compound.

The “polymerizable compound” in the invention means a compound having at least one carbon-carbon unsaturated bond capable of radical polymerization triggered by the generation of a starting radical derived from a polymerization initiator. More specific explanation will be given with taking an example of using an addition polymerizable compound as the polymerizable compound.

Examples of the polymerizable compound that can be preferably used in the invention include an addition polymerizable compound having at least one ethylenic unsaturated double bond. This addition polymerizable compound is preferably selected from compounds having at least one, preferably two or more, terminal ethylenic unsaturated bonds. The family of such compounds is widely known in the pertinent industrial field, and these compounds may be used in the invention without any particular limitations. These compounds respectively have a chemical form such as a monomer, a prepolymer such as a dimer or a trimer, an oligomer, a copolymer thereof, or a mixture of any of these. Examples of the monomer include unsaturated carboxylic acids (for example, acrylic acid, methacrylic acid, itaconic acid, crotonic acid, isocrotonic acid, maleic acid, and the like), esters thereof, and amides thereof. Preferable examples thereof include esters of an unsaturated carboxylic acid and an aliphatic polyhydric alcohol compound and amides of an unsaturated carboxylic acid and an aliphatic polyvalent amine compound. Further, unsaturated carboxylic acid esters having a nucleophilic substituent such as a hydroxyl group, an amino group or a mercapto group; adducts of an amide with a monofunctional or polyfunctional isocyanate or an epoxy compound; dehydration condensation reaction products of an amide with a monofunctional or polyfunctional carboxylic acid, and the like may also be suitably used. Unsaturated carboxylic acid esters having an electrophilic substituent such as an isocyanate group or an epoxy group; adducts of an amide with a monofunctional or polyfunctional alcohol, an amine or a thiol; unsaturated carboxylic acid esters having a detachable substituent such as a halogen group or a tosyloxy group; substitution reaction products of an amide with a monofunctional or polyfunctional alcohol, an amine or a thiol, are also suitable. A family of compounds formed by modifying the above-described compounds by introducing an unsaturated phosphonic acid, styrene, vinyl ether or the like in place of the unsaturated carboxylic acid may also be used.

Specific examples of the monomer of an ester between an aliphatic polyhydric alcohol compound and an unsaturated carboxylic acid include, as acrylic acid esters, ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl) isocyanurate, a polyester acrylate oligomer, and the like.

Examples of methacrylic acid esters include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, bis-[p-(methacryloxyethoxy)phenyl]dimethylmethane, and the like.

Examples of itaconic acid esters include ethylene glycol diitaconate, propylene glycol diitaconate, 1,3-butanediol diitaconate, 1,4-butanediol diitaconate, tetramethylene glycol diitaconate, pentaerythritol diitaconate, sorbitol tetraitaconate, and the like.

Examples of crotonic acid esters include ethylene glycol dicrotonate, tetramethylene glycol dicrotonate, pentaerythritol dicrotonate, sorbitol tetracrotonate, and the like.

Examples of isocrotonic acid esters include ethylene glycol diisocrotonate, pentaerythritol diisocrotonate, sorbitol tetraisocrotonate, and the like.

Examples of maleic acid esters include ethylene glycol dimaleate, triethyelen glycol dimaleate, pentaerythritol dimaleate, sorbitol tetramaleate, and the like.

As examples of other esters, for example, the aliphatic alcohol-based esters described in JP-B Nos. 46-27926, 51-47334 and JP-A No. 57-196231; the esters having an aromatic-based skeleton described in JP-A Nos. 59-5240, 59-5241 and 2-226149; and the esters containing an amino group described in JP-A No. 1-165613; and the like, may also be suitably used.

The ester monomers described above may also be used as mixtures.

Specific examples of the monomer of an amide between an aliphatic polyvalent amine compound and an unsaturated carboxylic acid, include methylenebisacrylamide, methylenebismethacrylamide, 1,6-hexamethylenebisacrylamide, 1,6-hexamethylenebismethacrylamide, diethylenetriamine trisacrylamide, xylylenebisacrylamide, xylylenebismethacrylamide, and the like.

Examples of other preferable amide-based monomers include the monomers having a cyclohexylene structure described in JP-B No. 54-21726.

Furthermore, urethane-based addition polymerizable compounds produced by using an addition reaction between an isocyanate group and a hydroxyl group are also suitable, and specific examples thereof include, for example, the vinylurethane compounds containing two or more polymerizable vinyl groups in one molecule, produced by adding a vinyl monomer containing a hydroxyl group as represented by the following Formula (B), to a polyisocyanate compound having two or more isocyanate groups in one molecule, as described in JP-B No. 48-41708, and the like.

CH₂═C(R¹)COOCH₂CH(R²)OH (B)

wherein R¹ and R² each represent H or CH₃.

The urethane acrylates such as those described in JP-A No. 51-37193, JP-B Nos. 2-32293 and 2-16765; or the urethane compounds having an ethylene oxide-based skeleton described in JP-B Nos. 58-49860, 56-17654, 62-39417 and 62-39418, are also suitable.

If the addition polymerizable compounds having an amino structure or a sulfide structure in the molecule, as described in JP-A Nos. 63-277653, 63-260909 and 1-105238, are used, rapidly curable resin compositions may be obtained.

Other examples thereof include polyfunctional acrylates or methacrylates such as the polyester acrylates and epoxy acrylates obtained by reacting an epoxy resin and (meth)acrylic acid, such as those described in JP-A No. 48-64183, JP-B Nos. 49-43191 and 52-30490; the specific unsaturated compounds described in JP-B Nos. 46-43946, 1-40337 and 1-40336; the vinylphosphonic acid-based compounds described in JP-A No. 2-25493; and the like. Under certain circumstances, the structure containing a perfluoroalkyl group described in JP-A No. 61-22048 is also suitably used. The compounds introduced in Journal of the Adhesion Society of Japan, Vol. 20, No. 7, pp. 300-308 (1984) as photocurable monomers and oligomers, may also be used.

In view of the speed of reaction, compounds having a structure having a large content of unsaturated groups per molecule are preferable, and in many cases, bifunctional or higher-functional compounds are preferred. Furthermore, in order to increase the strength of the image areas, that is, the cured film, trifunctional or higher-functional compounds are desirable, and a method of controlling both reactivity and strength by using compounds having different functionalities or different polymerizable groups (for example, acrylic acid esters, methacrylic acid esters, styrene-based compounds, and vinyl ether-based compounds) in combination, is also effective. The addition polymerizable compound is used in an amount in the range of preferably 10% by mass to 60% by mass, and more preferably 15% by mass to 40% by mass, of the resin composition of the invention.

These polymerizable compounds may be used singly, or in combination of two or more species thereof. When the polymerizable compounds are used, film properties, for example, brittleness and flexibility, may be adjusted.

Preferable specific examples of the polymerizable compound usable in the resin composition of the invention are shown below, while the invention is not limited thereby.

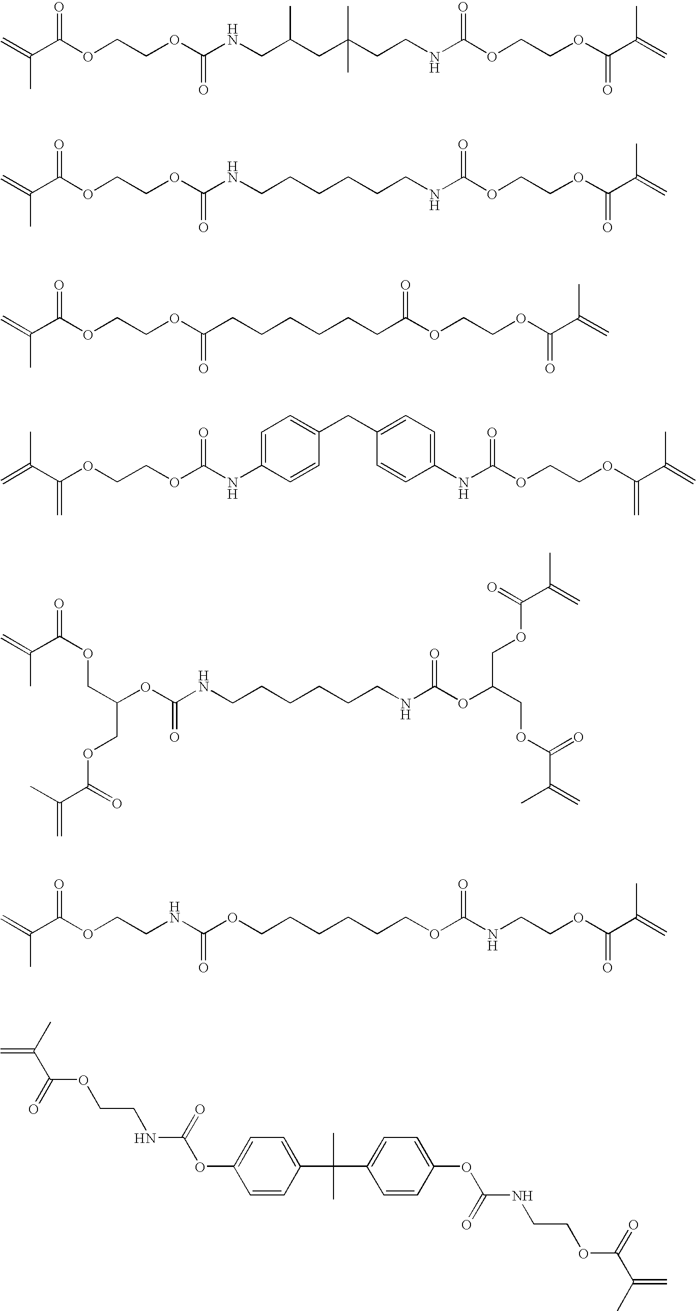

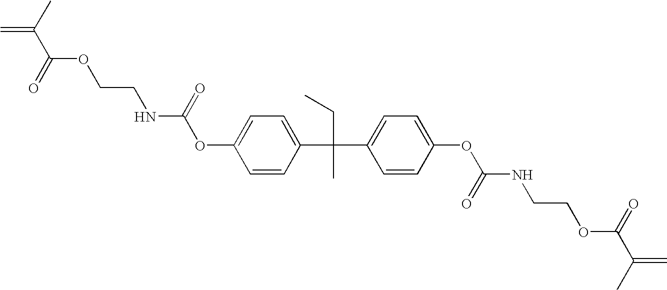

In the case of applying a resin composition for laser engraving containing the polymerizable compound to a relief forming layer of a relief printing plate precursor, compounds containing sulfur (S) atoms are particularly preferred among the polymerizable compounds, from the viewpoint that edge fusion of the relief may hardly occur and thus provide sharp (well-defined) relief can be easily obtained. That is, a compound contains a sulfur atom in a crosslinked network therein are preferable.

While a polymerizable compound which contains a sulfur atom and a polymerizable compound which does not contain a sulfur atom may also be used in combination, it is preferable to use the polymerizable compound containing a sulfur is singly used from the viewpoint that edge fusion of a relief formed from the relief forming layer containing thereof may hardly occur. A use of plural sulfur-containing polymerizable compounds having different characteristics in combination may contribute to the control of the film flexibility and the like.

Examples of the polymerizable compound containing a sulfur atom include the following compounds.

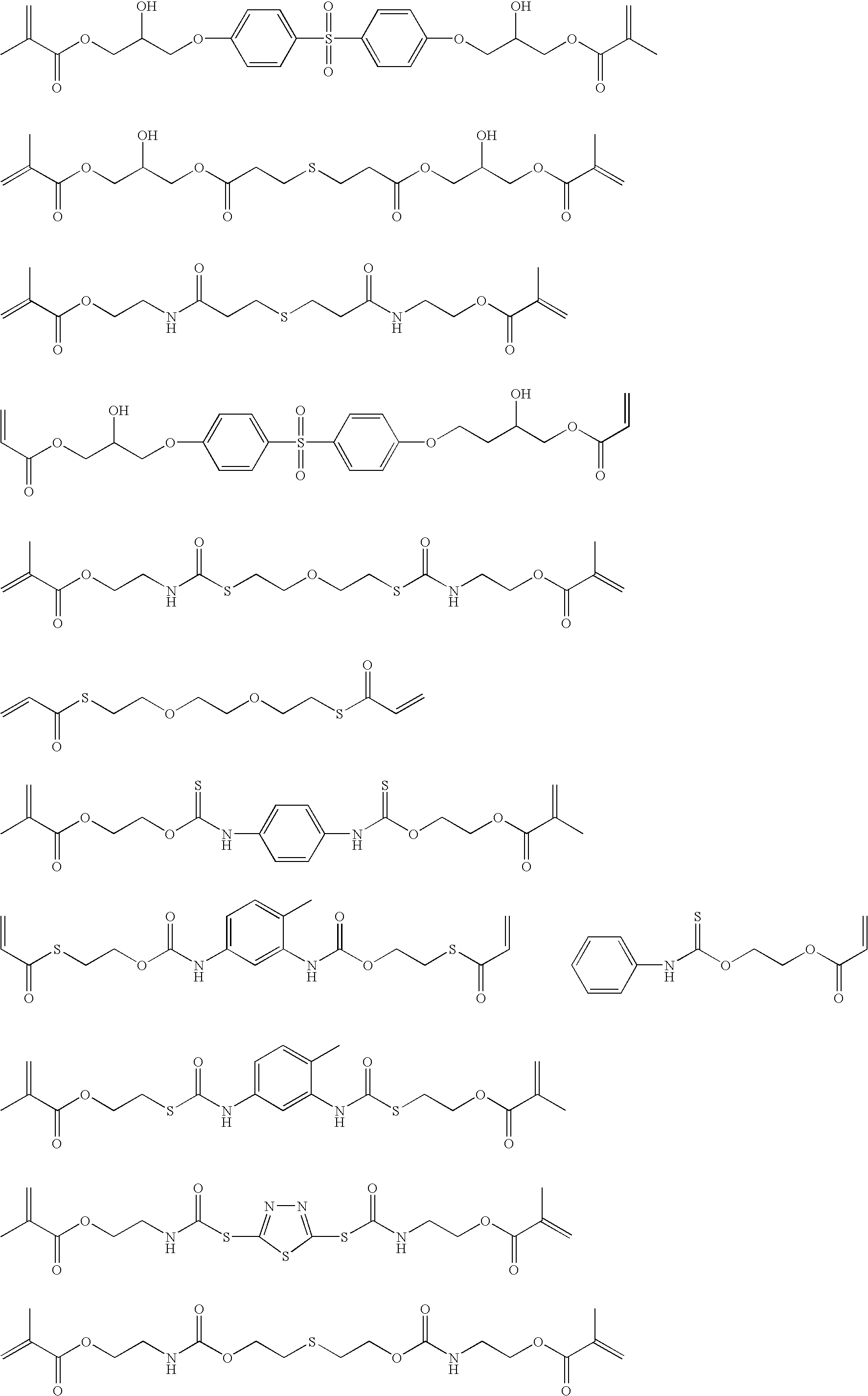

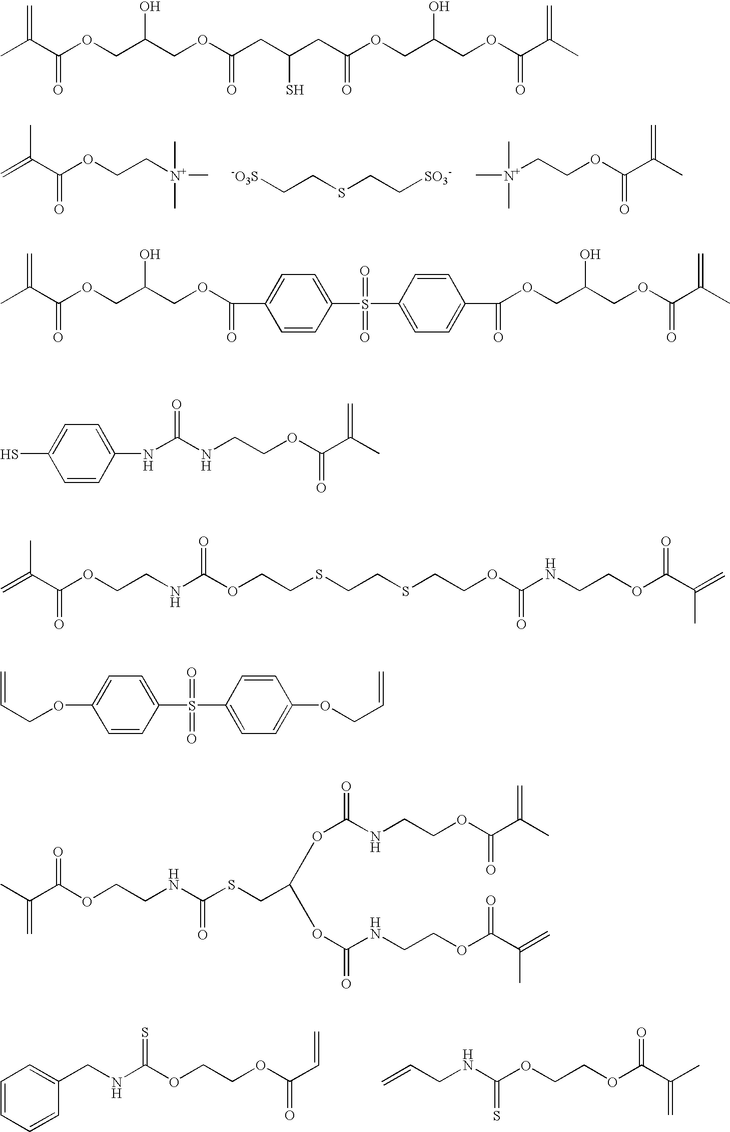

The resin composition of the invention preferably includes, as essential components, the above-described (A) inorganic porous material, (B) binder polymer, (C) thermopolymerization initiator, and (D) polymerizable compound, as well as optional components such as (E) a photothermal conversion agent and (F) a plasticizer, which will be described later. Hereinafter, each of these components will be described in detail.

(E) Photothermal Conversion Agent

The resin composition of the invention preferably contains a photothermal conversion agent which is capable of absorbing a light having a wavelength of 700 nm to 1300 nm.

When the resin composition contains such a photothermal conversion agent, in the case of performing laser engraving on the resin composition of the invention using, for example, a laser emitting an infrared light having a wavelength of 700 nm to 1300 nm (a YAG laser, a semiconductor laser, a fiber laser, a surface emitting laser, or the like) as the light source, the engraving sensitivity of the process may be increased. That is, such a photothermal conversion agent absorbs laser light to generate heat, and enhances thermal decomposition of the resin composition.

The photothermal conversion agent according to the invention is a compound having the maximum absorption wavelength in the wavelength region of 700 nm to 1300 nm. Particularly, the photothermal conversion agent is preferably a dye or a pigment having the maximum absorption at a wavelength ranging from 700 nm to 1300 nm.

Commercially available dyes and known dyes that are described in literatures such as “Handbook of Dyes” (edited by the Society of Synthetic Organic Chemistry, Japan, 1970), may be used as for the dye. Specific examples thereof include azo dyes, metal complex azo dyes, pyrazolone azo dyes, naphthoquinone dyes, anthraquinone dyes, phthalocyanine dyes, carbonium dyes, diimmonium compounds, quinonimine dyes, methine dyes, cyanine dyes, squarylium colorants, pyrylium salts, and metal thiolate complexes.

Preferable examples of the dye include the cyanine dyes described in JP-A Nos. 58-125246, 59-84356, 59-202829, 60-78787 and the like; the methine dyes described in JP-A Nos. 58-173696, 58-181690, 58-194595, and the like; the naphthoquinone dyes described in JP-A Nos. 58-112793, 58-224793, 59-48187, 59-73996, 60-52940, 60-63744 and the like; the squarylium colorants described in JP-A No. 58-112792 and the like; the cyanine dyes described in U.K. Patent No. 434,875; and the like.

Preferable examples of the dye further include the near-infrared absorption sensitizers described in U.S. Pat. No. 5,156,938, the substituted arylbenzo(thio)pyrylium salts described in U.S. Pat. No. 3,881,924; the trimethinethiapyrylium salts described in JP-A No. 57-142645 (U.S. Pat. No. 4,327,169); the pyrylium-compounds described in JP-A Nos. 58-181051, 58-220143, 59-41363, 59-84248, 59-84249, 59-146063 and 59-146061; the cyanine dyes described in JP-A No. 59-216146; the pentamethinethiopyrylium salts and the like described in U.S. Pat. No. 4,283,475; and the pyrylium compounds described in JP-B Nos. 5-13514 and 5-19702. Preferable examples of the dye furthermore include the near-infrared absorption dyes represented by formulae (I) and (II) in U.S. Pat. No. 4,756,993.

Preferable examples of the photo-thermal conversion agent of the invention include the specific indolenine cyanine colorants described in JP-A No. 2002-278057.

Particularly preferable examples among these dyes include cyanine colorants, squarylium colorants, pyrylium salts, nickel thiolate complexes, and indolenine cyanine colorants. Cyanine colorants or indolenine cyanine colorants are even more preferable.

Specific examples of the cyanine colorants which may be suitably used in the invention include those described in paragraphs 0017 to 0019 of JP-A No. 2001-133969, paragraphs 0012 to 0038 of JP-A No. 2002-40638, and paragraphs 0012 to 0134 of JP-A No. 2002-23360.

The colorants represented by following Formula (d) or Formula (e) are preferable from the viewpoint of photo-thermal conversion property.

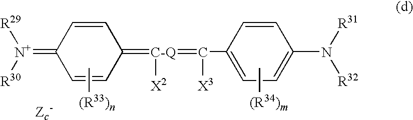

In Formula (d), R²⁹ to R³¹ each independently represent a hydrogen atom, an alkyl group or an aryl group; R³³ and R³⁴ each independently represent an alkyl group, a substituted oxy group, or a halogen atom; n and m each independently represent an integer from 0 to 4; R²⁹ and R³⁰, or R³¹ and R³² may be respectively be bound to each other to form a ring, and R²⁹ and/or R³⁰ may be bound to R³³, and R³¹ and/or R³² may be bound to R³⁴, to respectively form a ring; if a plurality of R³³ are present, the R³³s may be bound to each other to form a ring; if a plurality of R³⁴ are present, the R³⁴s may be bound to each other to form a ring; X² and X³ each independently represent a hydrogen atom, an alkyl group or an aryl group, and at least one of X² and X³ represents a hydrogen atom or an alkyl group; Q represents a trimethine group or pentamethine group which may be substituted, and may form a cyclic structure together with a divalent organic group; and Zc⁻ represents a counter-anion. However, if the colorant represented by Formula (d) has an anionic substituent in the structure and does not require charge neutralization, Zc⁻ is not necessary. Preferably, Zc⁻ is a halogen ion, a perchloric acid ion, a tetrafluoroborate ion, a hexafluorophosphate ion or a sulfonic acid ion, from the viewpoint of the storage stability of the photosensitive layer coating solution, and particularly preferably, Zc⁻ is a perchloric acid ion, a hexafluorophosphate ion or an arylsulfonic acid ion.

Specific examples of the dyes represented by Formula (d), which may be suitably used in the invention, include those shown below.

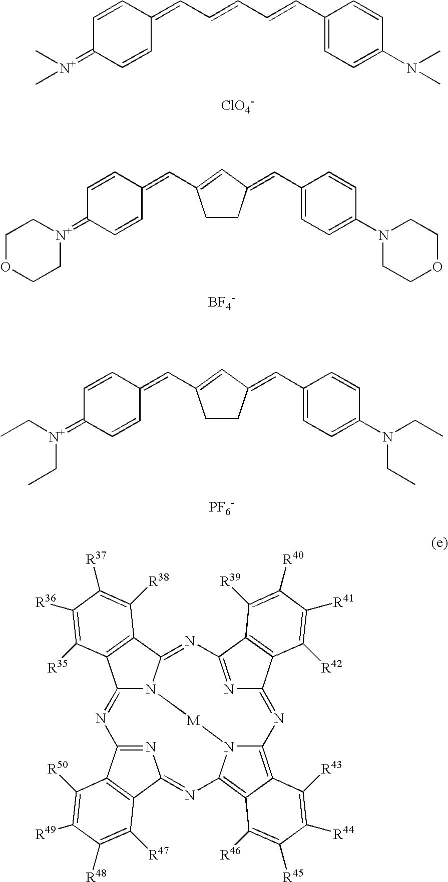

In Formula (e), R³⁵ to R⁵⁰ each independently represent a hydrogen atom, a halogen atom, a cyano group, an alkyl group, an aryl group, an alkenyl group, an alkynyl group, a hydroxyl group, a carbonyl group, a thio group, a sulfonyl group, a sulfinyl group, an oxy group, an amino group, or an onium salt structure, and if it is possible to introduce substituents to these groups, the groups may be substituted; M represents two hydrogen atoms or metal atoms, a halo-metal group, or an oxy-metal group, and as the metal atoms included therein, there may be mentioned the atoms of Groups IA, IIA, IIIB and IVB of the Period Table of Elements, the first-row, second-row and third-row transition metals, and lanthanoid elements. Among them, copper, magnesium, iron, zinc, cobalt, aluminum, titanium and vanadium are preferable.

Specific examples of the dyes represented by Formula (e), which may be suitably used in the invention, include those shown below.

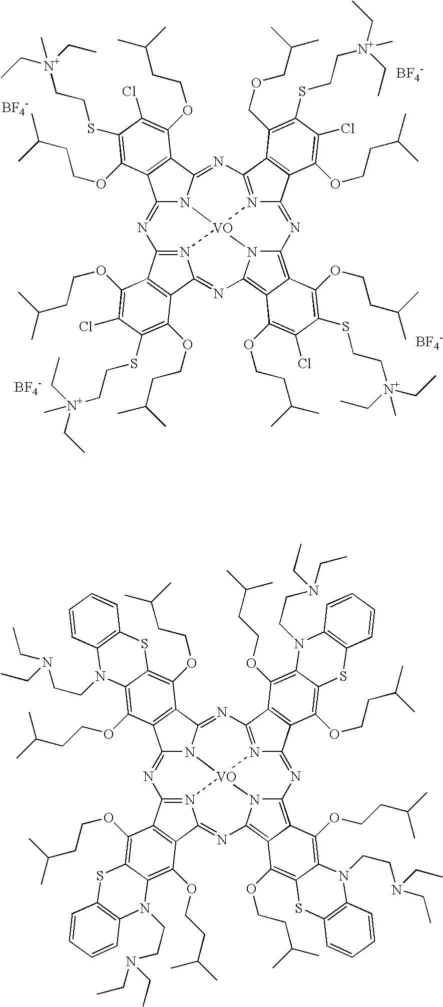

Examples of the pigment which may be used in the invention include commercially available pigments, and the pigments described in the Color Index (C.I.) Handbook, “Handbook of New Pigments” (edited by Japan Association of Pigment Technology, 1977), “New Pigment Application Technology” (published by CMC, Inc., 1986), and “Printing Ink Technology” (published by CMC, 1984).

Examples of the pigments include black pigments, yellow pigments, orange pigments, brown pigments, red pigments, magenta pigments, blue pigments, green pigments, fluorescent pigments, metal powder pigments, and other polymer-bound pigments. Specifically, insoluble azo pigments, azo lake pigments, condensed azo pigments, chelate azo pigments, phthalocyanine pigments, anthraquinone pigments, perylene- and perinone pigments, thio indigo pigments, quinacridone pigments, dioxazine pigments, isoindolinone pigments, quinophthalone pigments, dyed lake pigments, azine pigments, nitroso pigments, nitro pigments, natural pigments, fluorescent pigments, inorganic pigments, carbon black, and the like may be used. Among these pigments, carbon black is preferable.

These pigments may be used without being subjected to a surface treatment, or may be used after being subjected to a surface treatment. Examples of a method of the surface treatment include a method of coating the pigment surface with resin or wax, a method of adhering surfactants to the pigment surface, a method of binding a reactive substance (for example, a silane coupling agent, an epoxy compound, polyisocyanate, or the like) to the pigment surface, and the like. These surface treatment methods are described in “Properties and Applications of Metal Soaps” (published by Saiwai Shobo Co., Ltd.), “Printing Ink Technology” (published by CMC, Inc., 1984), and “New Pigment Application Technology” (published by CMC, Inc., 1986).

The particle size of the pigment is preferably in the range of 0.01 μm to 10 μm, more preferably in the range of 0.05 μm to 1 μm, and particularly preferably in the range of 0.1 μm to 1 μm. When the particle size of the pigment is 0.01 μm or larger, the dispersion stability of the pigment in the coating solution can be increased. Also, when the particle size is 10 μm or less, the uniformity of the layer formed from the resin composition can be improved.

Any known dispersing technologies that are used in the production of ink or in the production of toner may be used as the method for dispersing the pigment. Examples of the dispersing instrument used in the dispersing include an ultrasonic dispersing machine, a sand mill, an attritor, a pearl mill, a super mill, a ball mill, an impeller, a disperser, a KD mill, a colloid mill, Dynatron, a triple-roll mill, a pressurized kneader, and the like. Details are described in “New Pigment Application Technology” (published by CMC, Inc., 1986).

In embodiments, the photo-thermal conversion agent used in the invention can be at least one selected from cyanine compounds and phthalocyanine compounds, which are preferable from the viewpoint of high engraving sensitivity. The engraving sensitivity tends to be further increased and is thus preferable when at least one of these photo-thermal conversion agents are used in a combination under a condition that the thermal decomposition temperature of the photo-thermal conversion agent is equal to or higher than the thermal decomposition temperature of a hydrophilic polymer which is suitable as the binder polymer.

Specific examples of the photo-thermal conversion agent that may be used in the invention include a colorant which have a maximum absorption wavelength in the range of 700 nm to 1,300 nm and is selected from cyanine colorants such as heptamethine cyanine colorants, oxonol colorants such as pentamethine oxonol colorants, indolium colorants, benzindolium colorants, benzothiazolium colorants, quinolinium colorants, phthalide compounds reacted with a color developing agent, and the like. Photo-absorption properties of colorants greatly vary depending on the type and the intramolecular position of the substituent, the number of conjugate bonds, the type of counterion, the surrounding environment around the colorant molecule, or the like.

Commercially available laser colorants, hypersaturated absorption colorants, and near-infrared absorption colorants may also be used. Examples of the laser colorants include “ADS740PP”, “ADS745HT”, “ADS760MP”, “ADS740WS”, “ADS765WS”, “ADS745HO”, “ADS790NH” and “ADS800NH” (all trade names, manufactured by American Dye Source, Inc. (Canada)); and “NK-3555”, “NK-3509” and “NK-3519” (all trade names, manufactured by Hayashibara Biochemical Labs, Inc.). Examples of the near-infrared absorption colorants include “ADS775MI”, “ADS775MP”, “ADS775HI”, “ADS775PI”, “ADS775PP”, “ADS780MT”, “ADS780BP”, “ADS793E1”, “ADS798MI”, “ADS798MP”, “ADS800AT”, “ADS805PI”, “ADS805PP”, “ADS805PA”, “ADS805 PF”, “ADS812MI”, “ADS815E1”, “ADS818HI”, “ADS818HT”, “ADS822MT”, “ADS830AT”, “ADS838MT”, “ADS840MT”, “ADS845BI”, “ADS905AM”, “ADS956BI”, “ADS1040T”, “ADS1040P”, “ADS1045P”, “ADS1050P”, “ADS1060A”, “ADS1065A”, “ADS1065P”, “ADS1100T”, “ADS1120F”, “ADS1120P”, “ADS780WS”, “ADS785WS”, “ADS790WS”, “ADS805WS”, “ADS820WS”, “ADS830WS”, “ADS850WS”, “ADS780HO”, “ADS810CO”, “ADS820HO”, “ADS821NH”, “ADS840NH”, “ADS880MC”, “ADS890MC” and “ADS920MC” (all trade names, manufactured by American Dye Source, Inc. (Canada)); “YKR-2200”, “YKR-2081”, “YKR-2900”, “YKR-2100” and “YKR-3071” (all trade names, manufactured by Yamamoto Chemical Industry Co., Ltd.); “SDO-1000B” (trade name, manufactured by Arimoto Chemical Co., Ltd.); and “NK-3508” and “NKX-114” (both trade names, manufactured by Hayashibara Biochemical Labs, Inc.), while the examples are not intended to be limited to these.

Those described in Japanese Patent No. 3271226 may be used as the phthalide compound reacted with a color developing agent. Phosphoric acid ester metal compounds, for example, the complexes of a phosphoric acid ester and a copper salt described in JP-A No. 6-345820 and WO 99/10354, may also be used as the photo-thermal conversion agent. Further, ultramicroparticles having light absorption characteristics in the near-infrared region, and having a number average particle size of preferably 0.3 μm or less, more preferably 0.1 μm or less, and even more preferably 0.08 μm or less, may also be used as the photo-thermal conversion agent. Examples thereof include metal oxides such as yttrium oxide, tin oxide and/or indium oxide, copper oxide or iron oxide, and metals such as gold, silver, palladium or platinum. Also, compounds obtained by adding metal ions such as the ions of copper, tin, indium, yttrium, chromium, cobalt, titanium, nickel, vanadium and rare earth elements, into microparticles made of glass or the like, which have a number average particle size of 5 μm or less, and more preferably 1 μm or less, may also be used as the photo-thermal conversion agent.

In the case that the colorant may react with a component contained in the resin composition of the invention and causes a change in its maximum absorption wavelength of light absorption, the colorant may be encapsulated in microcapsules. In that case, the number average particle size of the capsules is preferably 10 μm or less, more preferably 5 μm or less, and even more preferably 1 mm or less. Compounds obtained by adsorbing metal ions of copper, tin, indium, yttrium, rare earth elements or the like on ion-exchanged microparticles, may also be used as the photo-thermal conversion agent. The ion-exchanged microparticles may be any of organic resin microparticles or inorganic microparticles. Examples of the inorganic microparticles include amorphous zirconium phosphate, amorphous zirconium phosphosilicate, amorphous zirconium hexametaphosphate, lamellar zirconium phosphate, reticulated zirconium phosphate, zirconium tungstate, zeolites and the like. Examples of the organic resin microparticles include generally used ion-exchange resins, ion-exchange celluloses, and the like.

The most suitable embodiment of the photothermal conversion agent used in the invention is carbon black, from the viewpoint of providing high engraving sensitivity. Since carbon black has high heat resistance as compared with organic dyes or organic pigments, carbon black is less susceptible to self-decomposition caused by the heat generated by photothermal conversion thereof during laser irradiation, and since carbon black can stably emit heat during laser irradiation, carbon black is presumed to be advantageous in enhancing the crosslinking efficiency of the thermal crosslinking process. Further, organic dyes and organic pigments have low heat resistance, due to the properties of organic compounds, and undergo self-decomposition caused by the heat generated by photothermal conversion thereof during laser irradiation, and are thus inferior to carbon black in terms of stable heat emission during laser irradiation.

For the above reasons, it is thought that when carbon black is used, the sensitivity becomes particularly high.

Any kind of carbon black may be used as long as the carbon black has stable dispersibility or the like in the resin composition. The carbon black may be a product classified according to the American Society for Testing and Materials (ASTM) standard or may be those usually used in various applications such as coloring, rubber making, or batteries.

Examples of the carbon black include furnace black, thermal black, channel black, lamp black, acetylene black, and the like. In addition, black-colored colorants such as carbon black may be used in the form of color chips or color pastes, in which the colorants have been dispersed in advance in nitrocellulose, a binder or the like, using a dispersant as necessary, in order to facilitate dispersion thereof. Such chips or pastes can be easily obtained as commercially available products.

When carbon black is used, photo-crosslinking utilizing UV light or the like is not suitable, and thermal crosslinking is preferable in terms of the curability of the film formed by the resin composition. Further, it is more preferable that carbon black is used in combination with the organic peroxide as the thermopolymerization initiator in view of achieving remarkably high engraving sensitivity.

In particularly preferable embodiments of the invention, a binder polymer having a glass transition temperature not lower than ordinary ambient temperatures, an organic peroxide as the polymerization initiator, and carbon black as the photo-thermal conversion agent, are used in combination.

When the resin composition is subjected to thermal crosslinking with the organic peroxide used as the thermopolymerization initiator, unreacted portions of the organic peroxide remain in the film. The remaining portions of the organic peroxide serve as an autoreactive additive, and are exothermically decomposed during laser engraving. Consequently, the heat generated therefrom can be added to the laser energy, which results in the increase in the engraving sensitivity. When the carbon black coexists in the system, heat generated by the photo-thermal conversion function of the carbon black can be transferred to the organic peroxide as well as the binder polymer. As a result of this, heat can be generated not only from the carbon black but also from the organic peroxide, which results in synergistic generation of thermal energy to be used for the decomposition of the binder polymer. In this regard, organic dyes and pigments other than carbon black may also act in the same manner. However, organic dyes and pigments, which have low heat resistance, may be not endure the above-described synergetic heat generation, and may be thus decomposed. Accordingly, uses of organic dyes and pigments other than carbon black may not achieve as high sensitivity as that achieved by carbon black.

When the glass transition temperature of the binder polymer is not lower than room temperature, the heat generated by the decomposition of the organic peroxide and released from the carbon black can be efficiently transferred to the binder polymer, and the heat can be effectively used for the thermal decomposition of the binder polymer, which may result in the achievement of the above-described effects.

Furthermore, in the case of forming a relief forming layer of a relief printing plate precursor by applying the resin composition of the invention, if carbon black is used in combination with an inorganic porous material, a relief forming layer having a good surface state may be obtained. The action mechanism that is supposed in this regard is as described previously.

The content of the photothermal conversion agent in the resin composition of the invention may vary largely depending on the magnitude of the molecular extinction coefficient inherent to the molecule, but the content is preferably in the range of from 0.01% by mass to 20% by mass, more preferably in the range of from 0.05% by mass to 10% by mass, and particularly preferably in the range of from 0.1% by mass to 5% by mass, with respect to the total solid content of the resin composition.

(F) Plasticizer

The resin composition of the invention preferably contains a plasticizer. Examples of the plasticizer include dioctyl phthalate, didodecyl phthalate, triethylene glycol dicaprylate, methyl glycol phthalate, tricresyl phosphate, dioctyl adipate, dibutyl sebacate, triacetylglycerin, and the like. Examples of the plasticizer further include polyethylene glycols, polypropylene glycol (mono-ol type, diol type and the like), and polypropylene glycol (mono-ol type, diol type and the like).

Since the plasticizer is expected to have an effect to soften a molded article which is formed from a resin composition, the plasticizer is desired to have good compatibility with the binder polymer. In general, a highly hydrophilic compound has good compatibility with the binder polymer. Among highly hydrophilic compounds, an ether compound containing a heteroatom in a straight chain, or a compound having a structure in which a hydrophilic group such as secondary amine and a hydrophobic group are alternately repeated, can be preferably used. The presence of the hydrophilic group such as —O— or —NH— achieves the compatibility of such compounds with PVA compounds, and the other hydrophobic group weakens the intermolecular force of PVA compounds, to thereby contribute to the softening.

A compound having fewer hydroxyl groups which are capable of forming hydrogen bonding between PVA compounds can be also preferably used as the plasticizer. Examples of such compound include ethylene glycol, propylene glycol, and dimers, trimers, and homo-oligomers or co-oligomers such as tetramer or higher-mers of ethylene glycol and propylene glycol, and secondary amines such as diethanolamine and dimethylolamine. Among these, ethylene glycols (monomers, dimers, trimers and oligomers) having small steric hindrance, excellent compatibility and low toxicity, are particularly preferably used as the plasticizer.

Ethylene glycols are roughly classified into three types according to the molecular weight. The first group includes ethylene glycol, which is a monomer; the second group includes diethylene glycol, which is a dimer, and triethylene glycol, which is a trimer; and the third group includes polyethylene glycol, which is a tetramer or higher one. Polyethylene glycol is roughly classified into liquid polyethylene glycol having a molecular weight in the range of 200 to 700, and solid polyethylene glycol having a molecular weight of 1000 or greater, and those are commercially available under names followed by the average molecular weight in many cases.

The lower molecular weight of the plasticizer is, the effect of the plasticizer to soften a resin is enhanced. In consideration of this, compounds which may be particularly preferably used as the plasticizer are ethylene glycol which belongs to the first group, diethylene glycol and triethylene glycol which belong to the second group, and tetraethylene glycol (tetramer) which belongs to the third group. Among them, diethylene glycol, triethylene glycol and tetraethylene glycol can be more preferably used as the plasticizer from the viewpoints of low toxicity, absence of extraction from the resin composition, and excellent handling property thereof. Mixtures of two or more of the plasticizers can be also preferably used.

The plasticizer may be added in a proportion of 10% by mass or less with respect to the total mass of the solid content of the resin composition.

Additives for Enhancing Engraving Sensitivity

### (Nitrocellulose)

It is more preferable that nitrocellulose as an additive for improving the engraving sensitivity is added to the resin composition of the invention.

Nitrocellulose, that is a self-reactive compound, generates heat at the time of laser engraving to assist thermal decomposition of the co-existing hydrophilic polymer. The engraving sensitivity is assumed to be enhanced as a result thereof.

Any nitrocellulose can be used in the invention as long as it can be thermally decomposed, and can be any one of RS (regular soluble) nitrocellulose, SS (spirit soluble) nitrocellulose and AS (alcohol soluble) nitrocellulose. The content of nitrogen in the nitrocellulose is usually about 10% by mass to 14% by mass, preferably 11% by mass to 12.5% by mass, and more preferably about 11.5% by mass to 12.2% by mass. The degree of polymerization of the nitrocellulose may also be selected from a wide range of about 10 to 1500. The polymerization degree of the nitrocellulose is typically 10 to 900, and preferably about 15 to about 150. Preferable examples of the nitrocellulose include those having a solution viscosity of 20 seconds to 1/10 seconds, more preferably about 10 seconds to ⅛ seconds, measured according to the method of viscosity indication provided by Hercules Powder Company, that is also known as JIS K6703 “Nitrocelluloses for Industrial Use”. The nitrocellulose which can be used in the invention typically has a solution viscosity of 5 seconds to ⅛ seconds, which is preferably about 1 second to ⅛ seconds.

The RS nitrocellulose (for example, a nitrocellulose having a nitrogen content of about 11.7% to 12.2%), which is soluble in a ester such as ethyl acetate, a ketone such as methyl ethyl ketone or methyl isobutyl ketone, or an ether such as cellosolve, can be used as a nitrocellulose which can be contained in the resin composition.

The nitrocellulose may be used singly or in combination of two or more thereof as necessary. The content of nitrocellulose may be selected as long as decrease in the engraving sensitivity of the resin composition for laser engraving can be avoided, and the content is typically 5 parts by mass to 300 parts by mass, preferably 20 parts by mass to 250 parts by mass, more preferably 50 parts by mass to 200 parts by mass, and particularly preferably 40 parts by mass to 200 parts by mass, with respect to 100 parts by mass of the binder polymer and the polymerizable compound.

(Highly Thermally Conductive Substance)

In view of improving the engraving sensitivity of the resin composition of the invention, a highly thermally conductive substance can be added to the resin composition of the invention as an additive for assisting heat transfer in the resin composition.

Examples of the highly thermally conductive substance include an inorganic compound such as a metal particle and an organic compound such as an electrically conductive polymer.

Preferable examples of the metal particle include gold microparticles, silver microparticles and copper microparticles, each having a particle size in the order of micrometers to a few nanometers.

Preferable examples of the electrically conductive polymers include polyaniline, polythiophene, polyisothianaphthene, polypyrrole, polyethylene dioxythiophene, polyacetylene and modified compounds thereof. From the viewpoint of being highly sensitive, polyaniline, polythiophene, polyethylene dioxythiophene and modified compounds thereof are further preferable, and polyaniline is particularly preferable. While the polyaniline can be either in an emeraldine base form or in an emeraldine salt form when added to the resin composition, it can be preferably in an emeraldine salt form in view of higher heat transfer efficiency.

Specific examples of the metal particle and the electrically conductive polymer include commercially available products supplied by Sigma Aldrich Corp., Wako Pure Chemical Industries, Ltd., Tokyo Chemical Industry Co., Ltd., Mitsubishi Rayon Co., Ltd., Panipol Oy and the like. Specific examples which are particularly preferable in view of improving the heat transfer efficiency include AQUAPASS-01x (trade name, manufactured by Mitsubishi Rayon Co., Ltd.), and PANIPOL W and PANIPOL F (both trade names, manufactured by Panipol Oy).

It is preferable that the electrically conductive polymer is added to the resin composition in a form of an aqueous dispersion or an aqueous solution. As described above, the solvent used in preparing the resin composition is water or an alcoholic solvent in the case where an alcoholphilic polymer, which are preferable embodiments of the binder polymer in the invention, are used. Accordingly, when the electrically conductive polymer is added to the resin composition in a form of an aqueous dispersion or an aqueous solution, miscibility of the electrically conductive polymer with a hydrophilic or an alcoholphilic polymer may become good, which may further result in increasing in the strength of a molded article such as a relief layer and the like formed by the resin composition and also in increasing the engraving sensitivity of the resin composition due to an improvement in its heat transfer efficiency.

Co-Sensitizer

The sensitivity required for photo-curing of the resin composition may be further enhanced by using a co-sensitizer. While the operating mechanism is not clear, it is thought to be largely based on the following chemical process. Namely, it is presumed that various intermediate active species (radicals and cations) generated in the course of a photoreaction initiated by a polymerization initiator and an addition polymerization reaction subsequent thereto, react with the co-sensitizer to generate new active radicals. These intermediate active species may be roughly classified into (a) compounds which are reduced and can generate active radicals; (b) compounds which are oxidized and can generate active radicals; and (c) compounds which react with less active radicals, and are converted to more active radicals or act as a chain transfer agent. However, in many cases, there is no general theory applicable on which individual compound belongs to which class.

Examples of the co-sensitizer which may be applied in the invention include the following compounds.

(a) Compounds which Generate Active Radicals Upon being Reduced

Compounds having a carbon-halogen bond are classified in this group. It is presumed that an active radical is generated when the carbon-halogen bond is reductively cleaved. Specific preferable examples of the compound include trihalomethyl-s-triazines and trihalomethyloxadiazoles.

Compounds having a nitrogen-nitrogen bond are also classified in this group. It is presumed that an active radical is generated when the nitrogen-nitrogen bond is reductively cleaved. Specific preferable examples of the compound include hexaarylbiimidazoles.

Compounds having an oxygen-oxygen bond are also classified in this group. It is presumed that an active radical is generated when the oxygen-oxygen bond is reductively cleaved. Specific preferable examples of the compound include organic peroxides.

Onium compounds are also classified in this group. It is presumed that an active radical is generated when a carbon-heteroatom bond or an oxygen-nitrogen bond in an onium compound is reductively cleaved. Specific preferable examples of the compound include diaryliodonium salts, triarylsulfonium salts, N-alkoxypyridinium salts (azinium) salts, and the like.

Ferrocenes and iron arene complexes are also classified in this group. It is presumed that an active radical is reductively generated therefrom.

(b) Compounds which Generate Active Radicals Upon being Oxidized

Alkylate complexes can be classified in this group. It is presumed that an active radical is generated when a carbon-heteroatom bond therein is oxidatively cleaved. Specific preferable examples thereof include triarylalkylborates.

Alkylamine compounds can be also classified in this group. It is presumed that an active radical is generated when a C—X bond on a carbon atom which is adjacent to a nitrogen atom therein is cleaved through oxidation. Preferable examples of the X include a hydrogen atom, a carboxyl group, a trimethylsilyl group, a benzyl group and the like. Specific preferable examples of the alkylamine compound include ethanolamines, N-phenylglycine, and N-trimethylsilylmethylanilines.

Sulfur-containing or tin-containing compounds, which are obtained by substituting the nitrogen atom of the above-mentioned alkylamine compounds by a sulfur atom or a tin atom, can be also classified in this group and may generate an active radical in a similar manner as the alkylamine compounds. Compounds having an S—S bond are also known to have sensitivity enhancing property by the S—S bond cleavage.

α-substituted methylcarbonyl compounds, which may generate an active radical by the cleavage of a bond between a carbonyl moiety and an α-carbon atom through oxidation, can be also classified in this group. Compounds obtained by converting the carbonyl moiety in the α-substituted methylcarbonyl compounds into an oxime ether also show an effect which is similar to that of the α-substituted methylcarbonyl compounds. Specific examples of the compounds include 2-alkyl-1-[4-(alkylthio)phenyl]-2-morpholinopronone-1's and oxime ethers obtained by reacting a 2-alkyl-1-[4-(alkylthio)phenyl]-2-morpholinopronone-1 with a hydroxylamine and then etherifying the N—OH moiety in the resultant.

Sulfinic acid salts can be also classified in this group. An active radical may be reductively generated therefrom. Specific examples thereof include sodium arylsulfinate.

(c) Compounds which Convert Less Active Radicals to More Active Radicals by Reacting Therewith, and Compounds which Act as a Chain Transfer Agent

Compounds having SH, PH, SiH or GeH within the molecule can be classified in this group. These compounds may generate a radical by donating hydrogen to a less active radical species, or may generate a radical by being oxidized and then deprotonated. Specific examples thereof include 2-mercaptobenzothiazoles, 2-mercaptobenzoxazoles, 2-mercaptobenzimidazoles, and the like.

More specific examples of these co-sensitizers are described in, for example, JP-A No. 9-236913, as additives for enhancing the sensitivity, and those may also be applied in the invention. Some examples thereof will be shown below, while the invention is not limited thereto. In the following formulae, “-TMS” represents a trimethylsilyl group.

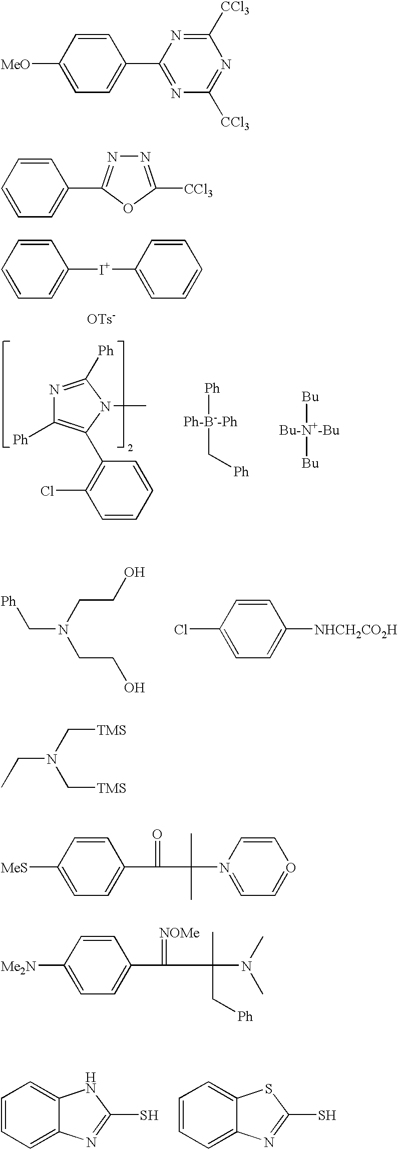

As is similar to the photo-thermal conversion agent, various chemical modifications for improving the properties of the resin composition may be carried out to the co-sensitizer. Examples of a method for the chemical modification include: bonding with the photo-thermal conversion agent, with the polymerizable compound or with some other part; introduction of a hydrophilic site; enhancement of compatibility; introduction of a substituent for suppressing crystal precipitation; introduction of a substituent for enhancing adhesiveness; and conversion into a polymer.

The co-sensitizer may be used singly, or in combination of two or more species thereof.

The content of the co-sensitizer in the resin composition of the invention is preferably 0.05 parts by mass to 100 parts by mass, more preferably 1 parts by mass to 80 parts by mass, and even more preferably 3 parts by mass to 50 parts by mass, with respect to 100 parts by mass of the polymerizable compound.

Polymerization Inhibitor

A small amount of thermal polymerization inhibitor can be preferably added to the resin composition of the invention in view of inhibiting unnecessary thermal polymerization of the polymerizable compound during the production or storage of the resin composition. Suitable examples of the thermal polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), N-nitrosophenylhydroxylamine cerium (I) salt, and the like.

Q-1301 (trade name, manufactured by Wako Pure Chemical Industries, Ltd., a 10% tricresyl phosphate solution) can be preferably used as the polymerization inhibitor from the viewpoint of excellent stability in storage of the resin composition of the invention. When Q-1301 is used in combination with the polymerizable compound, the storage stability of the resin composition of the invention can be significantly excellent, and good laser engraving sensitivity may be obtained. The addition amount of the thermal polymerization inhibitor is preferably 0.01% by mass to 5% by mass with respect to the total mass of the resin composition for laser engraving.

Also, if necessary, in order to prevent the inhibition of polymerization caused by oxygen, a higher fatty acid compound such as behenic acid or behenic acid amide may be added to the resin composition and can be localized at the surface of the layer during the course of drying of the layer performed after the resin composition is applied over (on or above) a support or the like. The addition amount of the higher fatty acid compound can be preferably 0.5% by mass to 10% by mass with respect to the total mass of the resin composition of the invention.

Colorant

A colorant such as a dye or a pigment may also be added to the resin composition of the invention for the purpose of coloring the resin composition.

The addition of the dye or the pigment may enhance properties of the resin composition such as the visibility of the image part, suitability for image density measuring device and the like. A pigment is particularly preferably used as the colorant in the invention. Specific examples of the colorant include pigments such as phthalocyanine pigments, azo pigments, carbon black or titanium oxide; and dyes such as Ethyl Violet, Crystal Violet, azo dyes, anthraquinone dyes or cyanine dyes.

The amount of addition of the colorant is preferably about 0.5% by mass to 5% by mass with respect to the total mass of the resin composition of the invention.

Other Additives

In order to improve the properties of cured products formed from the resin composition of the invention, known additives such as a filler may also be added.

Examples of the filler include carbon black, carbon nanotubes, fullerene, graphite, silica, alumina, aluminum, calcium carbonate and the like, and these fillers can be used individually or as mixtures of two or more thereof.

2. Relief Printing Plate Precursor for Laser Engraving

The relief printing plate precursor for laser engraving of the invention has a relief forming layer formed by thermally crosslinking the resin composition of the invention described above. This relief forming layer is preferably provided on a support. Hereinafter, the relief printing plate precursor for laser engraving of the invention may be simply referred to as a “relief printing plate precursor” in the following explanation.

Since the relief forming layer in the relief printing plate precursor of the invention has high engraving sensitivity when subjected to laser engraving as described above, laser engraving may be performed at high speed, and thus the engraving time may be shortened.

The relief printing plate precursor of the invention offers an excellent effect that it is easy to remove the engraving residue from the plate surface after plate making.

Furthermore, since the relief forming layer according to the invention is a hard relief forming layer which has been subjected to a heat-induced crosslinking treatment, sharp-shaped (well-defined) concavity and convexity may be formed by engraving.

The relief printing plate precursor of the invention having such characteristics is not particularly limited, and may be widely applied to the applications of a relief printing plate precursor provided with laser engraving. For example, as will be described later, the relief printing plate precursor of the invention may be applied to a relief printing plate precursor intended for the formation of a convex-shaped relief by laser engraving, as well as to another type of material for forming concavity and convexity or an opening at the surface, for example, an intaglio plate, a porous plate, a stamp or the like, as various printing plate precursors on which images are formed (relief forming) by laser engraving.

According to the invention, a previously thermally crosslinked layer having a flat surface as an image forming layer to be subjected to laser engraving, is called a relief forming layer, and a layer obtained by laser engraving this relief forming layer to form concavity and convexity on the surface is called a relief layer.

Hereinafter, the constituent elements of the relief printing plate precursor of the invention will be described.

The relief printing plate precursor for laser engraving may further have an adhesive layer between a support and a relief forming layer, and a slip coating layer and a protective film on the relief forming layer, as necessary.

Relief Forming Layer

The relief forming layer is a layer formed by thermally crosslinking the resin composition of the invention.

According to an embodiment of producing a relief printing plate from the relief printing plate precursor of the invention, a relief printing plate precursor having a relief forming layer formed by thermally crosslinking the resin composition of the invention, is subjected to laser engraving to thereby form a relief layer, and thus a relief printing plate is produced. Since the relief forming layer of the invention is thermally crosslinked, it may enable to suppress wearing of the relief layer subjected to printing and provide a relief printing plate having a sharp (well-defined) relief layer by laser engraving.

The relief forming layer may be formed by forming a sheet shape or sleeve-shaped molded body using a coating liquid for relief forming layer, and then thermally crosslinking the molded body.

The total content of the binder polymer in an uncrosslinked relief forming layer is preferably from 30 to 80% by mass, and more preferably from 40 to 70% by mass, with respect to the total mass of the solid content in the composition constituting the relief forming layer. When the total content of the binder polymer is in the aforementioned range, the printing plate precursor can be prevented from causing a cold flow, and effects of other components for improving other properties can be sufficiently obtained, and a sufficient print durability as a printing plate may be provided to the relief printing plate resulting therefrom.

The content of the polymerization initiator in an uncrosslinked relief forming layer is preferably from 0.01 to 10% by mass, and more preferably from 0.1 to 3% by mass, with respect to the total mass of the solid content in the relief forming layer. When the content of the thermopolymerization initiator is set to 0.01% by mass or more, thermal crosslinking is rapidly carried out upon forming a relief forming layer. When the content is set to 10% by mass or less, there can be no occurrence of the lack of other components, and a sufficient print durability as a printing plate may be provided to the relief printing plate resulting therefrom.

The content of the polymerizable compound in an uncrosslinked relief forming layer is preferably from 10% by mass to 60% by mass, and more preferably from 15% by mass to 40% by mass, with respect to the total mass of the solid content of the relief forming layer. When the content of the polymerizable compound is set to 10% by mass or more, the effect of the addition of the polymerization initiator can be sufficiently obtained to provide a sufficient print durability as a printing plate to the relief printing plate resulting therefrom. When the content of the polymerizable compound is set to 60% by mass or less, a sufficient strength as a printing plate may be provided to the relief printing plate resulting therefrom.

Explanation is hereinafter given with respect to an embodiment in which the relief forming layer is formed into a sheet shape.

Support

A support which may be used in the relief printing plate precursor for laser engraving will be described.

The material used in the support for the relief printing plate precursor for laser engraving is not particularly limited, but a material having high dimensional stability is preferably used. Examples thereof include metals such as steel, stainless steel and aluminum, plastic resins such as polyester (for example, PET, PBT, or PAN) and polyvinyl chloride, synthetic rubbers such as styrene-butadiene rubber, and plastic resins (epoxy resin, phenolic resin, and the like) reinforced with glass fiber. Among them, a PET (polyethylene terephthalate) film or a steel substrate is preferably used as the support.

The shape of the support is determined by whether the relief forming layer is in a sheet shape or in a sleeve shape. A preferable support that may be used in the case of forming the relief forming layer in a sleeve shape will be described below in detail.

Adhesive Layer

An adhesive layer may be provided between the relief forming layer and the support for the purpose of reinforcing the adhesive strength between the two layers.

Any material, which may enhance the adhesive force after the relief forming layer is formed by thermal crosslinking, can be employed. Here, the adhesive strength means both the adhesive strength between the support and the adhesive layer, and the adhesive strength between the adhesive layer and the relief forming layer.

The adhesive force between the support/the adhesive layer is such that, upon peeling of the adhesive layer and the relief forming layer from a laminate consisting of the support/the adhesive layer/the relief forming layer at the rate of 400 mm/min, the peeling force per 1 cm width of a sample is preferably 1.0 N/cm or more, or unpeelable, more preferably 3.0 N/cm or more, or unpeelable.

The adhesive force of the adhesive layer/the relief forming layer is such that, upon peeling of the adhesive layer from the adhesive layer/the relief forming layer at the rate of 400 mm/min, the peeling force per 1 cm width of a sample is preferably 1.0 N/cm or more, or unpeelable, more preferably 3.0 N/cm or more, or unpeelable.

As a material which may be used in the adhesive layer (adhesive), for example, a material described in 1. Skeist, “Handbook of Adhesives”, second edition (1977) may be used.

Protective Film and Slip Coat Layer

The relief forming layer becomes the part at which a relief is formed after the laser engraving. The surface of the convex portion of the relief may generally function as an ink deposition portion. There is almost no concern for generation of damages or dents on the surface of the relief forming layer which might affect printing when the relief forming layer is cured by crosslinking, since the thus-crosslinked relief forming layer has strength and hardness. However, the crosslink-curable relief forming layer which is not subjected to the crosslinking tend to have soft surfaces and are concerned for generation of damages or dents on the surface thereof when they are handled. From the viewpoint of prevention of the damages or dents, a protective film may be provided over (on or above) the relief forming layer.

If the protective film is too thin, the effect of preventing damages and depressions may not be obtained, and if the protective film is too thick, inconvenience may arise upon the handling thereof and production costs therefor may become higher. In consideration of these, the thickness of the protective film is preferably 25 μm to 500 μm, and more preferably 50 μm to 200 μm.

In the protecting film, a material known as the protecting film of the printing plate, for example, a polyester film such as PET (polyethylene terephthalate), and a polyolefin film such as PE (polyethylene) and PP (polypropylene) may be used. A surface of the film may be plain, or may be matted.

When the protecting film is provided on the relief forming layer, the protecting film should be peelable.

When the protecting film is unpeelable, or when the protecting film is hardly adhered on the relief forming layer, a slip coating layer may be provided between both layers.

A material used in the slip coating layer is preferably a material containing, as a main component, a resin which is soluble or dispersible in water, and has little adhering property, such as polyvinyl alcohol, polyvinyl acetate, partially saponified polyvinyl alcohol, hydroxyalkylcellulose, alkylcellulose, and polyamide resin. Among them, from a viewpoint of adhering property, partially saponified polyvinyl alcohol having a saponification degree of 60 mol % to 99 mol %, and hydroxyalkylcellulose and alkylcellulose having an alkyl group having 1 to 5 carbon atoms are particularly preferably used.

When the protecting film is peeled from the relief forming layer (and the slip coating layer)/the protecting film at the rate of 200 mm/min, the peeling force per 1 cm is preferably 5 mN/cm to 200 mN/cm, further preferably 10 mN/cm to 150 mN/cm. When the peeling force is 5 mN/cm or more, working may be performed without peeling of the protecting film during working and, when the peeling force is 200 mN/cm or less, the peeling film may be peeled naturally.

Method for Producing Relief Printing Plate Precursor for Laser Engraving

Hereinafter, the method of producing the relief printing plate precursor for laser engraving will be described.

There is no particular limitation to the preparation of a relief forming layer of a relief printing plate precursor for laser engraving according to the invention, but the formation described below is preferably used.

A coating liquid for a relief forming layer is prepared first, and then an uncrosslinked relief forming layer is formed by using, for example, a method of removing a solvent from the obtained coating liquid for the relief forming layer, and then melt extruding the coating liquid on a support; or a method of flow casting the obtained coating liquid for relief forming layer on a support, and drying this in an oven to remove the solvent from the coating liquid. Subsequently, the obtained uncrosslinked relief forming layer is subjected to a thermal crosslinking treatment, thereby forming a relief forming layer.

Thereafter, if necessary, the protecting film may be laminated on the relief forming layer. Lamination may be performed by pressing the protecting film and the relief forming layer with a heated calendar roll, or adhering the protecting film to the relief forming layer having a surface impregnated with a small amount of a solvent.

When the protecting film is used, a process of first laminating the relief forming layer on the protecting film and, then, laminating the support may be adopted.

When the adhesive layer is provided, the support coated with an adhesive layer may be used. When the slip coating layer is provided, the protecting film coated with a slip coating layer may be used.

The coating liquid composition for the relief forming layer may be produced, for example, by dissolving components of (A) to (D) as an the essential component and, as an optional component, a photothermal conversion agent and a plasticizer in a suitable solvent and, then, dissolving a polymerizable compound and a polymerization initiator.

Since most of a solvent component is necessary to be removed at a stage of producing the relief printing plate precursor, it is preferable that, as a solvent, an easily vaporized low-molecular alcohol (e.g. methanol) is used, and the total addition amount of the solvent is suppressed as less as possible. When a temperature of the system is high, an addition amount of the solvent may be suppressed, but when a temperature is too high, since a polymerizable compound is easily polymerization-reacted, a temperature for preparing a coating liquid composition after addition of the polymerizable compound and/or the polymerization initiator is preferably 30° C. to 80° C.

A thickness of the relief forming layer of the relief printing plate precursor for laser engraving is preferably 0.05 mm to 10 mm, more preferably 0.05 mm to 7 mm and, particularly preferably, 0.05 mm to 0.3 mm.

Any known methods for molding a resin may be employed when the relief forming layer is formed in a sleeve shape.

Examples thereof include: a casting method; a method including extruding a resin from a nozzle or a dice by a machine such as a pump or an extruder and adjusting a thickness of the resultant by use of a blade or by a calendar processing with rolls. During the molding, heat with a temperature, by which characteristics of a resin composition which configures the relief forming layer are not deteriorated, can be applied to the molding system. A rolling treatment, an abrading treatment, and/or the like may be further performed if necessary.

When the relief forming layer is made into a sleeve shape, the relief forming layer may be formed by being molded into a cylindrical shape at the initial stage of the molding, or may be formed by being molded into a sheet shape at first and then made into a cylindrical shape by being fixed on a cylindrical support or a plate cylinder. There is no particular limitation for the fixing of the sheet-shaped support to the cylindrical support, and examples thereof include: fixing the sheet-shaped support to the cylindrical support by using an adhesive tape having an adhesive layer, a tackifying layer, or the like provided on each of both sides; and fixing the sheet-shaped support to the cylindrical support via a layer containing an adhesive agent.

Examples of the adhesive tape include: a tape having a tackifying agent layer or an adhesive agent layer formed of an acrylic resin, a methacrylic resin, a styrene thermoplastic elastomer or the like formed on both sides of a film base material such as a polyester film or a polyolefin film; and a tape which has a base material formed of a foamed body of a polyolefin resin such as polyethylene or a polyurethane resin and provided with a tackifying agent layer or an adhesive agent layer as described above on both of sides thereof and has a cushioning property. A commercially available tape with adhesive on both sides or a cushion tape having tackifying agent layers on both sides may be appropriately used as well.

The adhesive agent layer used in the case that a cylindrical support and the relief forming layer are fixed via the adhesive agent layer can be formed using any known adhesive agents. Examples of an adhesive agent which can be used for the fixing of the relief forming layer to the cylindrical support include a rubber adhesive agent such as a styrene butadiene rubber (SBR), a chloroprene rubber or a nitrile rubber, and an adhesive agent which is hardened by moisture in air such as a silicone resin or a polyurethane resin having silyl group.

When the relief forming layer is made into a cylindrical shape, the relief forming layer may be formed by being molded into a cylindrical shape by a known method at first and then fixed on a cylindrical support, or may be formed by directly molded into a cylindrical shape by extrusion molding or the like so as to be a sleeve shape. The former method is preferably used in view of the productivity. When the relief forming layer is made into a sleeve shape, the thus-formed sleeve-shaped relief forming layer may still be subjected to crosslinking and hardened after being fixed onto a cylindrical support if necessary, and a rolling treatment, an abrading treatment or the like can be further carried out if desired.

Examples of the cylindrical support used in making the relief forming layer into a sleeve shape include: a metal sleeve formed of a metal such as nickel, stainless steel, iron or aluminum; a plastic sleeve formed by molding a resin; a sleeve formed of a fiber reinforced plastics (FRP sleeve) having a glass fiber, a carbon fiber, an aramid fiber or the like as a reinforcing fiber fiber-reinforced plastic; and a sleeve formed of a polymer film and having a shape maintained by compressed air.

The thickness of the cylindrical support may be arbitrarily selected depending upon the object, and the thickness can be typically sufficient as long as it is 0.1 mm or more and as long as the cylindrical support is not destructed by a pressure applied thereto when it is subjected to printing. In the case that the cylindrical support is a metal sleeve or a hard plastic sleeve, those having a thickness of 5 mm or more may be used as well, and it is also possible to use a cylindrical support having a solid body penetrated by a rotation axis (namely, a cylindrical support which is fixed to a rotating axis).

In view of an effective fixation of a shrinkable relief forming layer to the cylindrical support, the cylindrical support preferably has such characteristics that an inner diameter of the cylindrical support can expand by a air compressed to have pressure of about 6 bars and that it returns to have its initial inner diameter after the compressed air is released. A support having such a structure (namely, a structure with a diameter which can be easily adjusted by compressed air or the like) is preferable since a stress can be applied to the relief forming layer having a sleeve shape from inside thereof, a tightly rolling characteristic of the relief forming layer can work and, the relief layer can be stably fixed on a cylindrical plate or a plate cylinder even when a stress is applied thereto when it is subjected to printing.

After an uncrosslinked relief forming layer is formed, the uncrosslinked relief forming layer is subjected to thermal crosslinking, whereby a relief forming layer is formed. That is, when an uncrosslinked relief forming layer (resin composition) containing the respective components (A) to (D), and preferably further containing a photothermal conversion agent or the like, is subjected to thermal crosslinking treatment, the polymerizable compound is allowed to react under the action of a thermopolymerization initiator to form crosslinking, whereby a relief forming layer is formed. The thermopolymerization initiator is preferably a radical generating agent.

When the relief forming layer according to the invention is thermally crosslinked, the relief forming layer becomes a layer which is uniformly cured (crosslinked) from the surface to the interior thereof. Furthermore, when the relief forming layer is thermally crosslinked, there are advantages such as that, firstly, sharp relief is formed after laser engraving; and secondly, adhesion of engraving residue generated by laser engraving is suppressed. When an uncrosslinked relief forming layer is subjected to laser engraving, portions that are not originally intended for crosslinking are prone to melt and deform due to residual heat spread to the surroundings of laser-irradiated parts, and a sharp relief layer may not be obtained. Also, in view of the general properties of materials, a material having a lower molecular weight tends to be in a liquid state rather than a solid state, which implies that the material tends to have stronger adhesiveness. Engraving residue generated by engraving of the relief forming layer tends to have stronger adhesiveness when more materials having lower molecular weight are used. Since a low molecular weight polymerizable compound increases in molecular weight when crosslinked, the generated engraving residue tends to have reduced adhesiveness.

Heating techniques include a method of heating the printing plate precursor in a hot air oven or a far-infrared oven for a predetermined time, and a method of contacting the printing plate precursor with a heated roll for a predetermined time.

The heating temperature used in the crosslinking treatment may be arbitrarily adjusted while taking into consideration the decomposability of the polymerization initiator or the boiling point of the solvent, but the temperature is preferably 60 to 160° C., and more preferably 70 to 150° C., in view of making the film surface uniform and performing the drying process sufficiently. The heating time from the viewpoint of the thermal stability of the plate material component is preferably 10 minutes to 24 hours, more preferably 30 minutes to 15 hours, and particularly preferably 1 to 12 hours.

The heat-induced crosslinking treatment has an advantage of not requiring special, high-priced apparatuses, but since the temperature of the printing plate precursor rises high, there is a need to carefully select the raw materials to be used because, for example, a thermoplastic polymer which turns soft at high temperatures is likely to undergo deformation during heating.

3. Relief Printing Plate and Method for Production Thereof.

The method of producing a relief printing plate using the relief printing plate precursor of the invention preferably includes a process of forming a relief layer by laser engraving a relief forming layer (hereinafter, referred to as engraving process). A relief printing plate having a relief layer on a support may be produced according to such production method, using the relief printing plate precursor of the invention.

A preferable method of producing a relief printing plate according to the invention may further include, subsequently to the engraving process, the following rinsing process, drying process and post-crosslinking process as necessary.

Rinsing process: A process of rinsing the engraved surface of the relief layer after engraving, with water or a liquid containing water as a main component.

Drying process: A process of drying the engraved relief layer.

Post-crosslinking process: A process of further crosslinking the relief layer by supplying energy to the relief layer after engraving.

The Engraving Process

In the engraving process, the relief forming layer subjected to the crosslinking is engraved with laser to form a relief layer. The engraving process is preferably performed by irradiating the relief forming layer with laser light which corresponds to a desired image to be formed with employing a specific laser described below so that a relief layer to be used for printing can be formed thereby.

More specifically, a relief layer is formed in the engraving process by irradiating the relief forming layer with a laser light and corresponding to a desired image to be formed. The engraving preferably includes controlling the laser head with a computer based on the digital data of a desired image to be formed, and performing scanning irradiation over the relief forming layer. When an infrared laser is irradiated, molecules in the relief forming layer undergo molecular vibration, and thus heat is generated. When a high power laser such as a carbon dioxide laser or a YAG laser is used as the infrared laser, a large amount of heat is generated at the laser-irradiated areas, and the molecules in the photosensitive layer undergo molecular breakage or ionization, so that selective removal (that is, engraving) can be achieved. In a case that a photo-thermal conversion agent is contained in the relief forming layer, heat is generated in the irradiated portion. The heat generated by the photo-thermal conversion agent can also enhance the selective removal.

An advantage of the laser engraving is the ability to three-dimensionally control the structure of the engraved portion since the depth of engraving can be arbitrarily set thereby, For example, when areas for printing fine dots are engraved shallowly or with a shoulder, the relief may be prevented from collapsing under printing pressure. When groove areas for printing cutout characters are engraved deeply, the grooves may be hardly filled with ink, and collapse of the cutout characters may be thus suppressed.

When the engraving is performed with an infrared laser which corresponds to the maximum absorption wavelength of the photo-thermal conversion agent, a more sensitive and well-defined (sharp) relief layer can be obtained.

As an infrared laser used for laser engraving, carbon dioxide gas laser or semiconductor laser is preferable from the viewpoint of improving productivity and reducing costs, a CO₂ laser or a semiconductor laser can be preferably used, and among these, a fiber-coupled semiconductor infrared laser described below can be particularly preferably used.

Platemaking Device Equipped with Semiconductor Laser

In general, a semiconductor laser exhibits high efficiency in laser oscillation, is less expensive and can be made smaller as compared with CO₂ lasers. Moreover, due to its small size, a semiconductor laser can be easily provided in an array. Control of its beam diameter can be done by an imaging lens or a specific optical fiber. A fiber-coupled semiconductor laser can be effective for the image formation of the invention since it can efficiently output laser beam by an optical fiber installed therein. A shape of the laser beam can be controlled by processing the optical fiber. For example, a beam profile of the laser beam can be made into a top-hat shape so as to stably apply energy to a plate surface. Details of the semiconductor laser are described, for example, in “Laser Handbook”, Second Edition, edited by Laser Society and “Practical Laser Technique”, Electronic Communication Society.

In addition, the platemaking apparatus equipped with semiconductor laser with fiber which may be preferably used in the process for producing the relief printing plate using the relief printing plate precursor of the invention is described in detail in JP-A 2009-172658 which is submitted by the present applicant, and this may be used in platemaking of the relief printing plate related to the invention.

While any semiconductor laser can be used as ling as it emits light having a wavelength which is in the range of 700 nm to 1300 nm, it is preferably those emitting light having a wavelength which is in the range of 800 nm to 1200 nm, more preferably those emitting light having a wavelength which is in the range of 860 nm to 1200 nm, and further preferably those emitting light having a wavelength which is in the range of 900 nm to 1100 nm.

Since the band gap of GaAs resides at 860 nm at room temperature, semiconductor lasers having a AlGsAs active layer is generally used when light having a wavelength of 860 nm or less is employed. On the other hand, semiconductor lasers having a InGaAs active layer is generally used when light having a wavelength of 860 nm or more is employed. Employment of a wavelength which is in the range of 860 nm to 1200 nm is preferable since the semiconductor lasers having a InGaAs active layer is reliable relative to those having a AlGsAs active layer, the aluminum used therein being generally easily oxidized.

In consideration of configuration of cladding material and the like in addition to the active layer material, the more preferable embodiment of practically-usable semiconductor lasers having a InGaAs active layer include those emitting light having a wavelength which is in the range of 900 nm to 1100 nm, which would provide higher output and higher reliability. Accordingly, the low cost and high productivity can be more easily obtained by the invention when a semiconductor lasers having a InGaAs active layer and emitting light having a wavelength which is in the range of 900 nm to 1100 nm is employed.

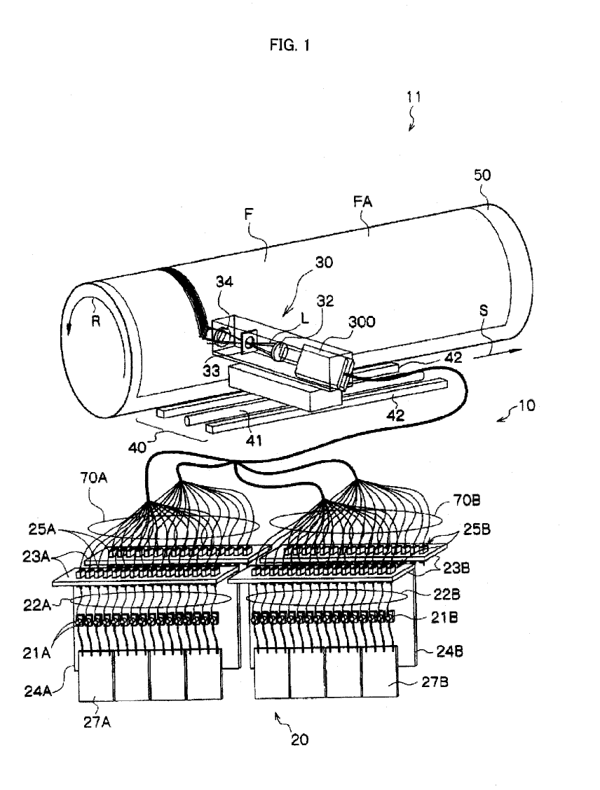

An embodiment of the plate making device equipped with a fiber-coupled semiconductor laser recording device which can be used in the method of making a printing plate of the invention will be illustrated hereinafter with respect its configuration by referring to FIG. 1.

A plate making device 11 which can be used in the method of the invention is equipped with: a fiber-coupled semiconductor laser recording device 10; and a plate making device 11 has a drum 50, which has an outer circumference surface, on which a printing plate precursor F (recording medium) of the invention can be attached. The laser recording device 10 has: a light source unit 20 which generates plural laser beams; a exposure head 30 which expose the relief printing plate precursor F to the plural laser beams generated by the light source unit 20; and a moving unit 40 of exposure head which moves the exposure head 30 in the auxiliary scanning direction.

The plate making device 11 drives the drum 50 to rotate in a main scanning direction (the direction indicated by an arrow R) and, at the same time, have an exposure head 30 to scan the drum 50 in an auxiliary scanning direction, which is at right angle to the main scanning direction and is indicated by an arrow S, while simultaneously emitting plural laser beams corresponding to image data to be engraved (recorded) from the exposure head 30 to the relief printing plate precursor F, so that a two-dimensional image can be engraved (recorded) on the relief printing plate precursor F at high speed. In the case where a narrow region is engraved (namely, when a precise engraving is performed for forming fine lines, fine dots or the like), the relief printing plate precursor F can be engraved shallowly. In the case where a broad region is engraved, the relief printing plate precursor F can be engraved deeply.

The light source unit 20 is equipped with: semiconductor lasers 21A and 21B, each of which has a broad area semiconductor laser to which an end of each of optical fibers 22A or 22B is individually coupled; light source supports 24A and 24B, each of which has the semiconductor laser 21A or 21B aligned on the surface thereof; adaptor supports 23A and 23B, each of which is vertically attached to an end of the light source support 24A or 24B and a plural (the same numbers as in the semiconductor lasers 21A, 21B) adaptors of SC-type light connectors 25A or 25B are installed thereon; and LD (laser diode) driver supports 27A and 27B, each of which is horizontally attached to another end of the light source support 24A or 24B and is installed with a LD driver circuit (not shown in FIG. 1) which drives the semiconductor lasers 21A and 21B corresponding to the image data of the image to be engraved (recorded) on the relief printing plate precursor F.

The exposure head 30 is equipped with a fiber array unit 300 by which laser beams emitted from the plural semiconductor lasers 21A and 21B can be emitted together. Each of the laser beams emitted from the semiconductor laser 21A or 21B is conveyed to the fiber array unit 300 by one among plural optical fibers 70A and 70B, which are connected to the SC-type light connector 25A or 25B connected to the adaptor supports 23A or 23B.

As shown in FIG. 1, the exposure head 30 has a collimator lens 32, an opening material 33 and an imaging lens 34 which are aligned in this order with respect to a position in which the fiber array unit 300 is disposed. The opening material 33 is aligned such that its opening resides at the position of a far field when looked from the side of the fiber array unit 300. As a result, a similar degree of light quantity restricting effect can be provided to all laser beams emitted from terminals 71A or 71B of the optical fibers 70A or 70B at the fiber array unit 300.

Laser beam forms an image at a vicinity of the exposure side (surface) FA of the relief printing plate precursor F by an imaging unit having the collimator lens 32 and the imaging lens 34 in its configuration.

The fiber-coupled semiconductor laser can change a shape of the laser beam emitted therefrom. In view of efficient engraving and good reproducibility of fine lines, it is preferable in the invention to control a spot diameter the laser beam to be in a range of 10 μm to 80 μm on the exposed surface (surface of a relief forming layer) FA by, for example, controlling the shape of the laser beam to have the imaging position (image forming position) P be within an area of inner side with respect to the exposure surface FA (the side of forwarding direction of laser beam) or the like.

The exposure head moving unit 40 is equipped with two rails 42 and a ball screw 41 aligned in such a manner that their longitudinal direction are along the auxiliary scanning direction. A pedestal 310 equipped with the exposure head 30 can be moved in an auxiliary scanning direction with being guided by the rail 42 by operating an auxiliary scanning motor 43, which drives and rotates the ball screw 41. The drum 50 can be rotated in the direction of the arrow R when a main scanning motor (not shown) is operated, whereby the main scanning is performed.

It is also possible to control the shape of the engraved region by controlling the amount of energy applied to the surface of the relief forming layer by the laser beam without changing the shape of the laser beam from the fiber-coupled semiconductor laser. Specific examples of the energy amount controlling-method include a method in which output power of the semiconductor laser is changed and a method in which a time length employed for the laser irradiation is changed.

If engraving remnants remain and adhere to the engraved surface, the rinsing process of rinsing, in which the engraved surface is rinsed with water or with a liquid containing water as a main component to wash away the engraving remnants, may be further performed. Examples of the method of the rinsing include a method of spraying water at high pressure, or a method of brush rubbing the engraved surface, mainly in the presence of water, using a batch type- or conveyor type-brush washout machine known as a developing machine for photosensitive resin letterpress plates, and the like. If the viscous liquid of the engraving remnants cannot be removed by simply washing with the water or the liquid, a rinsing solution containing soap may be used.

When the rinsing process is performed to the engraved surface, it is preferable to further perform the drying process in which the relief layer which has been engraved is dried to volatilize the rinsing solution.

Further, the post-crosslinking process in which a crosslinked structure is formed in the relief layer can be carried out if necessity. By carrying out the post-crosslinking process, the relief formed by engraving may be further strengthened.

The relief printing plate according to the invention, that has a relief layer over a support, can be thus obtained.

A thickness of the relief layer of the relief printing plate is preferably in a range of 0.05 mm to 10 mm, more preferably in a range of 0.05 mm to 7 mm, and particularly preferably in a range of 0.05 mm to 3 mm in view of satisfying various applicability to flexographic printing such as wearing resistance or ink transfer property.

The Shore A hardness of the relief forming layer subjected to the crosslinking is preferably from 50° to 90°.

When the Shore A hardness of the relief layer is 50° or more, the fine dots formed by engraving may not be fall and break even under the high printing pressure of a letterpress printing machine, and proper printing may be achieved. When the Shore A hardness of the relief layer is 90° or less, print scratches at solid parts may be prevented even in flexographic printing with a kiss-touch printing pressure.

The “Shore A hardness” herein means a value measured by a durometer (spring type rubber hardness meter), which impinges a presser (referred to as a penetration needle or an indenter) to a surface of an object to cause deformation of the surface, and measures the amount of the deformation (penetration depth) of the surface and expresses the result in a numerical value.

The relief printing plate produced by the method of the invention allows printing with a letterpress printing machine using any of an aqueous ink, oily ink or UV ink, and also allows printing with a flexographic printing machine using UV ink.

The relief printing plate obtained from the relief printing plate precursor of the invention can be excellent in terms of both suitability for an aqueous ink and suitability for a UV ink. Accordingly, printing can be performed by employing the relief printing plate without concern for deterioration of the strength or printing durability of the relief forming layer due to the effects of such inks.

As discussed above, according to the invention, there may be provided a resin composition for laser engraving which has high engraving sensitivity when subjected to laser engraving, has excellent storage stability, and allows easy removal of engraving residue generated by engraving. According to the invention, there may also be provided a relief printing plate precursor for laser engraving which has high engraving sensitivity, enables direct platemaking by laser engraving, and allows easy removal of engraving residue from the plate surface after plate making. According to the invention, a method of producing a relief printing plate using the relief printing plate precursor for laser engraving, and a relief printing plate obtained by the production method, may also be provided.

### EXAMPLES

Hereinafter, the present invention will be described in more detail by way of Examples, but the invention is not intended to be limited to these Examples.

The weight average molecular weight (Mw) of a polymer in the Examples indicates, unless stated otherwise, a value measured by a gel permeation chromatography (GPC) method.

### Example 1

### 1. Preparation of Crosslinkable Resin Composition for Laser Engraving

A three-necked flask equipped with a stirring blade and a cooling tube was charged with 5 parts by mass of “SYLYSIA 310P (trade name, manufactured by Fuji Silysia Chemical, Ltd.) as the inorganic porous material (A), 50 parts by mass of “DENKA BUTYRAL #3000-2” (trade name, manufactured by Denki Kagaku Kogyo Co., Ltd.; polyvinyl butyral derivative, Mw=19,000) as the binder polymer (B), 1 part by mass of KETJENBLACK EC600JD (trade name, manufactured by Lion Corp.; carbon black) as the photothermal conversion agent (E), and 47 parts by mass of ethanol as a solvent, and the mixture was heated at 70° C. for 120 minutes while the mixture was stirred, to thereby dissolve the polymer. Subsequently, the solution was cooled to 40° C., and 15 parts by mass of an ethylenically unsaturated monomer M-1 (having a structure shown below) as the polymerizable compound (D) (polyfunctional substance), 33 parts by mass of BLEMMER LMA (trade name, manufactured by NOF Corporation) as the polymerizable compound (D) (monofunctional substance), and 1 part by mass of PERBUTYL Z (trade name, manufactured by NOF Corp.) as the thermopolymerization initiator (C) were added to the solution. The mixture was stirred for 30 minutes, and thus a coating liquid for crosslinkable relief forming layer 1 (resin composition for laser engraving) having fluidity was obtained.

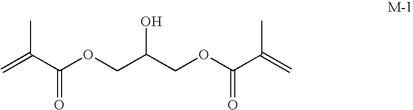

### 2. Production of Relief Printing Plate Precursor for Laser Engraving

A spacer having a predetermined thickness was provided on a PET substrate to form a frame, and the coating solution for the crosslinkable relief forming layer 1 obtained as described was quietly cast into the frame to such an extent as not flowing out of the spacer and dried in an oven at 70° C. for 3 hrs to dispose a relief forming layer of about 1 mm thickness.

Subsequently, the uncrosslinked relief forming layer was subjected to a thermal crosslinking treatment by heating at 120° C. for 2.5 hours, and thus a thermally crosslinked relief forming layer was formed.

Furthermore, a protective film (a PET sheet processed by a sandblasting method to impart a surface roughness Ra=0.3 μm) was provided on the surface of the relief forming layer, and thus a relief printing plate precursor for laser engraving 1 was obtained.

### 3. Production of Relief Printing Plate

The thermally crosslinked relief forming layer was subjected to engraving by the following two types of laser lights, and thereby a relief printing plate 1 was produced.

As for the first laser, engraving by laser irradiation was performed using a high definition CO₂ laser marker ML-9100 series (manufactured by Keyence Corp.) as a carbon dioxide laser engraving machine. First, the protective film was peeled off from the relief printing plate precursor for laser engraving, and then raster engraving was performed on a solid image part which measured 1 cm on each of the four edges, with the carbon dioxide laser engraving machine under the conditions of an output power of 12 W, a head speed of 200 mm/second, and a pitch setup of 2400 DPI. (The results obtained by an evaluation using this first laser will be indicated as “CO₂ laser” in the table shown below.)

As for the second laser, the above-described laser recording device shown in FIG. 1 was used, which was equipped with a fibered semiconductor laser (FC-LD), SDL-6390 (trade name, manufactured by JDSU Corp.; wavelength: 915 nm), having a maximum output power of 8.0 W, as the semiconductor laser engraving machine. Raster engraving was performed on a solid image part which measured 1 cm on each of the four edges, with the semiconductor laser engraving machine under the conditions of a laser output power of 7.5 W, a head speed of 409 mm/second, and a pitch setup of 2400 DPI. (The results obtained by an evaluation using this second laser will be indicated as “FC-LD” in the table shown below.)

As such, relief layers were formed using the two types of lasers, and thus a relief printing plate 1 was obtained for each relief layer.

The thickness of the relief layer of the relief printing plate 1 was approximately 1 mm.

The Shore A hardness of the relief layer was measured by the measurement method previously described, and was found to be 75°.

### Examples 2 to 19 and Comparative Examples 1 to 2

### 1. Preparation of Crosslinkable Resin Composition for Laser Engraving

Coating liquids for relief forming layer 2 to 19 of Examples 2 to 19, and coating liquids for relief forming layer C1 to C2 (resin composition for laser engraving) of Comparative Examples 1 and 2 were prepared in the same manner as in Example 1, except that the inorganic porous material (A), the binder polymer (B), the thermopolymerization initiator (C), the polymerizable compound (D) (polyfunctional substance), and the photothermal conversion agent (E), that had been used in Example 1 were replaced as indicated respectively in Table 1.

Details of the inorganic porous material (A), the binder polymer (B), the thermopolymerization initiator (C) and the photopolymerization initiator for comparison, the polymerizable compound (D), and the photothermal conversion agent (E), that were used in the respective Examples and Comparative Examples as indicated in Table 1 are as follows.

(A) Inorganic Porous Material

SYLYSIA 310P (trade name, manufactured by Fuji Silysia Chemical, Ltd.)

SYLYSIA 350 (trade name, manufactured by Fuji Silysia Chemical, Ltd.)

SYLOSPHERE C-1504 (trade name, manufactured by Fuji Silysia Chemical, Ltd.)

SYLYSIA 710 (trade name, manufactured by Fuji Silysia Chemical, Ltd.)

SYLYSIA 730 (trade name, manufactured by Fuji Silysia Chemical, Ltd.)

SYLYSIA 250N (trade name, manufactured by Fuji Silysia Chemical, Ltd.)

SYLOPHOBIC 702 (trade name, manufactured by Fuji Silysia Chemical, Ltd.)

SYLOMASK 52 (trade name, manufactured by Fuji Silysia Chemical, Ltd.)

SYLOMASK 55 (trade name, manufactured by Fuji Silysia Chemical, Ltd.)

•

(B) Binder Polymer

Binder 1: DENKA BUTYRAL #3000-2 (trade name, manufactured by Denki Kagaku Kogyo Co., Ltd.; polyvinyl butyral, Mw=90,000, Tg: above room temperature)

Binder 2: TORESIN F-30K (trade name, manufactured by Nagase ChemteX Corp.; methoxymethylated polyamide, Tg: above room temperature)

Binder 3: ARAKYD 9201N (trade name, manufactured by Arakawa Chemical Industries, Ltd.; modified epoxy resin, Tg: above room temperature)

Binder 4: ETHYLCELLULOSE 45 (trade name, manufactured by Wako Pure Chemical Industries, Ltd.; cellulose derivative, Tg: above room temperature)

Binder 5: 10/90 (molar ratio) Copolymer of BLEMMER PME 100/methyl methacrylate (trade name; acrylic resin having a hydrophilic group in a side chain, Mw=32,000, Tg: above room temperature)

Binder 6: Polymer obtained by capping the terminals of a 1/1 (molar ratio) polyadduct of polycarbonate diol (trade name: PCDL L4672, Mn=1990)/tolylene diisocyanate, with 2-methacryloyloxyethyl isocyanate (Mw=10,000, Tg: below room temperature)

Binder 7: UDEL P-1700 (trade name, manufactured by Amoco Polymers, Inc.; Tg: below room temperature)

Binder 8: KRATON 1107 (trade name, manufactured by Shell Chemical Co., Houston, Tex.; styrene-isoprene-styrene block copolymer, Tg: below room temperature)

Binder 9: ELASTOSIL (trade name: Type R300/30S, manufactured by Wacker Chemie AG; silicone rubber, Tg: below room temperature)

(C) Thermopolymerization Initiator, or Photopolymerization Initiator for Comparison

(Thermopolymerization Initiator)

PERBUTYL Z (trade name, manufactured by NOF Corp.; organic peroxide)

PERHEXYL E (trade name, manufactured by NOF Corp.; organic peroxide)

PERHEXYL I (trade name, manufactured by NOF Corp.; organic peroxide)

PERHEXYL HC (trade name, manufactured by NOF Corp.; organic peroxide)

V-601 (trade name, manufactured by Wako Pure Chemical Industries, Ltd.; dimethyl 2,2′-azobisisobutyrate)

(Photopolymerization Initiator)

IRGACURE 184 (trade name, manufactured by Ciba Geigy AG)

((D) Polymerizable Compound)

M-1: Ethylenic unsaturated monomer (having the above-described structure)

M-2: Ethylenic unsaturated monomer (having the following structure)

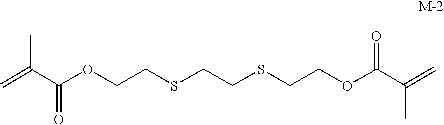

(E) Photothermal Conversion Agent

Carbon black: KETJENBLACK EC600JD (trade name, manufactured by Lion Corp.), ADS-820HO (trade name, manufactured by American Dye Source, Inc.)

### 2. Production of Relief Printing Plate Precursor for Laser Engraving

(Production of Relief Printing Plate Precursors for Laser Engraving 2 to 19)

Relief printing plate precursors for laser engraving 2 to 19 of Examples 2 to 19, each having a thermally crosslinked relief forming layer, were obtained in the same manner as in Example 1, except that the coating liquid for relief forming layer 1 used in Example 1 was changed to the coating liquids for relief forming layer 2 to 19, respectively.

Production of Relief Printing Plate Precursor for Laser Engraving C1

A relief printing plate precursor for laser engraving C1 of Comparative Example 1 was obtained by changing the coating liquid for relief forming layer 1 used in Example 1 to the coating liquid for relief forming layer C1, and forming a relief forming layer under the film forming conditions described in the Examples of WO 2004/00571 A1.

(Production of Relief Printing Plate Precursor for Laser Engraving C2)

A relief printing plate precursor for laser engraving C2 of Comparative Example 2 having a thermally crosslinked relief forming layer was obtained in the same manner as in Example 1, except that the coating liquid for relief forming layer 1 used in Example 1 was changed to the coating liquid for relief forming layer C2.

### 3. Production of Relief Printing Plate

Relief printing plates of Examples 2 to 19 and Comparative Examples 1 to 2 were obtained by engraving the relief forming layers of the relief printing plate precursors for laser engraving of Examples 2 to 19 and Comparative Examples 1 to 2 in the same manner as in Example 1 to form relief layers.

The thickness of the relief layers of these relief printing plates was approximately 1 mm.

Measurement of the Shore A hardness of the relief layers in the respective relief printing plates obtained was carried out in the same manner as in Example 1. The measured Shore A hardness values are shown in Table 1.

### 4. Evaluation

4-1. Evaluation of Storage Stability of Coating Liquid

The coating liquids for relief forming layer 1 to 19 and C1 to C2 prepared in the respective Examples and Comparative Examples (10 g each) were each placed in a 50-ml pear-shaped flask, and were left to stand in a sealed state under a white lamp at room temperature for 14 days. Subsequently, the pear-shaped flasks were inverted, and the fluidity of the coating liquids was visually inspected.

Those liquids maintaining fluidity were rated A, while those liquids lacking fluidity and being solidified (gelated) were rated B. The results are shown in Table 1.

4-2. Evaluation of Removability (Rinsing Property) of Engraving Residue

The printing plate engraved in each of the Examples and Comparative Examples was immersed in water, and the engraved portion was rubbed 10 times with a toothbrush (Clinica Toothbrush (flat) manufactured by Lion Corporation). Thereafter, it was confirmed whether or not residue remained on the surface of the relief layer under an optical microscope. Evaluation was performed such that A was given when residue was not present, B was given when residue hardly existed, C was given when residue remained slightly, and D was given when residue could not be removed.

In this evaluation, the same result was obtained regardless of whichever of the 2 lasers had been used in engraving.

The results are shown in Table 1.

4-3. Evaluation of Surface State of Relief Forming Layer

For each of the Examples and Comparative Examples, the surface of the relief printing plate (2 cm×2 cm) having a thermally crosslinked relief forming layer was observed with an optical microscope, and the number of crater-shaped concavity and convexity site was counted. Those plates having 0 to 3 sites were rated A; those plates having 4 to 10 sites were rated B; and those plates having 10 or more sites were rated C. The results are shown in Table 1.

4-5. Evaluation of Engraving Sensitivity

The “engraving depth” of the relief layers obtained by laser engraving the relief forming layers carried by the relief printing plate precursors 1 to 19 and C1 to C2, was measured as follows. Here, the “engraving depth” means the difference between the position (height) of an engraved site and the position (height) of a non-engraved site, when the cross-section of the relief layer was observed. The “engraving depth” in the present Examples was measured by observing the cross-section of a relief layer with an ultra-deep color 3D profile measuring microscope, VK9510 (trade name, manufactured by Keyence Corp.). A larger engraving depth means higher engraving sensitivity. The results are shown in Table 1 for each type of laser used in the engraving.

TABLE 1

| | Composition of coating liquid (resin composition) | | | | |
|---|---|---|---|---|---|
| | used in formation of relief forming layer | | | | |
| | | | | (D) | |
| | | | | Polymerizable | (E) |
| | | (B) | (C) | compound | Photothermal |
| | (A) Inorganic | Binder | Thermopolymerization | (polyfunctional | conversion |
| | porous material | polymer | initiator | substance) | agent |
| Example 1 | SYLYSIA 310P | Binder-1 | PERBUTYL Z | M-1 | Carbon black |
| Example 2 | SYLYSIA 310P | Binder-1 | PERBUTYL Z | M-2 | Carbon black |
| Example 3 | SYLYSIA 310P | Binder-1 | PERBUTYL Z | M-1 | ADS820HO |
| Example 4 | SYLYSIA 310P | Binder-2 | PERBUTYL Z | M-1 | Carbon black |
| Example 5 | SYLYSIA 310P | Binder-3 | PERBUTYL Z | M-1 | Carbon black |
| Example 6 | SYLYSIA 310P | Binder-4 | PERBUTYL Z | M-1 | Carbon black |
| Example 7 | SYLYSIA 310P | Binder-5 | PERBUTYL Z | M-1 | Carbon black |
| Example 8 | SYLYSIA 310P | Binder-6 | PERBUTYL Z | M-1 | Carbon black |
| Example 9 | SYLYSIA 310P | Binder-7 | PERBUTYL Z | M-1 | Carbon black |
| Example 10 | SYLYSIA 310P | Binder-8 | PERBUTYL Z | M-1 | Carbon black |
| Example 11 | SYLYSIA 310P | Binder-9 | PERBUTYL Z | M-1 | Carbon black |
| Example 12 | SYLYSIA 350 | Binder-1 | PERHEXYL E | M-2 | Carbon black |
| Example 13 | SYLOSPHERE | Binder-1 | PERHEXYL E | M-2 | Carbon black |
| | C-1504 | | | | |
| Example 14 | SYLYSIA 710 | Binder-1 | PERHEXYL E | M-2 | Carbon black |
| Example 15 | SYLYSIA 730 | Binder-1 | PERHEXYL I | M-2 | Carbon black |
| Example 16 | SYLYSIA 250N | Binder-1 | PERHEXYL I | M-2 | Carbon black |
| Example 17 | SYLOPHOBIC | Binder-1 | PERHEXYL I | M-2 | Carbon black |
| | 702 | | | | |
| Example 18 | SYLOMASK 52 | Binder-1 | PERHEXYL HC | M-2 | Carbon black |
| Example 19 | SYLOMASK 55 | Binder-1 | V-601 | M-2 | Carbon black |
| Comparative | SYLOSPHERE | Binder-7 | IRGACURE 184 | Benzyl | None |
| Example 1 | C-1504 | | | methacrylate | |
| Comparative | None | Binder-1 | PERBUTYL Z | M-1 | Carbon black |
| Example 2 | | | | | |

| | Evaluation results | | | | | |
|---|---|---|---|---|---|---|
| | Coating | Rinsing property | Surface state | Engraving | Engraving | |
| | liquid | of engraving | of relief | depth (μm) | depth (μm) | Shore A |
| | stability | residue | forming layer | (CO₂ laser) | (FC-LD) | hardness (°) |
| Example 1 | A | A | A | 270 | 320 | 75 |
| Example 2 | A | A | A | 300 | 350 | 77 |
| Example 3 | A | A | A | 250 | 300 | 78 |
| Example 4 | A | A | A | 270 | 320 | 77 |
| Example 5 | A | A | A | 275 | 325 | 74 |
| Example 6 | A | A | A | 270 | 320 | 73 |
| Example 7 | A | A | A | 270 | 320 | 78 |
| Example 8 | A | B | A-B | 250 | 300 | 79 |
| Example 9 | A | B | A-B | 230 | 280 | 65 |
| Example 10 | A | B | A-B | 220 | 270 | 60 |
| Example 11 | A | B | A-B | 210 | 260 | 63 |
| Example 12 | A | A | A | 300 | 350 | 74 |
| Example 13 | A | A | A | 305 | 355 | 74 |
| Example 14 | A | A | A | 300 | 350 | 75 |
| Example 15 | A | A | A | 295 | 345 | 80 |
| Example 16 | A | A | A | 300 | 350 | 78 |
| Example 17 | A | A | A | 305 | 355 | 79 |
| Example 18 | A | A | A | 305 | 355 | 80 |
| Example 19 | A | A | A | 290 | 340 | 81 |
| Comparative | B | B | A | 250 | 300 | 47 |
| Example 1 | | | | | | |
| Comparative | A | D | C | 270 | 320 | 78 |
| Example 2 | | | | | | |

As shown in Table 1, it was found that the coating liquids for a relief forming layer of the Examples (resin composition for laser engraving) exhibited excellent storage stability (photostability) of the coating liquid. It was also found that the surface state of the relief forming layer of the relief printing plate precursors of the Examples was satisfactory, and when relief printing plates were produced by engraving the relief printing plate precursors, rinsing properties of the engraving residue were excellent. Furthermore, the relief printing plates of the Examples had greater engraving depths than the relief printing plates of the Comparative Examples, whereby it was confirmed that the resin compositions for laser engraving prepared in the Examples had high engraving sensitivity.

All publications, patent applications, and technical standards mentioned in this specification are herein incorporated by reference to the same extent as if each individual publication, patent application, or technical standard was specifically and individually indicated to be incorporated by reference.

What is claimed is:

1. A resin composition for laser engraving, comprising at least an inorganic porous material, a binder polymer, a thermopolymerization initiator, and a polymerizable compound.

2. The resin composition for laser engraving of claim 1, wherein the binder polymer has a glass transition temperature (Tg) of from 20° C. to 200° C.

3. The resin composition for laser engraving of claim 1, wherein the binder polymer is at least one polymer selected from the group consisting of a polyester, a polyurethane, a polyvinyl butyral, a polyvinyl alcohol and a polyamide.

4. The resin composition for laser engraving of claim 1, further comprising a photothermal conversion agent which absorbs light having a wavelength of from 700 nm to 1,300 nm.

5. The resin composition for laser engraving of claim 4, wherein the photothermal conversion agent is carbon black.

6. The resin composition for laser engraving of claim 1, wherein the thermopolymerization initiator is selected from the group consisting of an organic peroxide, a hexaarylbiimidazole compound and an azo compound.

7. The resin composition for laser engraving of claim 1, wherein the thermopolymerization initiator is an organic peroxide.

8. A relief printing plate precursor for laser engraving, having a relief forming layer formed by thermally crosslinking the resin composition for laser engraving of claim 1.

9. A method of producing a relief printing plate, the method comprising laser-engraving the relief forming layer in the relief printing plate precursor for laser engraving of claim 8 to form a relief layer.

10. A relief printing plate having a relief layer, produced by the method of producing a relief printing plate of claim 9.

11. The relief printing plate of claim 10, wherein the thickness of the relief layer is in a range of from 0.05 mm to 10 mm.

12. The relief printing plate of claim 10, wherein the Shore A hardness of the relief layer is in a range of from 50° to 90°.
